(19) United States
(12) Patent Application Publication
(10) Pub. No.: US 2012/0308931 A1
(43) Pub. Date: Dec. 6, 2012

(54) RESIST COMPOSITION AND METHOD OF FORMING RESIST PATTERN

(75) Inventors: Tsuyoshi Kurosawa, Kawasaki-shi (JP); Kotaro Endo, Kawasaki-shi (JP); Yuta Iwasawa, Kawasaki-shi (JP)

(73) Assignee: TOKYO OHKA KOGYO CO., LTD., Kawasaki-shi (JP)

(21) Appl. No.: 13/433,604

(22) Filed: Mar. 29, 2012

(30) Foreign Application Priority Data
Apr. 5, 2011 (JP) 2011-083797

(51) Int. Cl. G03F 7/027; G03F 7/20

(52) U.S. Cl. 430/285.1; 430/325

(57) ABSTRACT

A resist composition including a base component which exhibits changed solubility in a developing solution under action of acid, and an acid generator containing compounds represented by general formulas (b1) and (b2) shown below

X-Q¹-Y¹—SO₃⁻A⁺ (b 1)

in which Q¹ represents a divalent linking group containing an oxygen atom, Y¹ represents an alkylene group of 1-4 carbons which may have a substituent or a fluorinated alkylene group 1-4 carbons which may have a substituent, X represents an alicyclic hydrocarbon group of 3-30 carbons which may have a substituent, and A⁺ represents an organic cation

R¹—Y⁵—SO₂⁻A⁺ (b 2)

in which R¹ represents a monovalent chain-like aliphatic hydrocarbon group containing a hetero atom at an arbitrary position, Y⁵ represents an alkylene group of 1-4 carbons which may have a substituent or a fluorinated alkylene group of 1-4 carbons which may have a substituent, and A⁺ represents an organic cation.

### TECHNICAL FIELD

The present invention relates to a resist composition and a method of forming a resist pattern using the resist composition.

Priority is claimed on Japanese Patent Application No. 2011-083797, filed Apr. 5, 2011, the content of which is incorporated herein by reference.

### BACKGROUND ART

In lithography techniques, for example, a resist film composed of a resist material is formed on a substrate, and the resist film is subjected to selective exposure followed by development, thereby forming a resist pattern having a predetermined shape on the resist film. A resist material in which the exposed portions of the resist film become soluble in a developing solution is called a positive-type, and a resist material in which the exposed portions become insoluble in a developing solution is called a negative-type. In recent years, in the production of semiconductor elements and liquid crystal display elements, advances in lithography techniques have lead to rapid progress in the field of pattern miniaturization.

Typically, these pattern miniaturization techniques involve shortening the wavelength (and increasing the energy) of the exposure light source. Conventionally, ultraviolet radiation typified by g-line and i-line radiation has been used, but nowadays KrF excimer lasers and ArF excimer lasers are starting to be introduced in the mass production of semiconductor elements. Furthermore, research is also being conducted into lithography techniques that use an exposure light source having a shorter wavelength (and a higher energy level) than these excimer lasers, such as extreme ultraviolet radiation (EUV), electron beam (EB), and X-ray.

Resist materials for use with these types of exposure light sources require lithography properties such as a high resolution capable of reproducing patterns of minute dimensions, and a high level of sensitivity to these types of exposure light sources.

As a resist material that satisfies these conditions, a chemically amplified composition is used, which includes an acid generator component that generates acid upon exposure and a base component that exhibits changed solubility in a developing solution under the action of acid.

A resin (base resin) is generally used as the base component used in a chemically amplified resist composition.

For example, a chemically amplified resist composition for forming a positive-type resist pattern in an alkali developing process that uses an alkali developing solution as the developing solution typically contains an acid generator component and a resin component which exhibits increased solubility in the alkali developing solution under the action of acid. If the resist film formed using this resist composition is selectively exposed during formation of a resist pattern, then within the exposed portions, acid is generated from the acid generator component, and the action of this acid causes an increase in the solubility of the resin component in the alkali developing solution, making the exposed portions soluble in the alkali developing solution. Accordingly, by performing alkali developing, the unexposed portions remain as a pattern, resulting in the formation of a positive-type pattern.

As the resin component, a resin for which the polarity increases under the action of acid is generally used. As the polarity increases, the solubility of the resin in an alkali developing solution increases, whereas the solubility of the resin within organic solvents decreases. Accordingly, if a solvent developing process that uses a developing solution containing an organic solvent (an organic developing solution) is employed instead of the alkali developing process, then within the exposed portions of the resist film, the solubility in the organic developing solution decreases relatively, meaning that during the solvent developing process, the unexposed portions of the resist film are dissolved in the organic developing solution and removed, whereas the exposed portions remain as a pattern, resulting in the formation of a negative-type resist pattern. This type of solvent developing process that results in the formation of a negative-type resist pattern is also referred to as a negative-type developing process (for example, see Patent Document 1).

Currently, resins that contain structural units derived from (meth)acrylate esters within the main chain (acrylic resins) are generally used as base resins for chemically amplified resist compositions that use ArF excimer laser lithography or the like, as they exhibit excellent transparency in the vicinity of 193 nm (for example, see Patent Document 2).

Here, the term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position. The term “(meth)acrylic acid” is a generic term that includes either or both of acrylic acid having a hydrogen atom bonded to the α-position and methacrylic acid having a methyl group bonded to the α-position.

A multitude of compounds have been proposed as the acid generator used in a chemically amplified resist composition, and examples of known acid generators include onium salt acid generators, oxime sulfonate acid generators, diazomethane acid generators, nitrobenzylsulfonate acid generators, iminosulfonate acid generators, and disulfone acid generators.

Among these, as the onium salt acid generator, an iodonium salt having an iodonium ion as the cation or a sulfonium salt having a sulfonium ion as the cation is generally used. Further, the anion (acid) that forms the salt with the aforementioned cation is typically a fluorinated alkylsulfonate ion (for example, see Patent Document 3).

Furthermore, chemically amplified resist compositions that employ a combination of two acid generators having different structures for the aforementioned anion (acid) have also been proposed (for example, see Patent Documents 4 and 5).

### DOCUMENTS OF RELATED ART

### Patent Documents

### [Patent Document 1]

Japanese Unexamined Patent Application, First Publication No. 2008-292975

### [Patent Document 2]

Japanese Unexamined Patent Application, First Publication No. 2003-241385

### [Patent Document 3]

Japanese Unexamined Patent Application, First Publication No. 2005-037888

### [Patent Document 4]

Japanese Unexamined Patent Application, First Publication No. 2009-008777

### [Patent Document 5]

Japanese Unexamined Patent Application, First Publication No. 2009-157040

### DISCLOSURE OF INVENTION

### Problems to be Solved by the Invention

As further progress is expected to be made in lithography techniques and the application field for lithography techniques is expected to expand, there is considerable demand for the development of novel materials for use in lithography applications. For example, as the miniaturization of resist patterns progresses, improvements will be demanded for resist materials, not only in terms of resolution, but also in terms of various other lithography properties such as improved mask reproducibility and reduced roughness. The term “roughness” refers to surface unevenness of the resist pattern, which tends to cause shape defects in the resist pattern. These types of resist pattern shape defects tend to have an adverse effect on the formation and the like of very fine semiconductor elements, and improvement of such shape defects becomes more critical as the pattern becomes finer.

However, in conventional resist compositions, developing tends not to result in satisfactory resolution of the resist film right through to the interface with the substrate, increasing the likelihood of footing (a trapezoidal shape) and yielding a resist pattern having inferior verticalness.

The present invention takes the above circumstances into consideration, with an object of providing a resist composition and a method of forming a resist pattern that enable formation of a resist pattern of superior shape having excellent rectangularity.

### Means to Solve the Problems

A first aspect of the present invention for achieving the above object is a resist composition including a base component (A) which exhibits changed solubility in a developing solution under the action of acid, and an acid generator component (B) which generates acid upon exposure, wherein the acid generator component (B) contains a compound (B1) represented by a general formula (b1) shown below, and a compound (B2) represented by a general formula (b2) shown below.

[Chemical Formula 1]

X-Q¹-Y¹—SO₃⁻A⁺ (b 1)

In the above formula, Q¹ represents a divalent linking group containing an oxygen atom, Y¹ represents an alkylene group of 1 to 4 carbon atoms which may have a substituent or a fluorinated alkylene group of 1 to 4 carbon atoms which may have a substituent, X represents an alicyclic hydrocarbon group of 3 to 30 carbon atoms which may have a substituent, and A⁺ represents an organic cation.

[Chemical Formula 2]

R¹—Y⁵—SO₃⁻A⁺ (b 2)

In the above formula, R¹ represents a monovalent chain-like aliphatic hydrocarbon group containing a hetero atom at an arbitrary position, Y⁵ represents an alkylene group of 1 to 4 carbon atoms which may have a substituent or a fluorinated alkylene group of 1 to 4 carbon atoms which may have a substituent, and A⁺ represents an organic cation.

A second aspect of the present invention is a method of forming a resist pattern, the method including: using the resist composition of the first aspect to form a resist film on a substrate, conducting exposure of the resist film, and developing the resist film to form a resist pattern.

In the present description and claims, the term “exposure” is used as a general concept that includes irradiation with any form of radiation

A “structural unit” describes a monomer unit that contributes to the formation of a polymeric compound (a resin, polymer or copolymer).

The term “aliphatic” is a relative concept used in relation to the term “aromatic”, and defines a group or compound or the like that has no aromaticity.

The term “alkyl group” includes linear, branched and cyclic monovalent saturated hydrocarbon groups, unless specified otherwise.

The term “alkylene group” includes linear, branched and cyclic divalent saturated hydrocarbon groups, unless specified otherwise. This definition also applies for the alkyl group within an alkoxy group.

A “halogenated alkyl group” is a group in which part or all of the hydrogen atoms of an alkyl group have each been substituted with a halogen atom, and a “halogenated alkylene group” is a group in which part or all of the hydrogen atoms of an alkylene group have each been substituted with a halogen atom, wherein examples of the halogen atom include a fluorine atom, chlorine atom, bromine atom and iodine atom.

A “fluorinated alkyl group” is a group in which part or all of the hydrogen atoms of an alkyl group have each been substituted with a fluorine atom, and a “fluorinated alkylene group” is a group in which part or all of the hydrogen atoms of an alkylene group have each been substituted with a fluorine atom.

### Effect of the Invention

The present invention is able to provide a resist composition and a method of forming a resist pattern that enable formation of a resist pattern of superior shape having excellent rectangularity.

### MODES FOR CARRYING OUT THE INVENTION

### <<Resist Composition>>

The resist composition of the present invention includes a base component (A) which exhibits changed solubility in a developing solution under the action of acid (hereinafter referred to as “component (A)”), and an acid generator component (B) which generates acid upon exposure (hereinafter referred to as “component (B)”).

When this resist composition is used to form a resist film, and the resist film is then subjected to selective exposure, acid is generated from the component (B) in the exposed portions, and the solubility of the component (A) in a developing solution changes under the action of the generated acid, whereas in the unexposed portions, the solubility of the component (A) in the developing solution does not change, meaning a difference in solubility in the developing solution develops between the exposed portions and the unexposed portions. As a result, when the resist film is subsequent developed, the exposed portions are dissolved and removed to form a positive-type resist pattern in the case of a positive-type composition, or alternatively, the unexposed portions are dissolved and removed to form a negative-type resist pattern in the case of a negative-type composition.

In this description, a resist composition in which the exposed portions are dissolved and removed to form a positive-type resist pattern is referred to as a “positive-type resist composition”, whereas a resist composition in which the unexposed portions are dissolved and removed to form a negative-type resist pattern is referred to as a “negative-type resist composition”.

The resist composition of the present invention may be either a positive-type resist composition or a negative-type resist composition.

Further, the resist composition of the present invention may be used within either an alkali developing process in which an alkali developing solution is used for the developing treatment during formation of the resist pattern, or a solvent developing process in which a developing solution containing an organic solvent (an organic developing solution) is used for the developing treatment.

### <Component (A)>

As the component (A), either a single organic compound or a mixture of two or more organic compounds typically used as the base components for chemically amplified resist compositions may be used.

In the present description, the term “base component” refers to an organic compound capable of forming a film, and is preferably an organic compound having a molecular weight of 500 or more. Ensuring that the organic compound has a molecular weight of 500 or more ensures a satisfactory film-forming ability, and facilitates the formation of nano level resist patterns.

The organic compounds used as the base component may be broadly classified into non-polymers and polymers.

In general, compounds which have a molecular weight of at least 500 but less than 4,000 may be used as non-polymers. Hereinafter, the term “low molecular weight compound” is used to describe a non-polymer having a molecular weight of at least 500 but less than 4,000.

In terms of the polymers, typically, compounds which have a molecular weight of 1,000 or more may be used. In the present description and claims, the term “resin” is used to describe a polymer having a molecular weight of 1,000 or more.

The “molecular weight” of a polymer refers to the weight-average molecular weight in terms of the polystyrene-equivalent value determined by gel permeation chromatography (GPC).

The component (A) may exhibit either increased solubility in the developing solution under the action of acid or decreased solubility in the developing solution under the action of acid.

In those cases where the resist composition of the present invention is a resist composition which forms a negative-type resist pattern in an alkali developing process (or forms a positive-type resist pattern in a solvent developing process), a base component which is soluble in an alkali developing solution (hereinafter referred to as an alkali-soluble base component) is preferably used as the component (A), and a cross-linking agent component is also added to the composition. A resin (alkali-soluble resin) is typically used as the alkali-soluble base component.

The alkali-soluble base component typically contains alkali-soluble groups such as hydroxyl groups, carboxyl groups and/or amino groups, whereas the cross-linking agent component contains one or more reactive groups such as a methylol group or alkoxymethyl group that are capable of reacting with the alkali-soluble groups under the action of acid. Accordingly, when the resist composition is used to form a resist film and the resist film is then subjected to selective exposure, acid is generated from the component (B) in the exposed portions, the action of the generated acid causes cross-linking to occur between the alkali-soluble base component and the cross-linking agent component, causing a reduction in the amount of alkali-soluble groups within the alkali-soluble base component and a corresponding decrease in the polarity and increase in the molecular weight, and as a result, the solubility of the base component in an alkali developing solution decreases (whereas the solubility in an organic developing solution increases). Accordingly, during resist pattern formation, by conducting selective exposure of a resist film obtained by applying the resist composition to a substrate, the exposed portions change to a state that is substantially insoluble in an alkali developing solution (but soluble in an organic developing solution), while the unexposed portions remain soluble in an alkali developing solution (but substantially insoluble in an organic developing solution), meaning developing with an alkali developing solution can be used to form a negative-type resist pattern. Further, if an organic developing solution is used as the developing solution, then a positive-type resist pattern can be formed.

As the cross-linking agent component, an amino-based cross-linking agent such as a glycoluril having a methylol group or alkoxymethyl group, or a melamine-based cross-linking agent is usually preferable, as it enables the formation of a resist pattern with minimal swelling. The amount added of the cross-linking agent component is preferably within a range from 1 to 50 parts by weight, relative to 100 parts by weight of the alkali-soluble resin.

In those cases where the alkali-soluble base component has self cross-linking properties (for example, cases in which the alkali-soluble base component contains one or more groups that can react with the alkali-soluble groups under the action of acid), addition of the cross-linking agent component may be unnecessary.

In those cases where the resist composition of the present invention is a resist composition which forms a positive-type pattern in an alkali developing process, but forms a negative-type pattern in a solvent developing process, a base component (A0) (hereinafter referred to as “component (A0)”) which exhibits increased polarity under the action of acid is preferably used as the component (A). The polarity of the base component (A0) changes upon exposure, and therefore by using the base component (A0), favorable developing contrast can be achieved not only in an alkali developing process, but also in a solvent developing process.

In other words, in those cases where an alkali developing process is used, the component (A0) is substantially insoluble in an alkali developing solution prior to exposure, but when acid is generated from the component (B) upon exposure, the action of the acid causes an increase in the polarity of the component (A0) that increases the solubility in the alkali developing solution. Accordingly, during resist pattern formation, by conducting selective exposure of a resist film formed by applying the resist composition to a substrate, the exposed portions change from being substantially insoluble in the alkali developing solution to being soluble, while the unexposed portions remain substantially insoluble in the alkali developing solution, meaning alkali developing can be used to form a positive-type resist pattern. On the other hand, in those cases where a solvent developing process is used, the component (A0) exhibits good solubility in an organic developing solution prior to exposure, but when acid is generated from the component (B) upon exposure, the action of the acid causes an increase in the polarity of the component (A0) that reduces the solubility in the organic developing solution.

Accordingly, during resist pattern formation, by conducting selective exposure of a resist film formed by applying the resist composition to a substrate, the exposed portions change from being soluble in the organic developing solution to being substantially insoluble, while the unexposed portions remain soluble in the organic developing solution, meaning developing with the organic developing solution can be used to achieve contrast between the exposed portions and the unexposed portions, enabling formation of a negative-type resist pattern.

In the present invention, the component (A) is preferably a base component (A0). In other words, the resist composition of the present invention is preferably a chemically amplified resist composition that functions as a positive-type composition in an alkali developing process, and functions as a negative-type composition in a solvent developing process.

The component (A0) may be a resin component that exhibits increased polarity under the action of acid, a low molecular weight compound component that exhibits increased polarity under the action of acid, or a mixture thereof.

The component (A0) is preferably a resin component that exhibits increased polarity under the action of acid, and preferably includes a polymeric compound (A1) (hereinafter referred to as “component (A1)”) having a structural unit (a1) derived from an acrylate ester in which the hydrogen atom bonded to the carbon atom on the α-position may be substituted with a substituent and containing an acid decomposable group that exhibits increased polarity under the action of acid.

In addition to the structural unit (a1), the component (A1) preferably also includes at least one structural unit selected from the group consisting of structural units (a0) derived from an acrylate ester in which the hydrogen atom bonded to the carbon atom on the α-position may be substituted with a substituent and containing an —SO₂-containing cyclic group, and structural units (a2) derived from an acrylate ester in which the hydrogen atom bonded to the carbon atom on the α-position may be substituted with a substituent and containing a lactone-containing cyclic group.

The component (A1) preferably also includes, either in addition to the aforementioned structural unit (a1), or in addition to a combination of the structural unit (a1) and at least one of the structural unit (a0) and the structural unit (a2), a structural unit (a3) derived from an acrylate ester in which the hydrogen atom bonded to the carbon atom on the α-position may be substituted with a substituent and containing a polar group-containing aliphatic hydrocarbon group.

In the present description and claims, a “structural unit derived from an acrylate ester” refers to a structural unit that is formed by the cleavage of the ethylenic double bond of an acrylate ester.

The term “acrylate ester” describes a compound in which the hydrogen atom at the carboxyl group terminal of acrylic acid (CH₂═CH—COOH) has been substituted with an organic group.

In the acrylate ester, the hydrogen atom bonded to the carbon atom on the α-position may be substituted with a substituent. Examples of the substituent that may substitute the hydrogen atom bonded to the carbon atom on the α-position include atoms other than a hydrogen atom and groups, and more specific examples include alkyl groups of 1 to 5 carbon atoms, halogenated alkyl groups of 1 to 5 carbon atoms and hydroxyalkyl groups. Unless specified otherwise, “the carbon atom on the α-position of an acrylate ester” refers to the carbon atom having the carbonyl group bonded thereto.

In the following description, an acrylate ester in which the hydrogen atom bonded to the carbon atom on the α-position is substituted with a substituent may also be termed an “α-substituted acrylate ester”. Further, the generic term “(α-substituted) acrylate ester” may be used to describe either or both of the acrylate ester and the α-substituted acrylate ester.

In an α-substituted acrylate ester, the alkyl group for the α-position substituent is preferably a linear or branched alkyl group, and specific examples include a methyl group, ethyl group, propyl group, isopropyl group, n-butyl group, isobutyl group, tert-butyl group, pentyl group, isopentyl group and neopentyl group.

Further, specific examples of the halogenated alkyl group for the α-position substituent include groups in which part or all of the hydrogen atoms of an aforementioned “alkyl group for the α-position substituent” have each been substituted with a halogen atom. Examples of the halogen atom include a fluorine atom, chlorine atom, bromine atom or iodine atom, and a fluorine atom is particularly desirable.

A hydrogen atom, an alkyl group of 1 to 5 carbon atoms or a halogenated alkyl group of 1 to 5 carbon atoms is preferably bonded to the α-position of the (α-substituted) acrylate ester, a hydrogen atom, an alkyl group of 1 to 5 carbon atoms or a fluorinated alkyl group of 1 to 5 carbon atoms is more preferred, and from the viewpoint of industrial availability, a hydrogen atom or a methyl group is the most desirable.

[Structural Unit (a1)]

The structural unit (a1) is a structural unit derived from an acrylate ester in which the hydrogen atom bonded to the carbon atom on the α-position may be substituted with a substituent and containing an acid decomposable group that exhibits increased polarity under the action of acid.

The term “acid decomposable group” describes a group having acid degradability which, under the action of the acid generated from the component (B) upon exposure, undergoes cleavage of at least some of the bonds within the structure of the acid decomposable group.

Examples of acid decomposable groups that exhibit increased polarity under the action of acid include groups which degrade under the action of acid to form a polar group.

Examples of this polar group include a carboxyl group, hydroxyl group, amino group and sulfo group (—SO₃H). Among these groups, polar groups that contain an —OH within the structure (hereinafter also referred to as “OH-containing polar groups”) are preferred, a carboxyl group or a hydroxyl group is more preferable, and a carboxyl group is particularly desirable.

More specific examples of the acid decomposable group include groups in which an aforementioned polar group is protected with an acid-dissociable group (such as a group in which the hydrogen atom of an OH-containing polar group is protected with an acid-dissociable group).

An “acid-dissociable group” describes a group having acid dissociability which, under the action of the acid generated from the component (B) upon exposure, undergoes cleavage of at least the bond between the acid-dissociable group and the atom adjacent to the acid-dissociable group. An acid-dissociable group that constitutes an acid decomposable group must be a group of lower polarity than the polar group generated by dissociation of the acid-dissociable group, so that when the acid-dissociable group dissociates under the action of acid, a polar group having a higher polarity than the acid-dissociable group is generated, resulting in an increase in the polarity. As a result, the polarity of the entire component (A1) increases. Increasing the polarity causes a relative change in the solubility within the developing solution, so that the solubility increases in those cases where the developing solution is an alkali developing solution, whereas the solubility decreases in those cases where the developing solution is a developing solution containing an organic solvent (an organic developing solution).

There are no particular limitations on the acid-dissociable group, and any of the groups that have been proposed as acid-dissociable groups within the base resins of chemically amplified resists can be used. Generally, groups that form either a cyclic or chain-like tertiary alkyl ester with the carboxyl group of the (meth)acrylic acid or the like, and acetal-type acid-dissociable groups such as alkoxyalkyl groups are widely known.

Here, a “tertiary alkyl ester” describes a structure in which an ester is formed by substituting the hydrogen atom of a carboxyl group with a chain-like or cyclic alkyl group, and a tertiary carbon atom within the chain-like or cyclic alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom, thereby forming a carboxyl group.

The chain-like or cyclic alkyl group may have a substituent.

Hereinafter, for the sake of simplicity, groups that exhibit acid dissociability as a result of the formation of a tertiary alkyl ester with a carboxyl group are referred to as “tertiary alkyl ester-type acid-dissociable groups”.

Examples of tertiary alkyl ester-type acid-dissociable groups include aliphatic branched acid-dissociable groups and acid-dissociable groups that contain an aliphatic cyclic group.

Here, the term “aliphatic branched” refers to a branched structure having no aromaticity. The structure of the “aliphatic branched acid-dissociable group” is not limited to groups constituted of only carbon atoms and hydrogen atoms (not limited to hydrocarbon groups), but is preferably a hydrocarbon group. Further, the “hydrocarbon group” may be either saturated or unsaturated, but in most cases, is preferably saturated.

Examples of the aliphatic branched, acid-dissociable group include groups represented by a formula —C(R⁷¹)(R⁷²)(R⁷³). In this formula, each of R⁷¹ to R⁷³ independently represents a linear alkyl group of 1 to 5 carbon atoms. The group represented by the formula —C(R⁷¹)(R⁷²)(R⁷³) preferably has 4 to 8 carbon atoms, and specific examples include a tert-butyl group, 2-methyl-2-butyl group, 2-methyl-2-pentyl group and 3-methyl-3-pentyl group.

A tert-butyl group is particularly desirable.

The term “aliphatic cyclic group” refers to a monocyclic group or polycyclic group that has no aromaticity.

The “aliphatic cyclic group” within the “acid-dissociable group that contains an aliphatic cyclic group” may or may not have a substituent. Examples of the substituent include alkyl groups of 1 to 5 carbon atoms, alkoxy groups of 1 to 5 carbon atoms, a fluorine atom, fluorinated alkyl groups of 1 to 5 carbon atoms, and an oxygen atom (═O).

The basic ring of the “aliphatic cyclic group” excluding substituents is not limited to structures constituted of only carbon and hydrogen (not limited to hydrocarbon groups), but is preferably a hydrocarbon group. Further, the “hydrocarbon group” may be either saturated or unsaturated, but is preferably saturated.

The aliphatic cyclic group may be either monocyclic or polycyclic.

Examples of the aliphatic cyclic group include groups in which one or more hydrogen atoms have been removed from a monocycloalkane which may or may not be substituted with an alkyl group of 1 to 5 carbon atoms, a fluorine atom or a fluorinated alkyl group, and groups in which one or more hydrogen atoms have been removed from a polycycloalkane such as a bicycloalkane, tricycloalkane or tetracycloalkane. Specific examples include groups in which one or more hydrogen atoms have been removed from a monocycloalkane such as cyclopentane or cyclohexane, and alicyclic hydrocarbon groups in which one or more hydrogen atoms have been removed from a polycycloalkane such as adamantane, norbornane, isobornane, tricyclodecane or tetracyclododecane. Further, part of the carbon atoms that constitute the ring structure of any of these alicyclic hydrocarbon groups may be substituted with an ether group (—O—).

Examples of the acid-dissociable groups that contain an aliphatic cyclic group include the following.

(i) a group which forms a tertiary carbon atom on the ring structure of a monovalent aliphatic cyclic group in which a substituent (a group or an atom other than hydrogen) is bonded to the carbon atom to which an atom adjacent to the acid dissociable, dissolution inhibiting group (e.g., “—O—” within “—C(═O)—O— group”) is bonded; and

(ii) a group which have a monovalent aliphatic cyclic group, and a branched alkylene group containing a tertiary carbon atom that is bonded to the monovalent aliphatic cyclic group.

In a group of type (i) described above, examples of the substituent bonded to the carbon atom to which an atom adjacent to the acid dissociable group is bonded on the ring skeleton of the aliphatic cyclic group include alkyl groups. Examples of these alkyl groups include the same groups as those described below for R¹⁴ in formulas (1-1) to (1-9) shown below.

Specific examples of groups of type (i) include groups represented by general formulas (1-1) to (1-9) shown below.

Specific examples of groups of type (ii) include groups represented by general formulas (2-1) to (2-6) shown below.

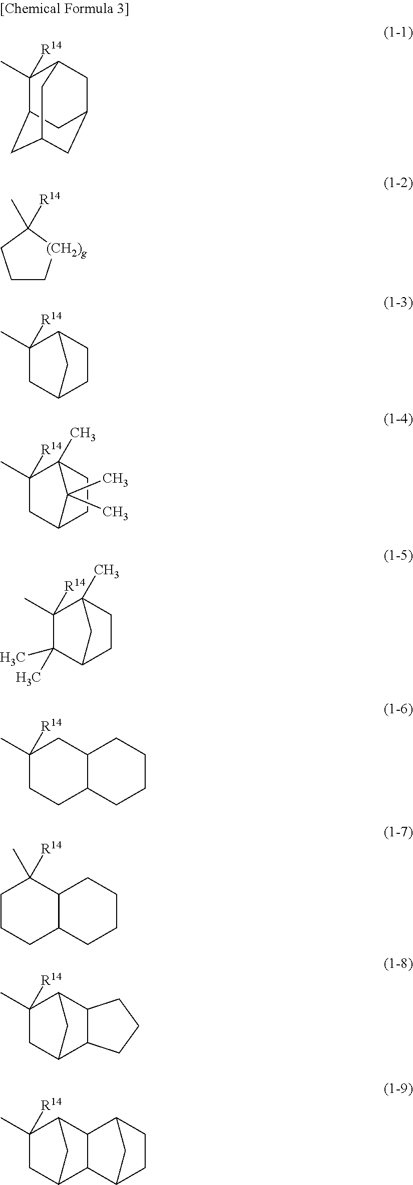

In the above formulas, R¹⁴ represents an alkyl group, and g represents an integer of 0 to 8.

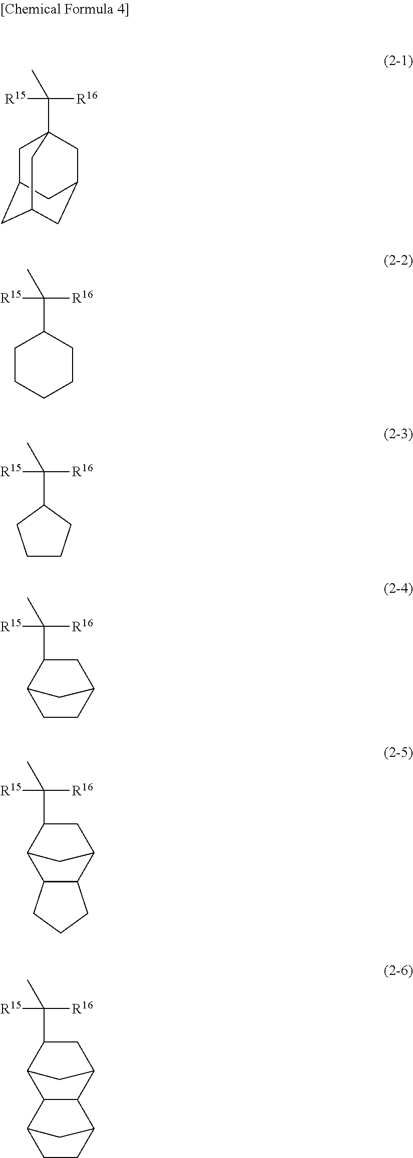

In the above formulas, each of R¹⁵ and R¹⁶ independently represents an alkyl group.

In the formulas (1-1) to (1-9), the alkyl group for R¹⁴ may be linear, branched or cyclic, and a linear or branched alkyl group is preferable.

The linear alkyl group preferably has 1 to 5 carbon atoms, more preferably 1 to 4 carbon atoms, and still more preferably 1 or 2 carbon atoms. Specific examples include a methyl group, ethyl group, n-propyl group, n-butyl group and n-pentyl group. Among these, a methyl group, ethyl group or n-butyl group is preferable, and a methyl group or ethyl group is more preferable.

The branched alkyl group preferably has 3 to 10 carbon atoms, and more preferably 3 to 5 carbon atoms. Specific examples of such branched alkyl groups include an isopropyl group, isobutyl group, tert-butyl group, isopentyl group and neopentyl group, and an isopropyl group is particularly desirable.

g is preferably an integer of 0 to 3, more preferably an integer of 1 to 3, and still more preferably 1 or 2.

In the formulas (2-1) to (2-6), examples of the alkyl group for R¹⁵ and R¹⁶ include the same alkyl groups as those described above for R¹⁴.

In the formulas (1-1) to (1-9) and (2-1) to (2-6), part of the carbon atoms that constitute the ring(s) may be replaced with an ethereal oxygen atom (—O—).

Further, in the formulas (1-1) to (1-9) and (2-1) to (2-6), one or more of the hydrogen atoms bonded to the carbon atoms that constitute the ring(s) may each be substituted with a substituent. Examples of the substituent include an alkyl group of 1 to 5 carbon atoms, a fluorine atom and a fluorinated alkyl group.

An “acetal-type acid-dissociable group” generally substitutes a hydrogen atom at the terminal of an OH-containing polar group such as a carboxyl group or hydroxyl group, so as to be bonded with an oxygen atom. When acid is generated upon exposure, the generated acid acts to break the bond between the acetal-type acid-dissociable group and the oxygen atom to which the acetal-type acid-dissociable group is bonded, thereby forming an OH-containing polar group such as a carboxyl group or hydroxyl group.

Examples of acetal-type acid-dissociable groups include groups represented by a general formula (p1) shown below.

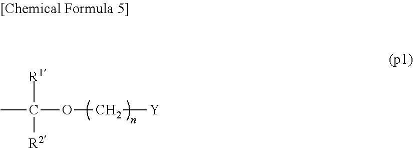

In the formula, each of R^{1′} and R^{2′} independently represents a hydrogen atom or an alkyl group of 1 to 5 carbon atoms, n represents an integer of 0 to 3, and Y represents an alkyl group of 1 to 5 carbon atoms or an aliphatic cyclic group.

In the above formula (p1), n is preferably an integer of 0 to 2, more preferably 0 or 1, and most preferably 0.

Examples of the alkyl group for R^{1′} and R^{2′} include the same alkyl groups as those described above for the substituent which may be bonded to the carbon atom on the α-position within the description relating to the aforementioned α-substituted acrylate ester. Among these, a methyl group or ethyl group is preferable, and a methyl group is the most desirable.

In the present invention, it is preferable that at least one of R^{1′} and R^{2′} is a hydrogen atom. That is, it is preferable that the acid-dissociable group (p1) is a group represented by a general formula (p1-1) shown below.

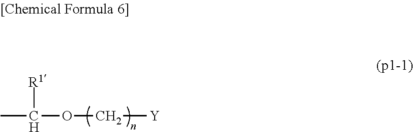

In the formula, R^{1′}, n and Y are the same as defined above.

Examples of the alkyl group for Y include the same alkyl groups as those described above for the substituent which may be bonded to the carbon atom on the α-position within the description relating to the aforementioned α-substituted acrylate ester.

As the aliphatic cyclic group for Y, any of the monocyclic or polycyclic aliphatic cyclic groups which have been proposed for conventional ArF resists and the like can be appropriately selected for use. For example, the same aliphatic cyclic groups as those described above in connection with the “acid-dissociable group that contains an aliphatic cyclic group” can be used.

Further, as the acetal-type acid-dissociable group, groups represented by a general formula (p2) shown below can also be used.

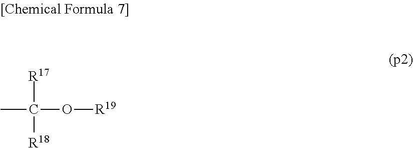

In the formula, each of R¹⁷ and R¹⁸ independently represents a linear or branched alkyl group or a hydrogen atom, and R¹⁹ represents a linear, branched or cyclic alkyl group, or alternatively, each of R¹⁷ and R¹⁹ may independently represent a linear or branched alkylene group, wherein R¹⁷ and R¹⁹ are bonded to each other to form a ring.

The alkyl group for R¹⁷ and R¹⁸ preferably has 1 to 15 carbon atoms, and may be either linear or branched. As the alkyl group, an ethyl group or methyl group is preferable, and a methyl group is most preferable.

It is particularly desirable that either one of R¹⁷ and R¹⁸ is a hydrogen atom, and the other is a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cycloalkyl group, it preferably has 4 to 15 carbon atoms, more preferably 4 to 12 carbon atoms, and most preferably 5 to 10 carbon atoms. Examples of the cycloalkyl group include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

Further, in the above formula (p2), each of R¹⁷ and R¹⁹ may independently represent a linear or branched alkylene group (preferably an alkylene group of 1 to 5 carbon atoms), wherein R¹⁹ and R¹⁷ are bonded to each other.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include a tetrahydropyranyl group and tetrahydrofuranyl group.

More specific examples of the structural unit (a1) include structural units represented by a general formula (a1-0-1) shown below and structural units represented by a general formula (a1-0-2) shown below.

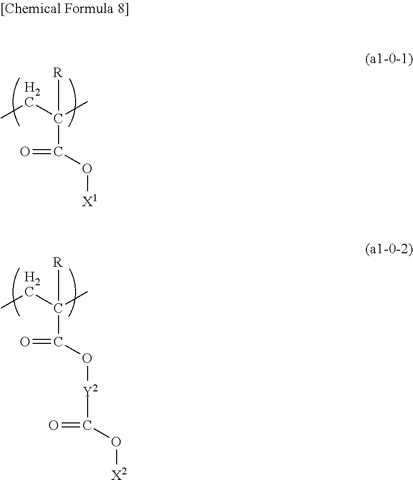

In the above formulas, R represents a hydrogen atom, an alkyl group of 1 to 5 carbon atoms or a halogenated alkyl group of 1 to 5 carbon atoms, X¹ represents an acid-dissociable group, Y² represents a divalent linking group, and X² represents an acid-dissociable group.

In the general formula (a1-0-1), examples of the alkyl group and the halogenated alkyl group for R include the same alkyl groups and halogenated alkyl groups as those described above for the substituent which may be bonded to the carbon atom on the α-position within the description relating to the aforementioned α-substituted acrylate ester. R is preferably a hydrogen atom, an alkyl group of 1 to 5 carbon atoms or a fluorinated alkyl group of 1 to 5 carbon atoms, and is most preferably a hydrogen atom or a methyl group.

There are no particular limitations on X¹ as long as it is an acid-dissociable group. Examples include the aforementioned tertiary alkyl ester-type acid-dissociable groups and acetal-type acid-dissociable groups, and of these, a tertiary alkyl ester-type acid-dissociable group is preferable.

In the general formula (a1-0-2), R is the same as defined above.

X² is the same as defined for X¹ in the formula (a1-0-1).

Although there are no particular limitations on the divalent linking group for Y², preferred examples include divalent hydrocarbon groups which may have a substituent, and divalent linking groups containing a hetero atom.

The description that the hydrocarbon group “may have a substituent” means that part or all of the hydrogen atoms within the hydrocarbon group may each be substituted with a substituent (an atom other than a hydrogen atom or a group).

The hydrocarbon group may be either an aliphatic hydrocarbon group, or an aromatic hydrocarbon group.

An “aliphatic hydrocarbon group” refers to a hydrocarbon group that has no aromaticity.

The aliphatic hydrocarbon group for the divalent hydrocarbon group for Y² may be either saturated or unsaturated. In general, the aliphatic hydrocarbon group is preferably saturated.

More specific examples of the aliphatic hydrocarbon group include linear or branched aliphatic hydrocarbon groups, and aliphatic hydrocarbon groups that include a ring within the structure.

The linear or branched aliphatic hydrocarbon group preferably has 1 to 10 carbon atoms, more preferably 1 to 6 carbon atoms, still more preferably 1 to 4 carbon atoms, and most preferably 1 to 3 carbon atoms.

As the linear aliphatic hydrocarbon group, a linear alkylene group is preferable, and specific examples include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferable, and specific examples include alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—, alkylethylene groups such as —CH(CH₃)CH₂—, —CH(CH₃)CH(CH₃)—, —C(CH₃)₂CH₂—, —CH(CH₂CH₃)CH₂— and —C(CH₂CH₃)₂—CH₂—, alkyltrimethylene groups such as —CH(CH₃)CH₂CH₂— and —CH₂CH(CH₃)CH₂—, and alkyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent. Examples of the substituent include a fluorine atom, a fluorinated alkyl group of 1 to 5 carbon atoms and an oxygen atom (═O).

Examples of the aliphatic hydrocarbon group that includes a ring within the structure include alicyclic hydrocarbon groups (groups in which two hydrogen atoms have been removed from an aliphatic hydrocarbon ring), groups in which an alicyclic hydrocarbon group is bonded to the terminal of a linear or branched aliphatic hydrocarbon group, and groups in which an alicyclic hydrocarbon group is interposed within the chain of a linear or branched aliphatic hydrocarbon group. Examples of the linear or branched aliphatic hydrocarbon group include the same groups as those mentioned above.

The alicyclic hydrocarbon group preferably has 3 to 20 carbon atoms, and more preferably 3 to 12 carbon atoms.

The alicyclic hydrocarbon group may be either a polycyclic group or a monocyclic group. As the monocyclic alicyclic hydrocarbon group, a group in which two hydrogen atoms have been removed from a monocycloalkane is preferred. The monocycloalkane preferably contains 3 to 6 carbon atoms, and specific examples include cyclopentane and cyclohexane. As the polycyclic alicyclic hydrocarbon group, a group in which two hydrogen atoms have been removed from a polycycloalkane is preferred, wherein the polycycloalkane preferably contains 7 to 12 carbon atoms, and specific examples of the polycycloalkane include adamantane, norbornane, isobornane, tricyclodecane and tetracyclododecane.

The alicyclic hydrocarbon group may or may not have a substituent. Examples of the substituent include an alkyl group of 1 to 5 carbon atoms, a fluorine atom, a fluorinated alkyl group of 1 to 5 carbon atoms, and an oxygen atom (═O).

The aromatic hydrocarbon group is a hydrocarbon group having an aromatic ring.

The aromatic hydrocarbon group used as the divalent hydrocarbon group for Y² preferably has 3 to 30 carbon atoms, more preferably 5 to 30 carbon atoms, still more preferably 5 to 20 carbon atoms, still more preferably 6 to 15 carbon atoms, and most preferably 6 to 10 carbon atoms. Here, the number of carbon atoms within substituents is not included in the number of carbon atoms of the aromatic hydrocarbon group.

Specific examples of the aromatic ring within the aromatic hydrocarbon group include aromatic hydrocarbon rings such as benzene, biphenyl, fluorene, naphthalene, anthracene and phenanthrene, and aromatic heterocyclic rings in which part of the carbon atoms that constitute one of the above aromatic hydrocarbon rings have been substituted with a hetero atom. Examples of the hetero atom in the aromatic heterocyclic rings include an oxygen atom, a sulfur atom and a nitrogen atom.

Specific examples of the aromatic hydrocarbon group include groups in which two hydrogen atoms have been removed from an aforementioned aromatic hydrocarbon ring (namely, arylene groups), and groups in which one hydrogen atom from a group having one hydrogen atom removed from an aforementioned aromatic hydrocarbon ring (namely, an aryl group) is substituted with an alkylene group (for example, groups in which one hydrogen atom is removed from the aryl group of an arylalkyl group such as a benzyl group, phenethyl group, 1-naphthylmethyl group, 2-naphthylmethyl group, 1-naphthylethyl group or 2-naphthylethyl group). The alkylene group (the alkyl chain within the arylalkyl group) preferably contains 1 to 4 carbon atoms, more preferably 1 or 2 carbon atoms, and most preferably 1 carbon atom.

The aromatic hydrocarbon group may or may not have a substituent. For example, a hydrogen atom bonded to the aromatic hydrocarbon ring of an aforementioned aromatic hydrocarbon group may be substituted with a substituent. Examples of the substituent include an alkyl group, alkoxy group, halogen atom, halogenated alkyl group, hydroxyl group and oxygen atom (═O).

The alkyl group for the substituent is preferably an alkyl group of 1 to 5 carbon atoms, and is most preferably a methyl group, ethyl group, propyl group, n-butyl group or tert-butyl group.

The alkoxy group for the substituent is preferably an alkoxy group of 1 to 5 carbon atoms, is more preferably a methoxy group, ethoxy group, n-propoxy group, iso-propoxy group, n-butoxy group or tert-butoxy group, and is most preferably a methoxy group or an ethoxy group.

Examples of the halogen atom for the substituent include a fluorine atom, chlorine atom, bromine atom and iodine atom, and a fluorine atom is preferred.

Examples of the halogenated alkyl group for the substituent include groups in which part or all of the hydrogen atoms of an aforementioned alkyl group have each been substituted with an aforementioned halogen atom.

Examples of the hetero atom in the “divalent linking group containing a hetero atom” for Y² include atoms other than a carbon atom or hydrogen atom, and specific examples include an oxygen atom, nitrogen atom, sulfur atom or halogen atom.

Specific examples of the divalent linking group containing a hetero atom include —O—, —C(═O)—O—, —C(═O)—, —O—C(═O)—O—, —C(═O)—NH—, —NH— (wherein H may be substituted with a substituent such as an alkyl group or acyl group), —S—, —S(═O)₂—, —S(═O)₂—O—, —NH—C(═O)—, ═N— and groups represented by general formulas —Y²¹—O—Y²²—, —[Y²¹—C(═O)—O]_{m′}—Y²²— and —Y²¹—O—C(═O)—Y²²— [wherein each of Y²¹ and Y²² independently represents a divalent hydrocarbon group which may have a substituent, O represents an oxygen atom, and m′ represents an integer of 0 to 3].

When Y² represents —NH—, the H may be substituted with a substituent such as an alkyl group or an acyl group. The substituent (the alkyl group or acyl group or the like) preferably contains 1 to 10 carbon atoms, more preferably 1 to 8 carbon atoms, and most preferably 1 to 5 carbon atoms.

In the formulas —Y²¹—O—Y²²—, —[Y²¹—C(═O)—O]_{m′}—Y²²— and —Y²¹—O—C(═O)—Y²²—, each of Y²¹ and Y²² independently represents a divalent hydrocarbon group which may have a substituent. Examples of this divalent hydrocarbon group include the same groups as those described above for the “divalent hydrocarbon group which may have a substituent” for Y².

Y²¹ is preferably a linear aliphatic hydrocarbon group, more preferably a linear alkylene group, still more preferably a linear alkylene group of 1 to 5 carbon atoms, and most preferably a methylene group or ethylene group.

Y²² is preferably a linear or branched aliphatic hydrocarbon group, and is more preferably a methylene group, ethylene group or alkylmethylene group. The alkyl group within the alkylmethylene group is preferably a linear alkyl group of 1 to 5 carbon atoms, more preferably a linear alkyl group of 1 to 3 carbon atoms, and most preferably a methyl group.

In the group represented by the formula —[Y²¹—C(═O)—O]_{m′}—Y²²—, m′ represents an integer of 0 to 3, and is preferably an integer of 0 to 2, more preferably 0 or 1, and most preferably 1. In other words, the group represented by the formula —[Y²¹—C(═O)—O]_{m′}—Y²²— is most preferably a group represented by a formula —Y²¹—C(═O)—O—Y²²—. Among such groups, groups represented by a formula —(CH₂)_{a′}—C(═O)—O—(CH₂)_{b′}— are particularly preferred. In this formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

The divalent linking group containing a hetero atom is preferably a linear group containing an oxygen atom as the hetero atom, such as a group containing an ether linkage or an ester linkage, and a group represented by one of the above formulas —Y²¹—O—Y²²—, —[Y²¹—C(═O)—O]_{m′}—Y²²— or —Y²¹—O—C(═O)—Y²² is particularly desirable.

Among the above possibilities, the divalent linking group for Y² is preferably a linear or branched alkylene group, a divalent alicyclic hydrocarbon group, or a divalent linking group containing a hetero atom. Of these groups, a linear or branched alkylene group or a divalent linking group containing a hetero atom is particularly preferred.

Specific examples of the structural unit (a1) include structural units represented by general formulas (a1-1) to (a1-4) shown below.

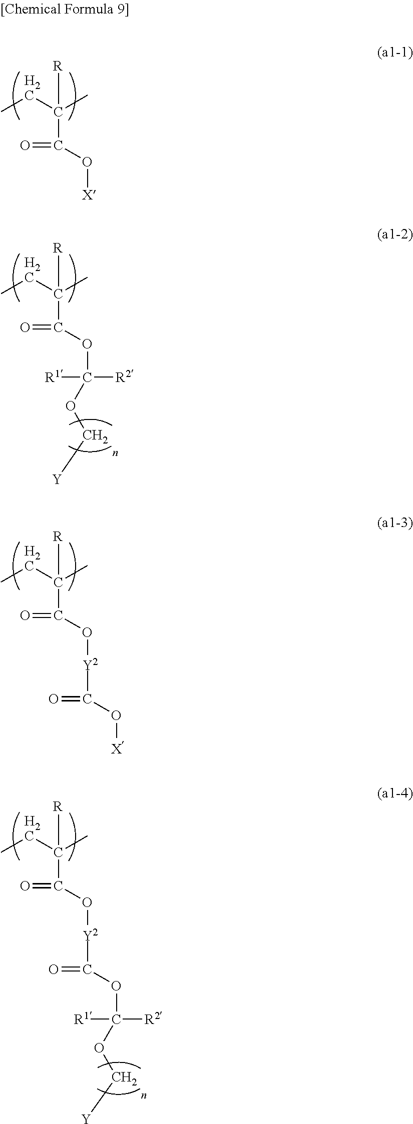

In the formulas, R, R^{1′}, R^{2′}, n, Y and Y² are each the same as defined above, and X′ represents a tertiary alkyl ester-type acid-dissociable group.

In the above formulas, examples of X′ include the same tertiary alkyl ester-type acid-dissociable groups as those described above.

R^{1′}, R^{2′}, n and Y¹ are the same as defined above for R^{1′}, R^{2′}, n and Y respectively in the general formula (p1) described above in connection with the “acetal-type acid-dissociable group”.

Examples of Y² include the same groups as those listed above for Y² in the general formula (a1-0-2).

Specific examples of the structural units represented by the general formula (a1-1) to (a1-4) are shown below.

In the formulas shown below, R^{α} represents a hydrogen atom, a methyl group or a trifluoromethyl group.

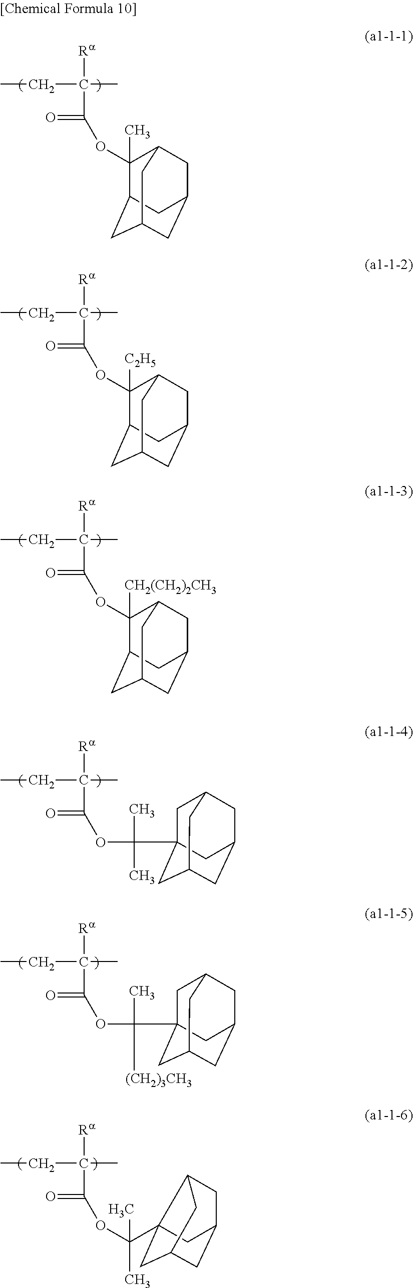

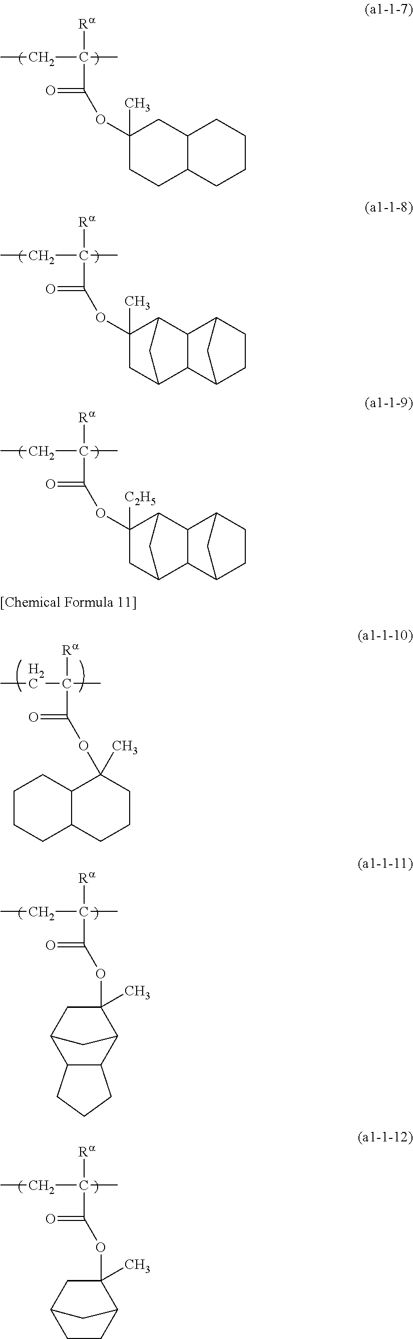

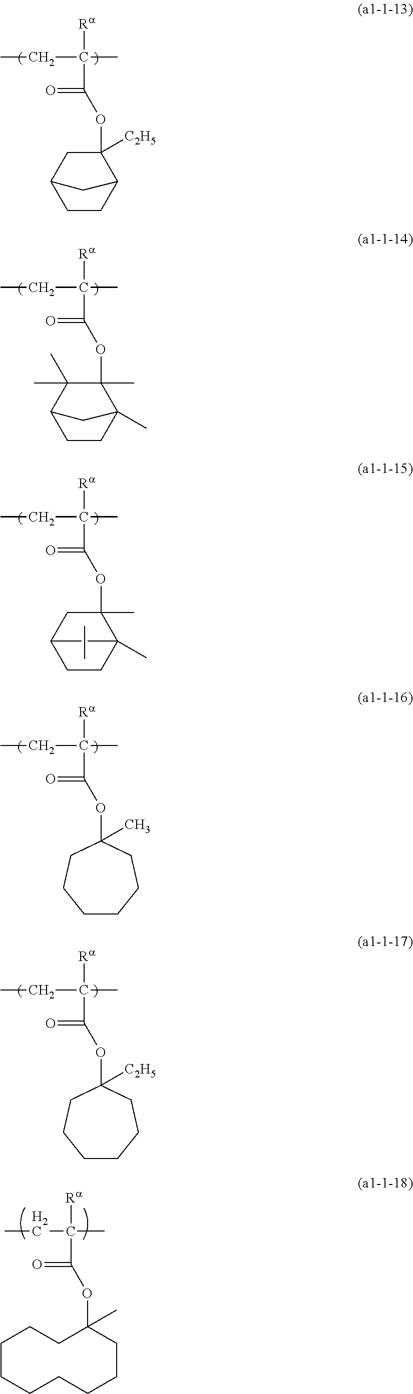

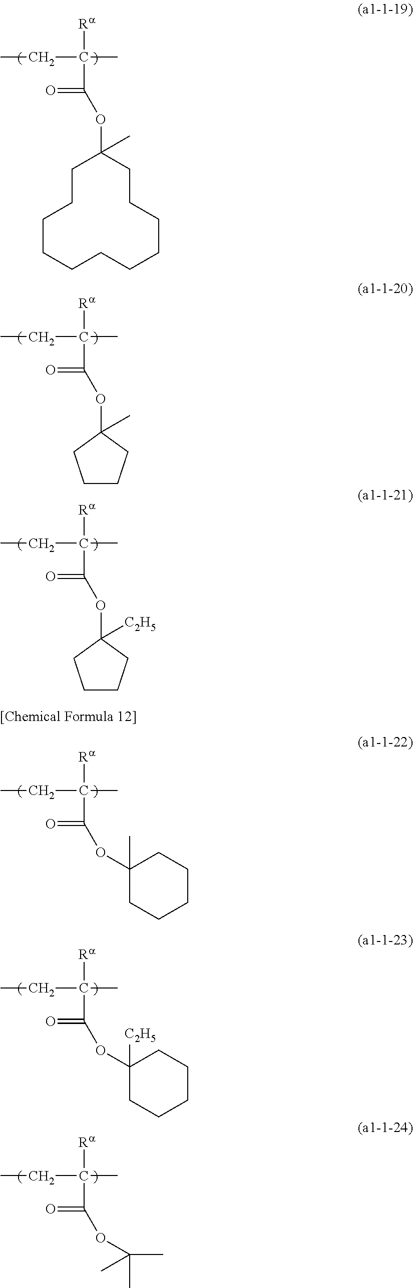

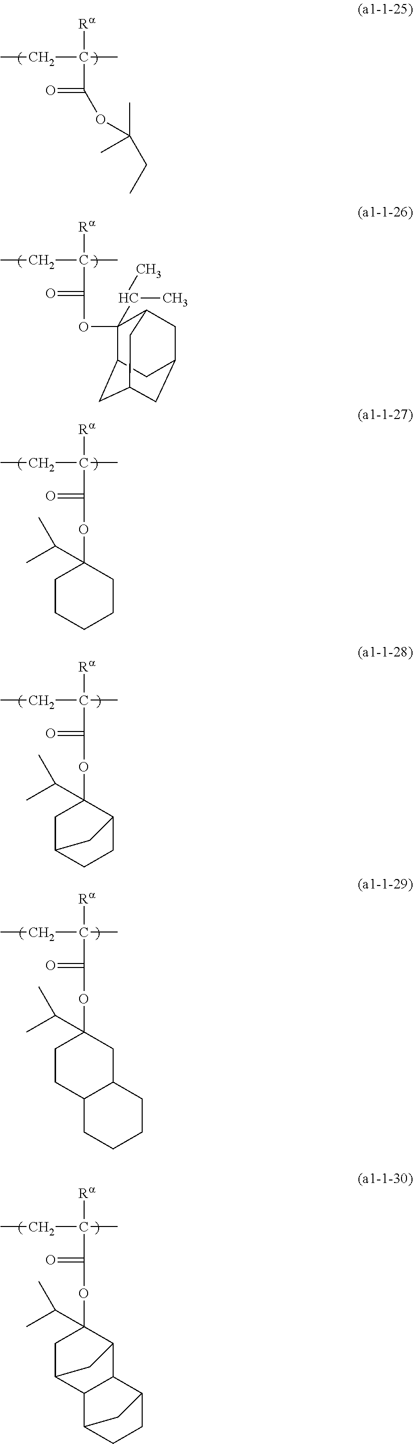

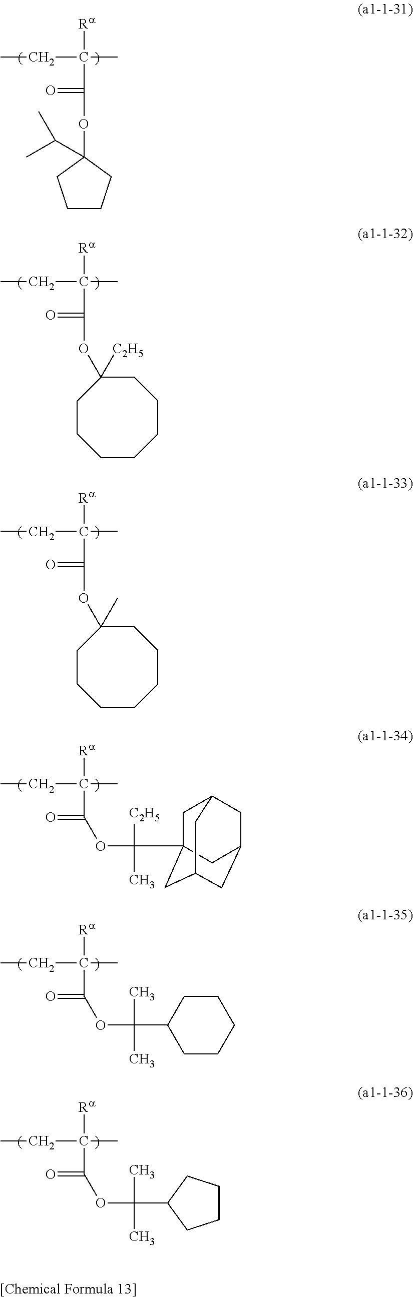

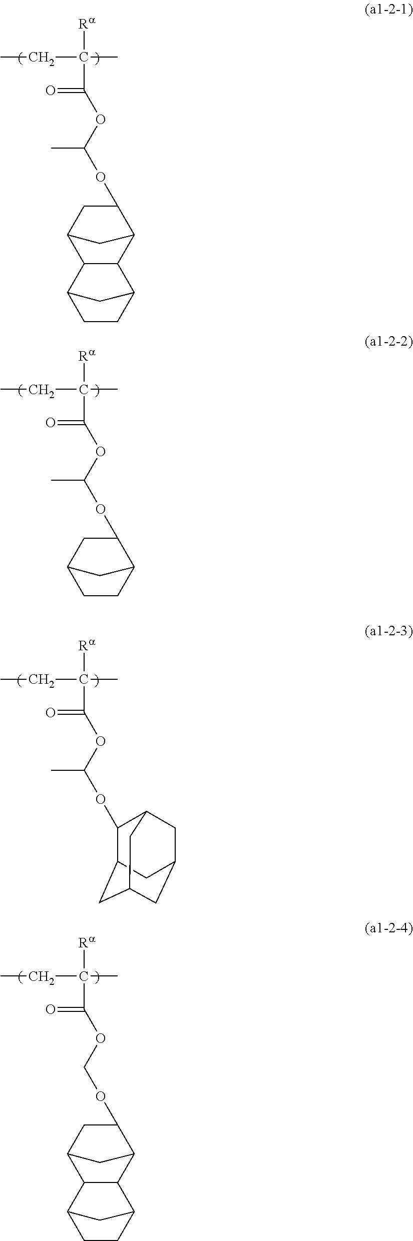

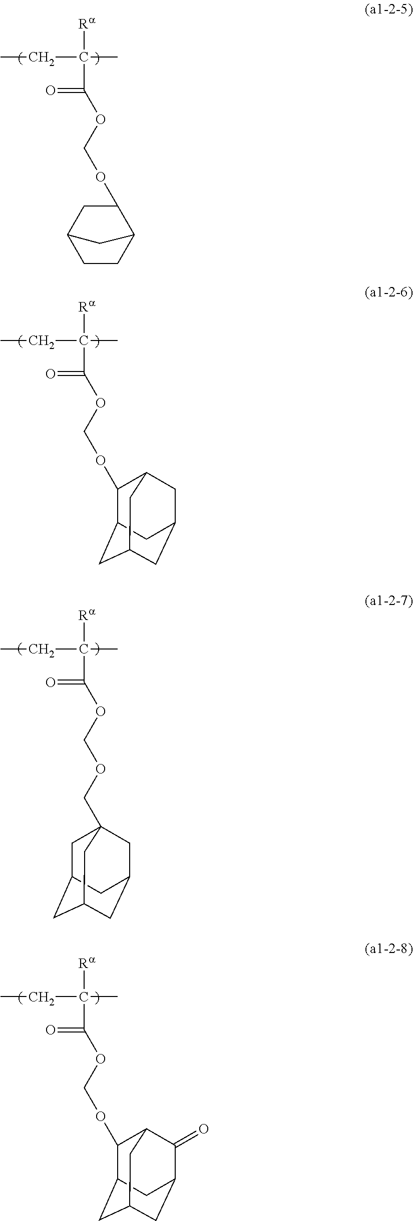

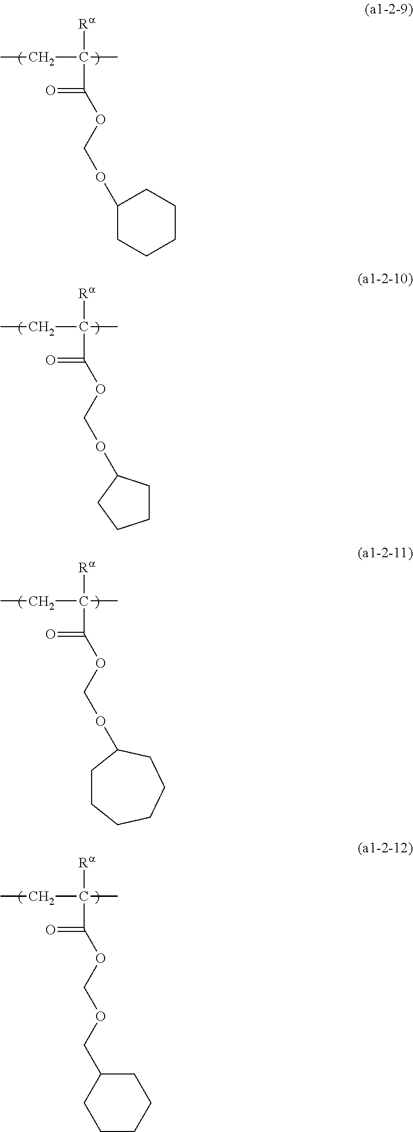

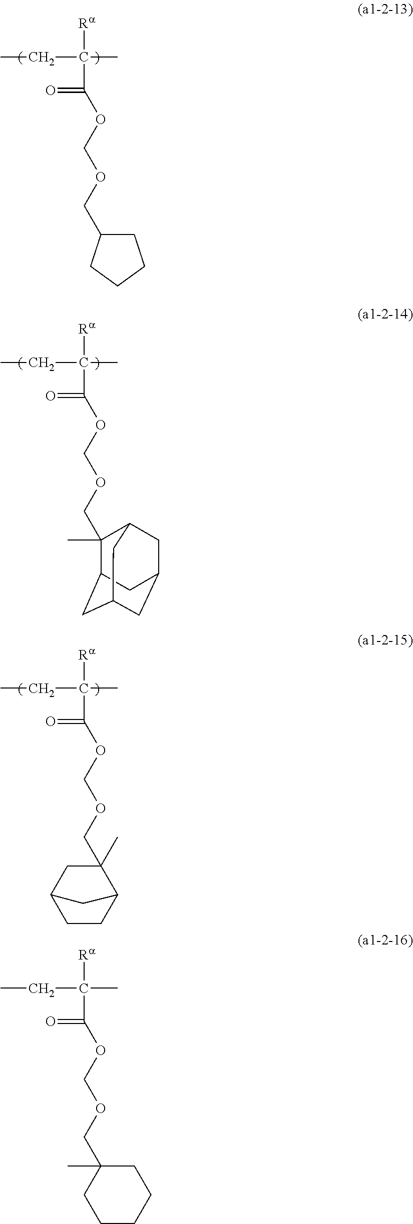

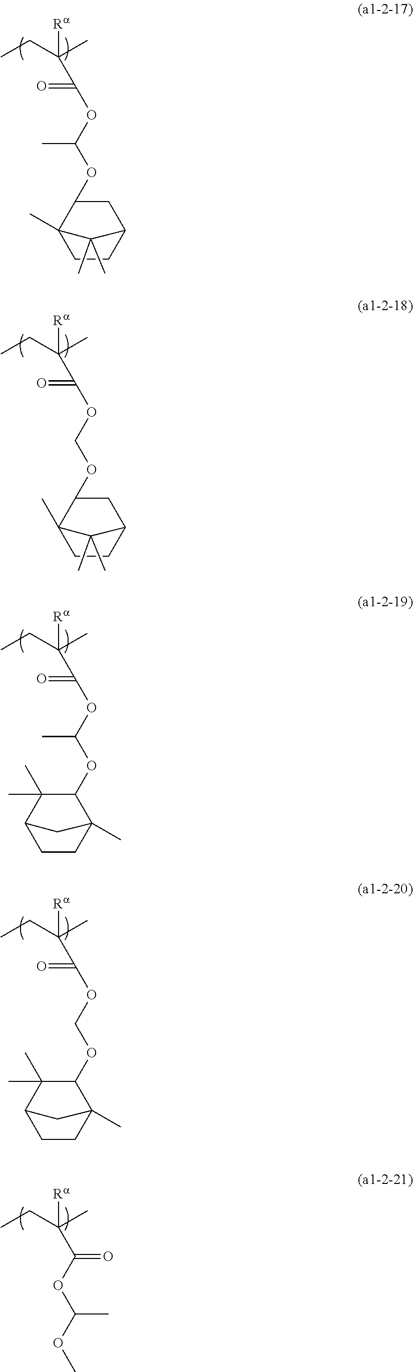

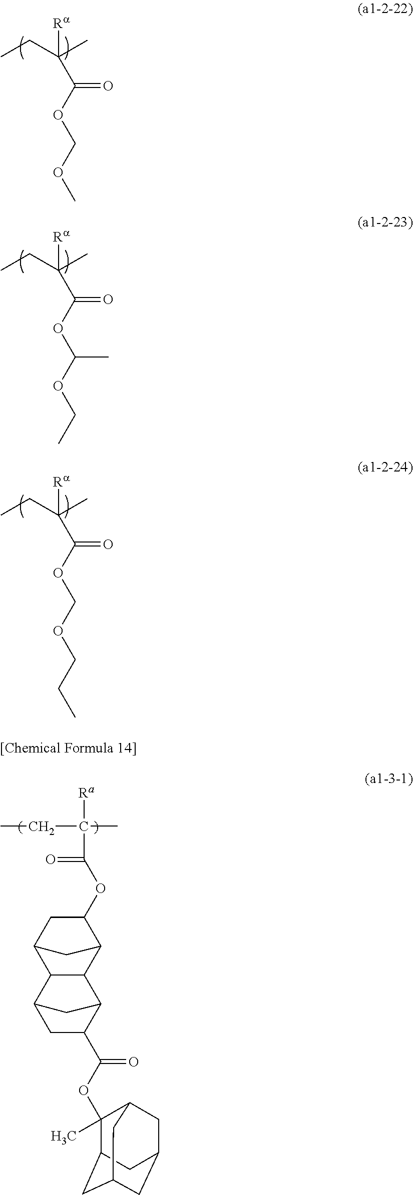

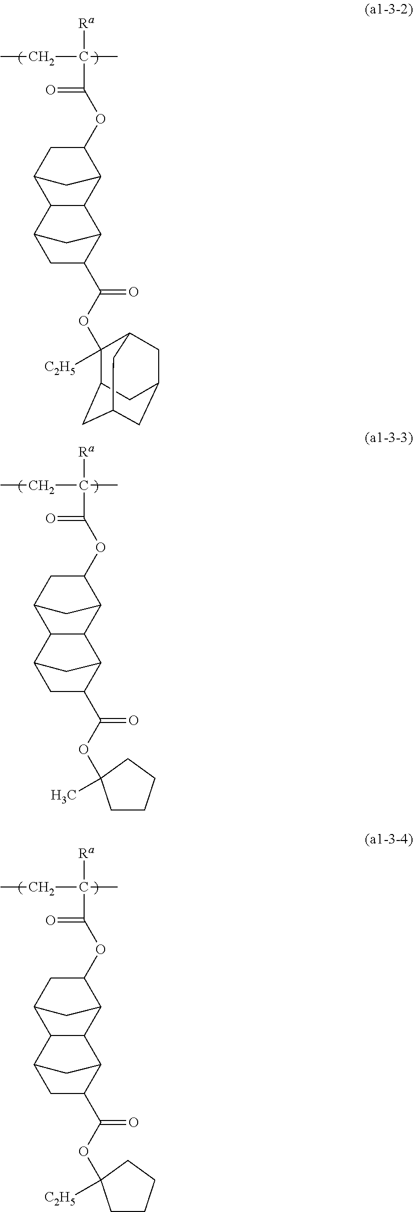

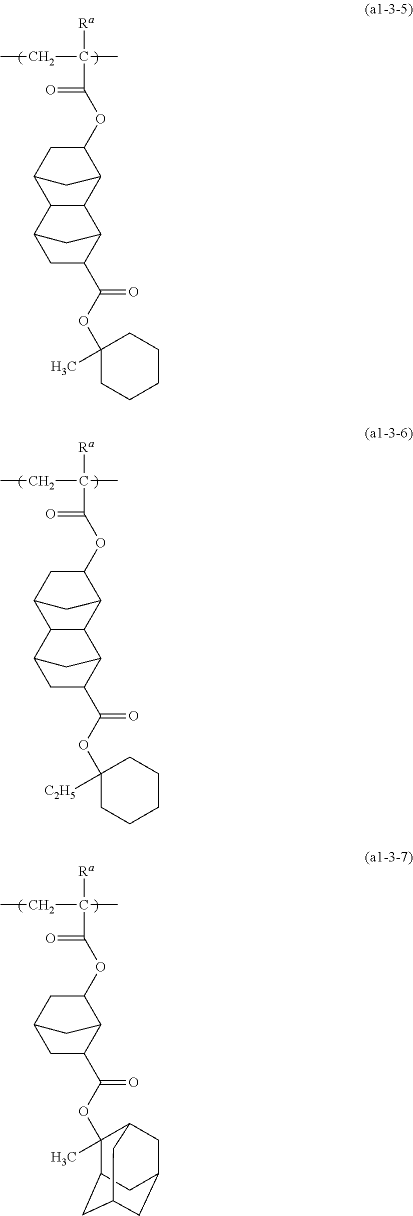

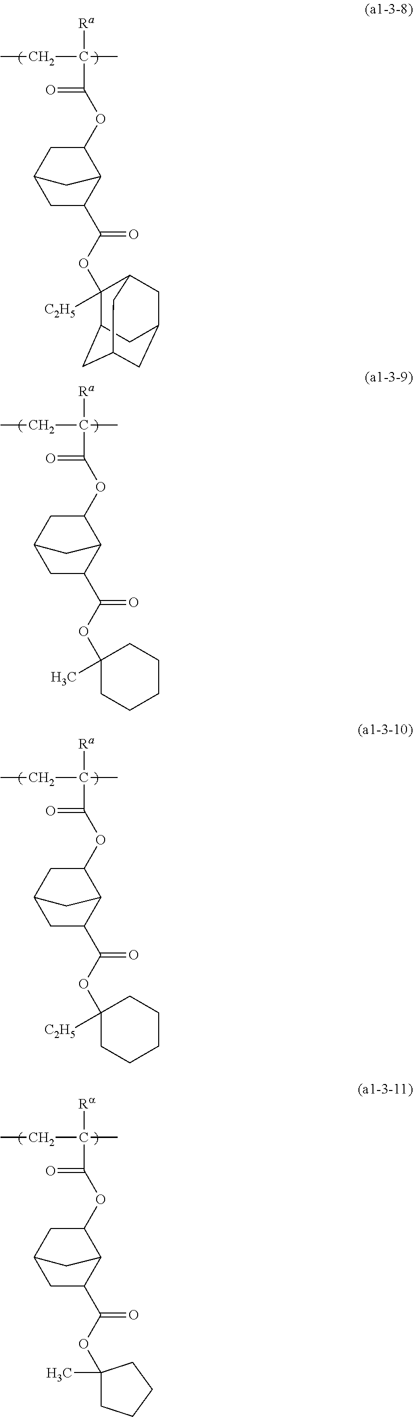

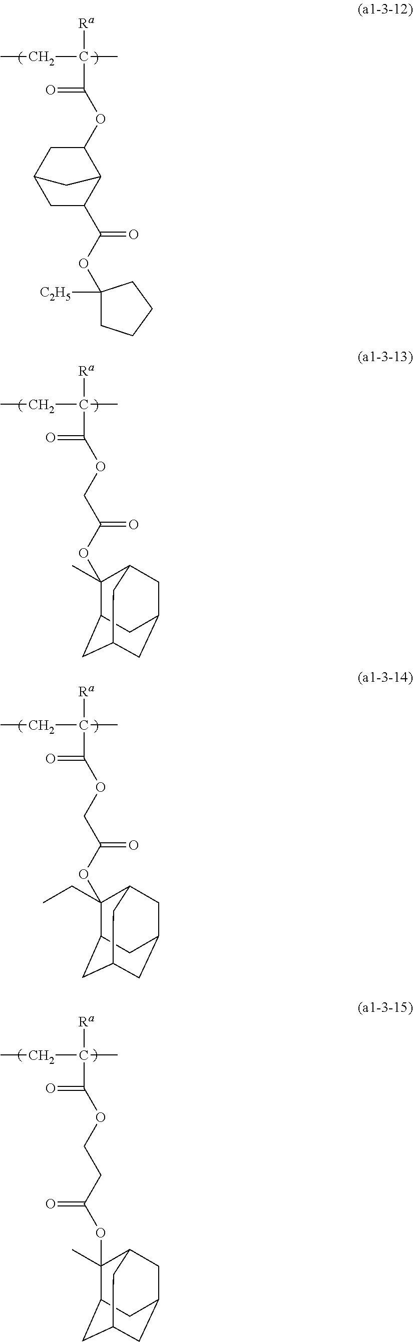

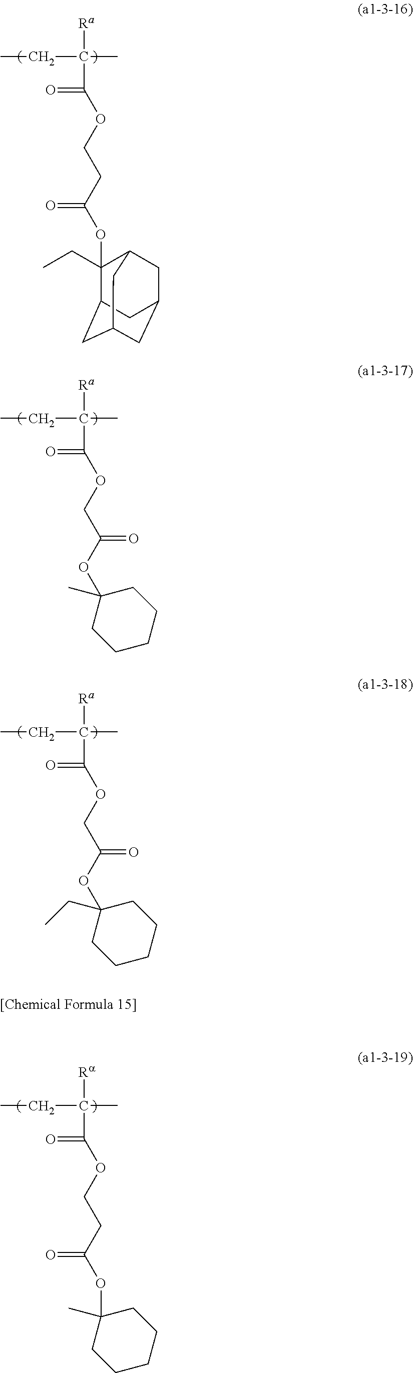

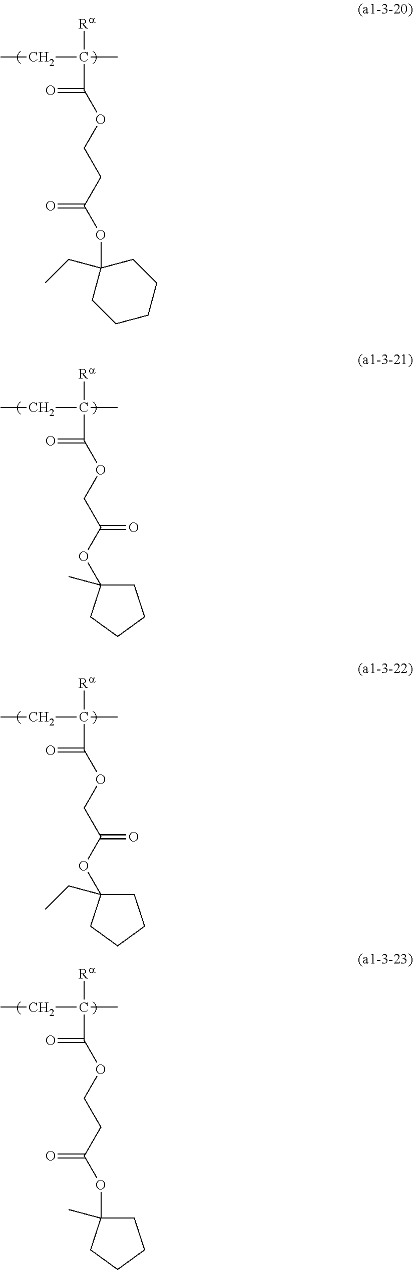

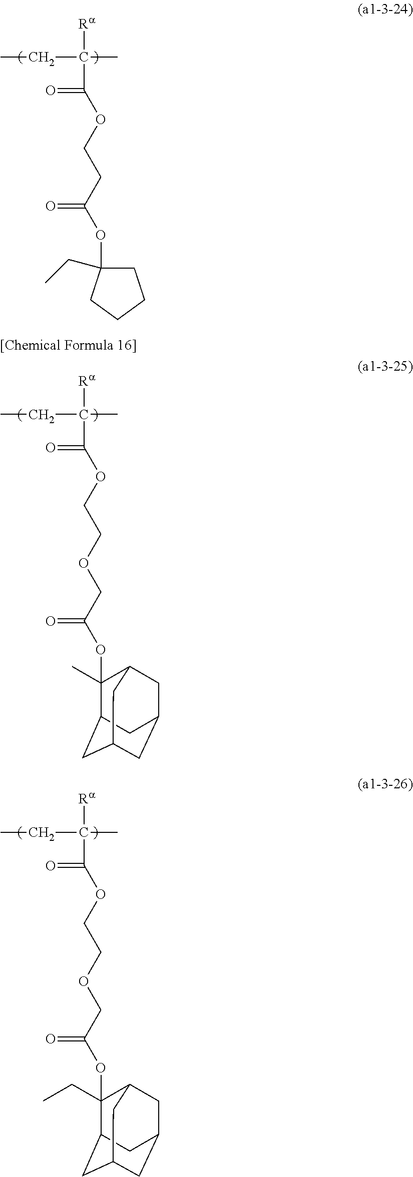

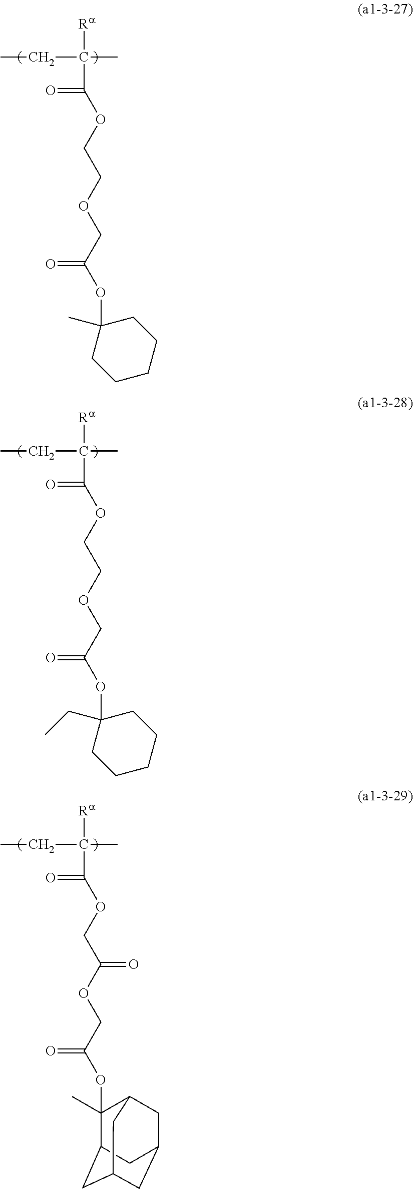

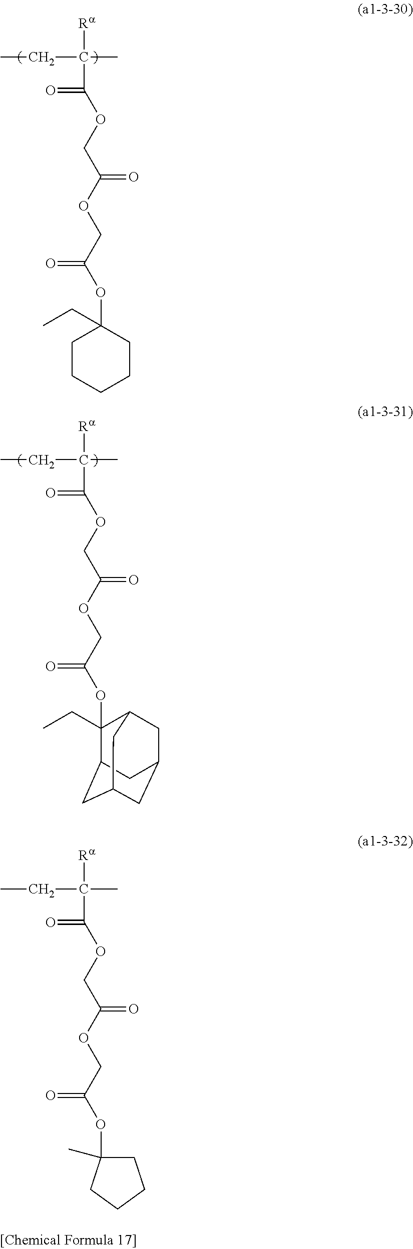

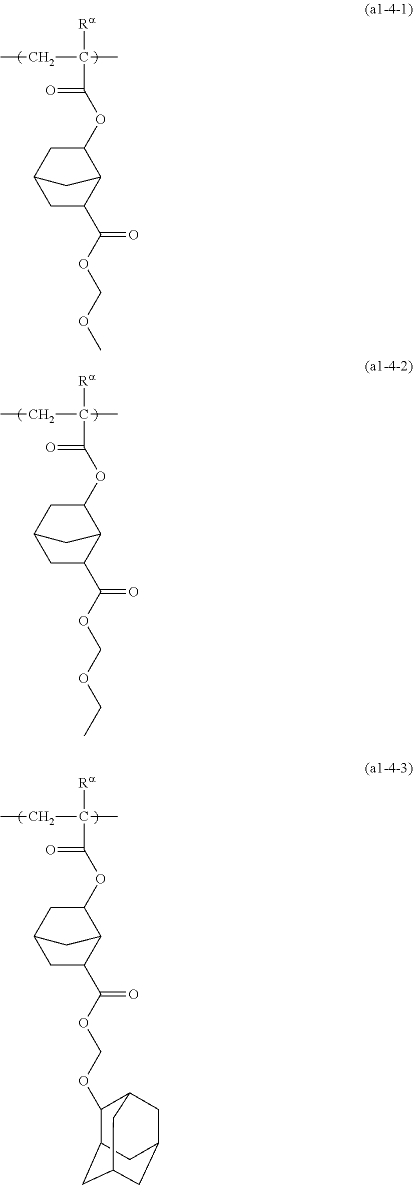

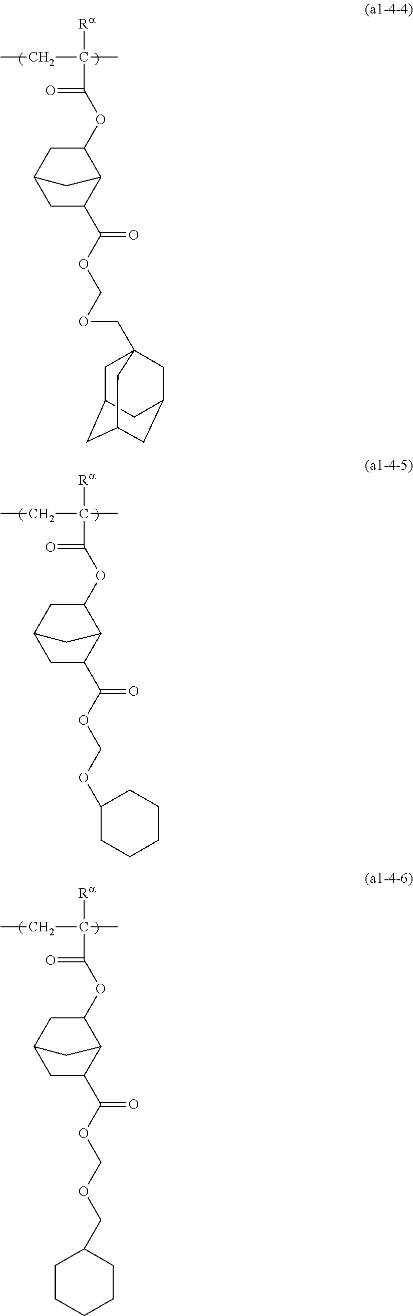

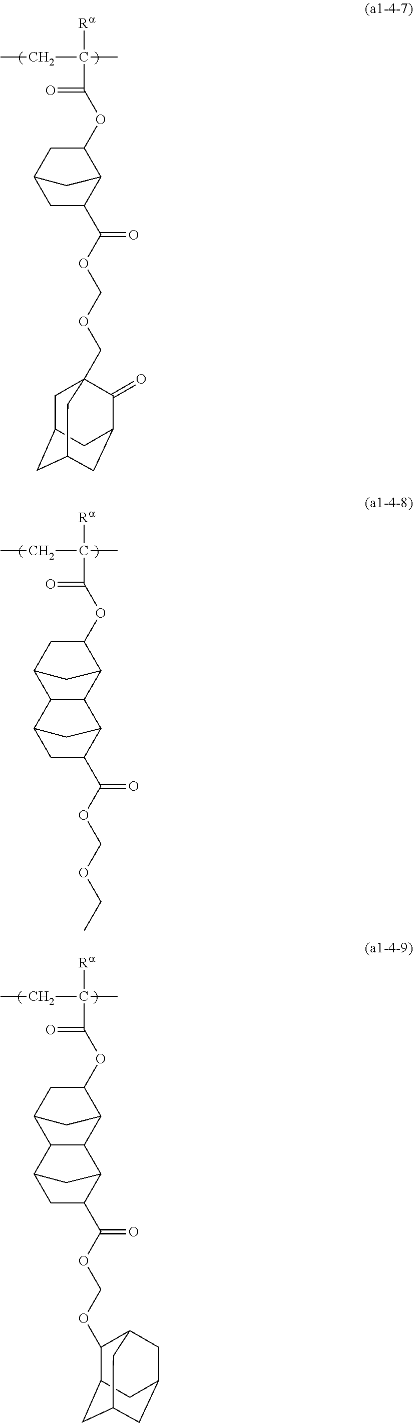

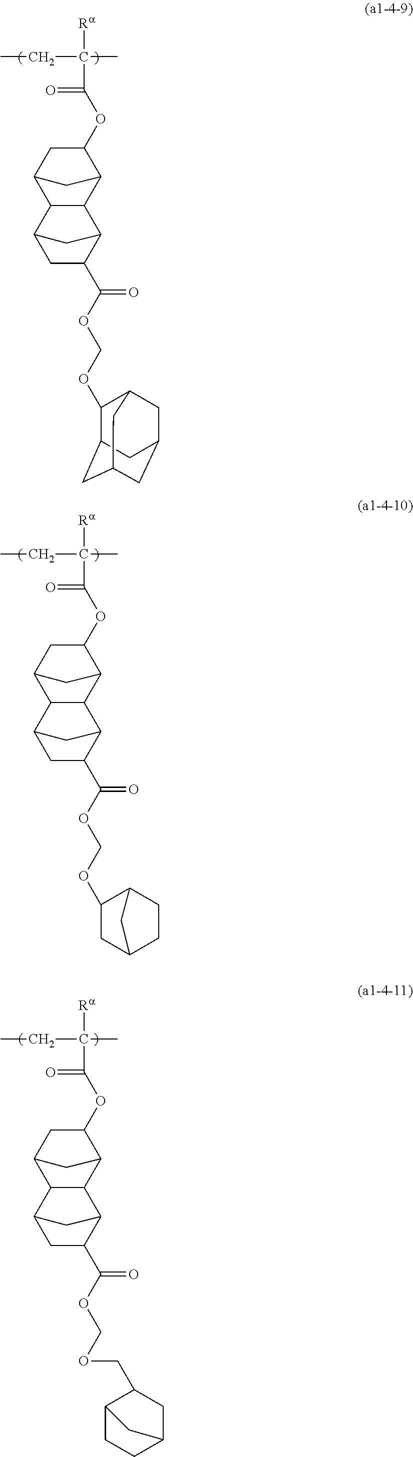

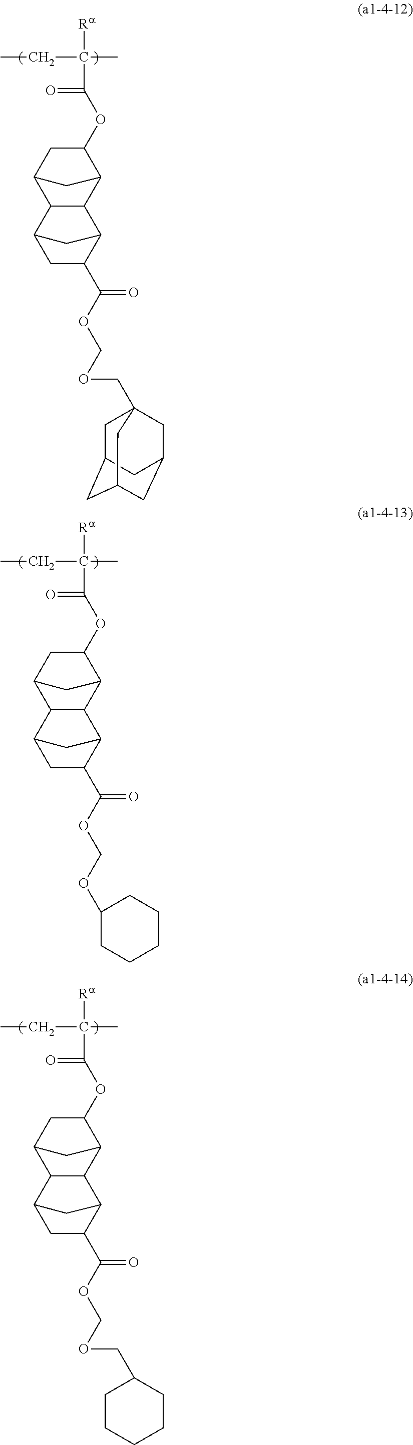

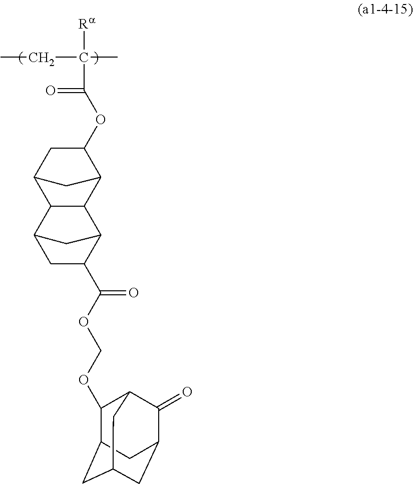

The present invention preferably includes, as the structural unit (a1), at least one structural unit selected from the group consisting of structural units represented by a general formula (a1-0-11) shown below, structural units represented by a general formula (a1-0-12) shown below, structural units represented by a general formula (a1-0-13) shown below, structural units represented by a general formula (a1-0-14) shown below, structural units represented by a general formula (a1-0-15) shown below, and structural units represented by general formula (a1-0-2) shown below.

Among these, at least one structural unit selected from the group consisting of structural units represented by the general formula (a1-0-11), structural units represented by the general formula (a1-0-12), structural units represented by the general formula (a1-0-13), structural units represented by the general formula (a1-0-14), and structural units represented by the general formula (a1-0-15) is particularly desirable.

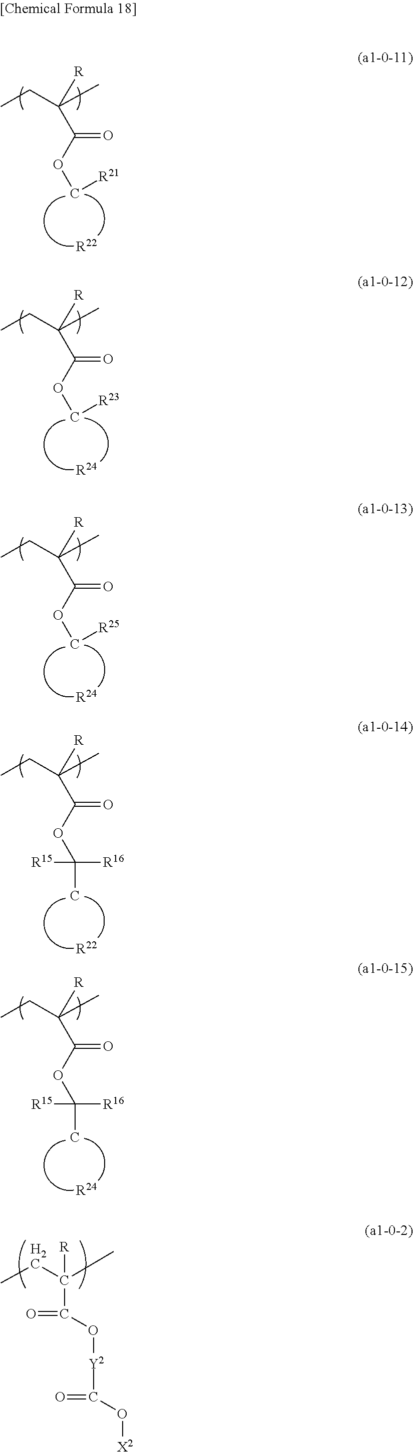

In the above formulas, R represents a hydrogen atom, an alkyl group of 1 to 5 carbon atoms or a halogenated alkyl group of 1 to 5 carbon atoms, R²¹ represents an alkyl group, R²² represents a group that forms an aliphatic monocyclic group together with the carbon atom to which R²² is bonded, R²³ represents a branched alkyl group, R²⁴ represents a group that forms an aliphatic polycyclic group together with the carbon atom to which R²⁴ is bonded, R²⁵ represents a linear alkyl group of 1 to 5 carbon atoms, each of R¹⁵ and R¹⁶ independently represents an alkyl group, Y² represents a divalent linking group, and X² represents an acid-dissociable group.

In each of the above formulas, R, Y² and X² are the same as defined above.

In the formula (a1-0-11), examples of the alkyl group for R²¹ include the same alkyl groups as those described above for R¹⁴ in the formulas (1-1) to (1-9), and a methyl group, ethyl group or isopropyl group is preferred.

In terms of R²², examples of the aliphatic monocyclic group that is formed together with the carbon atom to which R²² is bonded include the monocyclic groups among the aliphatic cyclic groups described above in connection with the tertiary alkyl ester-type acid-dissociable groups. Specific examples include groups in which one or more hydrogen atoms have been removed from a monocycloalkane. The monocycloalkane is preferably a 3- to 11-membered ring, more preferably a 3- to 8-membered ring, still more preferably a 4- to 6-membered ring, and most preferably a 5- or 6-membered ring.

Part of the carbon atoms that constitute the ring of the monocycloalkane may or may not be substituted with an ether group (—O—).

Further, the monocycloalkane may include an alkyl group of 1 to 5 carbon atoms, a fluorine atom, or a fluorinated alkyl group of 1 to 5 carbon atoms as a substituent.

Examples of the R²² group that constitutes the aliphatic monocyclic group include linear alkylene groups which may have an ether group (—O—) interposed between the carbon atoms of the alkylene chain.

Specific examples of the structural unit represented by the formula (a1-0-11) include structural units represented by the above formulas (a1-1-16) to (a1-1-23), (a1-1-27) and (a1-1-31). Among these, structural units represented by a general formula (a1-1-02) shown below, which includes the structural units represented by the above formulas (a1-1-16) and (a1-1-17), the formulas (a1-1-20) to (a1-1-23), and the formulas (a1-1-27), (a1-1-31), (a1-1-32) and (a1-1-33) are preferred. Furthermore, structural units represented by a general formula (a1-1-02′) shown below are also preferred.

In each of the formulas below, h represents an integer of 1 to 4, and is preferably 1 or 2.

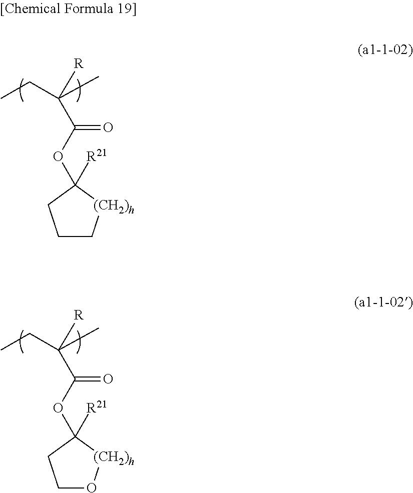

In the formulas, R and R²¹ are each the same as defined above, and h represents an integer of 1 to 4.

In the formula (a1-0-12), examples of the branched alkyl group for R²³ include the same branched alkyl groups as those described above for the alkyl group for R¹⁴ in the formulas (1-1) to (1-9), and an isopropyl group is particularly desirable.

Examples of the aliphatic polycyclic group formed by R²⁴ together with the carbon atom to which R²⁴ is bonded include the polycyclic groups among the aliphatic cyclic groups described above in connection with the tertiary alkyl ester-type acid-dissociable groups.

Specific examples of the structural unit represented by the general formula (a1-0-12) include the structural units represented by the above formula (a1-1-26) and the formulas (a1-1-28) to (a1-1-30).

The structural unit represented by the formula (a1-0-12) is preferably a structural unit in which the aliphatic polycyclic group formed by R²⁴ together with the carbon atom to which R²⁴ is bonded is a 2-adamantyl group, and a structural unit represented by the above formula (a1-1-26) is particularly desirable.

In the formula (a1-0-13), R and R²⁴ are each the same as defined above.

Examples of the linear alkyl group for R²⁵ include the same linear alkyl groups as those described above for the alkyl group for R¹⁴ in the formulas (1-1) to (1-9), and a methyl group or ethyl group is the most desirable.

Specific examples of the structural unit represented by the formula (a1-0-13) include the structural units represented by the formulas (a1-1-1) and (a1-1-2) and the formulas (a1-1-7) to (a1-1-15), which were mentioned above as specific examples of the general formula (a1-1).

The structural unit represented by the formula (a1-0-13) is preferably a structural unit in which the aliphatic polycyclic group formed by R²⁴ together with the carbon atom to which R²⁴ is bonded is a 2-adamantyl group, and a structural unit represented by the above formula (a1-1-1) or (a1-1-2) is particularly desirable.

In the formula (a1-0-14), R and R²² are each the same as defined above. R¹⁵ and R¹⁶ are the same as defined above for R¹⁵ and R¹⁶ respectively in the above general formulas (2-1) to (2-6).

Specific examples of the structural unit represented by the formula (a1-0-14) include the structural units represented by the formulas (a1-1-35) and (a1-1-36), which were mentioned above as specific examples of the general formula (a1-1).

In the formula (a1-0-15), R and R²⁴ are each the same as defined above. R¹⁵ and R¹⁶ are the same as defined above for R¹⁵ and R¹⁶ respectively in the above general formulas (2-1) to (2-6).

Specific examples of the structural unit represented by the formula (a1-0-15) include the structural units represented by the formulas (a1-1-4) to (a1-1-6) and the formula (a1-1-34), which were mentioned above as specific examples of the general formula (a1-1).

Examples of the structural unit represented by the formula (a1-0-2) include structural units represented by the above formulas (a1-3) and (a1-4), and of these, a structural unit represented by the formula (a1-3) is particularly desirable.

The structural unit represented by the formula (a1-0-2) is preferably a structural unit in which Y² in the formula is a group represented by one of the above formulas —Y²¹—O—Y²² or —Y²¹—C(═O)—O—Y²²—.

Preferred examples of such structural units include structural units represented by a general formula (a1-3-01) shown below, structural units represented by a general formula (a1-3-02) shown below, and structural units represented by a general formula (a1-3-03) shown below.

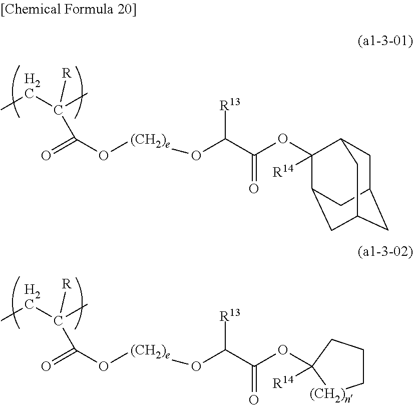

In the formulas, R is the same as defined above, R¹³ represents a hydrogen atom or a methyl group, R¹⁴ represents an alkyl group, e represents an integer of 1 to 10, and n′ represents an integer of 0 to 3.

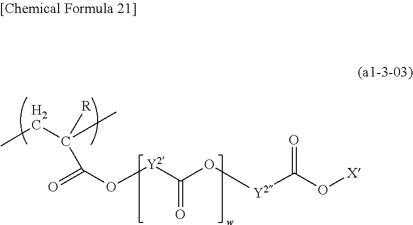

In the formula, R is the same as defined above, each of Y²′ and Y²″ independently represents a divalent linking group, X′ represents an acid-dissociable group, and w represents an integer of 0 to 3.

In the formulas (a1-3-01) and (a1-3-02), R¹³ is preferably a hydrogen atom. R¹⁴ is the same as defined above for R¹⁴ in the formulas (1-1) to (1-9).

e is preferably an integer of 1 to 8, more preferably an integer of 1 to 5, and most preferably 1 or 2.

n′ is preferably 1 or 2, and is most preferably 2.

Specific examples of the structural unit represented by the formula (a1-3-01) include the structural units represented by the above formulas (a1-3-25) and (a1-3-26).

Specific examples of the structural unit represented by the formula (a1-3-02) include the structural units represented by the above formulas (a1-3-27) and (a1-3-28).

Examples of the divalent linking groups for Y²′ and Y²″ in the formula (a1-3-03) include the same groups as those described above for Y² in the general formula (a1-3).

Y²′ is preferably a divalent hydrocarbon group which may have a substituent, is more preferably a linear aliphatic hydrocarbon group, and is still more preferably a linear alkylene group. Among such groups, a linear alkylene group of 1 to 5 carbon atoms is preferable, and a methylene group or ethylene group is the most desirable.

Y²″ is preferably a divalent hydrocarbon group which may have a substituent, is more preferably a linear aliphatic hydrocarbon group, and is still more preferably a linear alkylene group. Among such groups, a linear alkylene group of 1 to 5 carbon atoms is preferable, and a methylene group or ethylene group is the most desirable.

In the formula (a1-3-03), the acid-dissociable group for X′ is the same as defined above, is preferably a tertiary alkyl ester-type acid-dissociable group, is more preferably a group of type (i) described above, in which a substituent is bonded to a carbon atom within the ring structure of a monovalent aliphatic cyclic group that is bonded to the atom adjacent to the acid-dissociable group, thereby forming a tertiary carbon atom on the ring structure of the monovalent aliphatic cyclic group, and is most preferably a group represented by the above general formula (1-1).

w represents an integer of 0 to 3, and is preferably an integer of 0 to 2, more preferably 0 or 1, and most preferably 1.

The structural unit represented by the general formula (a1-3-03) is preferably a structural unit represented by a general formula (a1-3-03-1) or (a1-3-03-2) shown below, and among these, is most preferably a structural unit represented by the formula (a1-3-03-1).

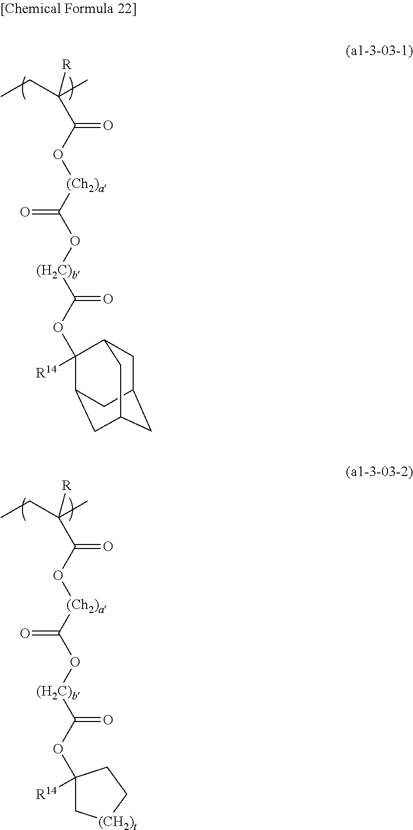

In the formulas, R and R¹⁴ are the same as defined above, a′ represents an integer of 1 to 10, b′ represents an integer of 1 to 10, and t represents an integer of 0 to 3.

In the formulas (a1-3-03-1) and (a1-3-03-2), a′ represents an integer of 1 to 10, and is preferably an integer of 1 to 8, more preferably an integer of 1 to 5, and most preferably 1 or 2.

b′ represents an integer of 1 to 10, and is preferably an integer of 1 to 8, more preferably an integer of 1 to 5, and most preferably 1 or 2.

t is preferably an integer of 1 to 3, and most preferably 1 or 2.

Specific examples of the structural unit represented by the formula (a1-3-03-1) or (a1-3-03-2) include the structural units represented by the above formulas (a1-3-29) to (a1-3-32).

The structural unit (a1) contained within the component (A1) may be a single type of structural unit or a combination of two or more types of structural units.

The amount of the structural unit (a1) within the component (A1), based on the combined total of all the structural units that constitute the component (A1), is preferably within a range from 15 to 70 mol %, more preferably from 15 to 60 mol %, and still more preferably from 20 to 55 mol %.

When the amount of the structural unit (a1) is at least as large as the lower limit of the above range, a pattern can be formed easily using a resist composition prepared from the component (A1), and the lithography properties such as the sensitivity, the resolution and LWR also improve. On the other hand, when the amount of the structural unit (a1) is not more than the upper limit of the above range, a good balance can be more easily achieved with the other structural units.

[Structural Unit (a0)]

The structural unit (a0) is a structural unit derived from an acrylate ester in which the hydrogen atom bonded to the carbon atom on the α-position may be substituted with a substituent and containing an —SO₂-containing cyclic group.

By including an —SO₂-containing cyclic group, the structural unit (a0) enhances the adhesion between the substrate and a resist film formed using a resist composition containing the component (A1). Further, the structural unit (a0) also contributes to improvements in the lithography properties such as the sensitivity, resolution, exposure latitude (EL margin), line width roughness (LWR), line edge roughness (LER) and mask reproducibility.

In this description, the term “—SO₂-containing cyclic group” refers to a cyclic group which includes a ring containing an —SO₂— moiety within the ring structure, and specifically refers to cyclic groups in which the sulfur atom (S) of the —SO₂— forms a part of the ring structure of the cyclic group.

In the —SO₂-containing cyclic group, the ring containing the —SO₂— moiety within the ring structure is counted as the first ring, and groups containing only the first ring are referred to as monocyclic groups, whereas groups containing other ring structures are described as polycyclic groups regardless of the structure of the other rings.

The —SO₂-containing cyclic group may be either monocyclic or polycyclic. The —SO₂-containing cyclic group is preferably a cyclic group containing an —O—

SO₂-moiety within the ring structure, namely a cyclic group containing a sultone ring in which the —O—S— within the —O—SO₂— forms a part of the ring structure of the cyclic group.

The —SO₂-containing cyclic group preferably contains 3 to 30 carbon atoms, more preferably 4 to 20 carbon atoms, still more preferably 4 to 15 carbon atoms, and most preferably 4 to 12 carbon atoms. Here, the number of carbon atoms refers to the number of carbon atoms that constitute the ring structure, and does not include carbon atoms contained within substituents.

The —SO₂-containing cyclic group may be an —SO₂-containing aliphatic cyclic group or an —SO₂-containing aromatic cyclic group. An —SO₂-containing aliphatic cyclic group is preferred.

Examples of the —SO₂-containing aliphatic cyclic group include groups in which at least one hydrogen atom has been removed from an aliphatic hydrocarbon ring in which part of the carbon atoms that constitute the ring structure have been substituted with either —SO₂— or —O—SO₂—. More specific examples include groups in which at least one hydrogen atom has been removed from an aliphatic hydrocarbon ring in which a —

CH₂-moiety that constitutes part of the ring structure has been substituted with an —SO₂-moiety, and groups in which at least one hydrogen atom has been removed from an aliphatic hydrocarbon ring in which a —CH₂—CH₂— moiety that constitutes part of the ring structure has been substituted with an —O—SO₂— moiety.

The alicyclic hydrocarbon group preferably contains 3 to 20 carbon atoms, and more preferably 3 to 12 carbon atoms.

The alicyclic hydrocarbon group may be either polycyclic or monocyclic. As the monocyclic alicyclic hydrocarbon group, groups in which two hydrogen atoms have been removed from a monocycloalkane of 3 to 6 carbon atoms are preferable, and specific examples of such monocycloalkanes include cyclopentane and cyclohexane. As the polycyclic alicyclic hydrocarbon group, groups in which two hydrogen atoms have been removed from a polycycloalkane of 7 to 12 carbon atoms are preferable, and specific examples of such polycycloalkanes include adamantane, norbornane, isobornane, tricyclodecane and tetracyclododecane.

The —SO₂-containing cyclic group may have a substituent. Examples of the substituent include an alkyl group, alkoxy group, halogen atom, halogenated alkyl group, hydroxyl group, oxygen atom (═O), —COOR″, —OC(═O)R″ (wherein R″ represents a hydrogen atom or an alkyl group), hydroxyalkyl group and cyano group.

The alkyl group for the substituent is preferably an alkyl group of 1 to 6 carbon atoms. The alkyl group is preferably a linear or branched group. Specific examples include a methyl group, ethyl group, propyl group, isopropyl group, n-butyl group, isobutyl group, tert-butyl group, pentyl group, isopentyl group, neopentyl group and hexyl group. Among these, a methyl group or ethyl group is preferred, and a methyl group is particularly desirable.

The alkoxy group for the substituent is preferably an alkoxy group of 1 to 6 carbon atoms. The alkoxy group is preferably a linear or branched group. Specific examples include groups in which an oxygen atom (—O—) is bonded to any of the alkyl groups described above as the substituent.

Examples of the halogen atom for the substituent include a fluorine atom, chlorine atom, bromine atom and iodine atom, and a fluorine atom is preferable.

Examples of the halogenated alkyl group for the substituent include groups in which part or all of the hydrogen atoms of an aforementioned alkyl group substituent have each been substituted with an aforementioned halogen atom. A fluorinated alkyl group is preferred as the halogenated alkyl group, and a perfluoroalkyl group is particularly desirable.

In the aforementioned —COOR″ group and —OC(═O)R″ group, R″ preferably represents a hydrogen atom, or a linear, branched or cyclic alkyl group of 1 to 15 carbon atoms.

In those cases where R″ represents a linear or branched alkyl group, the alkyl group preferably contains 1 to 10 carbon atoms, and more preferably 1 to 5 carbon atoms, and is most preferably a methyl group or ethyl group.

In those cases where R″ is a cyclic alkyl group, the cycloalkyl group preferably contains 3 to 15 carbon atoms, more preferably 4 to 12 carbon atoms, and most preferably 5 to 10 carbon atoms. Examples of the cycloalkyl group include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane.

The hydroxyalkyl group for the substituent preferably contains 1 to 6 carbon atoms, and specific examples include groups in which at least one hydrogen atom within an aforementioned alkyl group substituent has been substituted with a hydroxyl group.

More specific examples of the —SO₂-containing cyclic group include groups represented by general formulas (3-1) to (3-4) shown below.

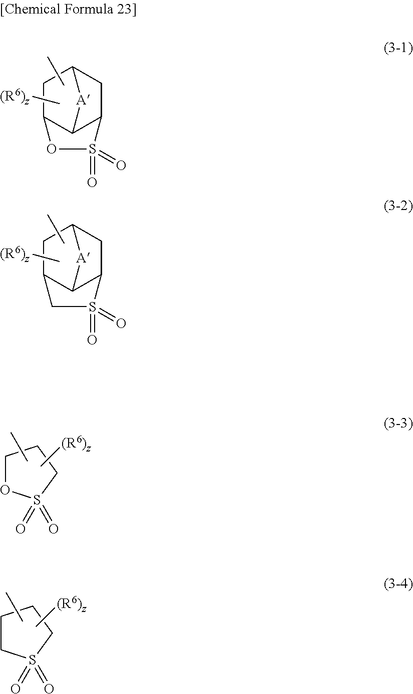

In the formulas, A′ represents an oxygen atom, a sulfur atom, or an alkylene group of 1 to 5 carbon atoms which may contain an oxygen atom or a sulfur atom, z represents an integer of 0 to 2, and R⁶ represents an alkyl group, alkoxy group, halogenated alkyl group, hydroxyl group, —COOR″, —OC(═O)R″, hydroxyalkyl group or cyano group, wherein R″ represents a hydrogen atom or an alkyl group.

In the above general formulas (3-1) to (3-4), A′ represents an oxygen atom (—O—), a sulfur atom (—S—), or an alkylene group of 1 to 5 carbon atoms which may contain an oxygen atom or a sulfur atom.

As the alkylene group of 1 to 5 carbon atoms for A′, a linear or branched alkylene group is preferable, and specific examples include a methylene group, ethylene group, n-propylene group and isopropylene group.

Examples of the alkylene groups which contain an oxygen atom or a sulfur atom include the aforementioned alkylene groups in which —O— or —S— is either bonded to the terminal of the alkylene group or interposed within the alkylene group. Specific examples of such alkylene groups include —O—CH₂—, —CH₂—O—CH₂—, —S—CH₂— and —CH₂—S—CH₂—.

A′ is preferably an alkylene group of 1 to 5 carbon atoms or —O—, more preferably an alkylene group of 1 to 5 carbon atoms, and most preferably a methylene group.

z represents an integer of 0 to 2, and is most preferably 0.

When z is 2, the plurality of R⁶ groups may be the same or different from each other.

Examples of the alkyl group, alkoxy group, halogenated alkyl group, —COOR″ group, —OC(═O)R″ group and hydroxyalkyl group for R⁶ include the same alkyl groups, alkoxy groups, halogenated alkyl groups, —COOR″ groups, —OC(═O)R″ groups and hydroxyalkyl groups as those described above for the substituent which the —SO₂-containing cyclic group may have.

Specific examples of the cyclic groups represented by the general formulas (3-1) to (3-4) are shown below. In the formulas shown below, “Ac” represents an acetyl group.

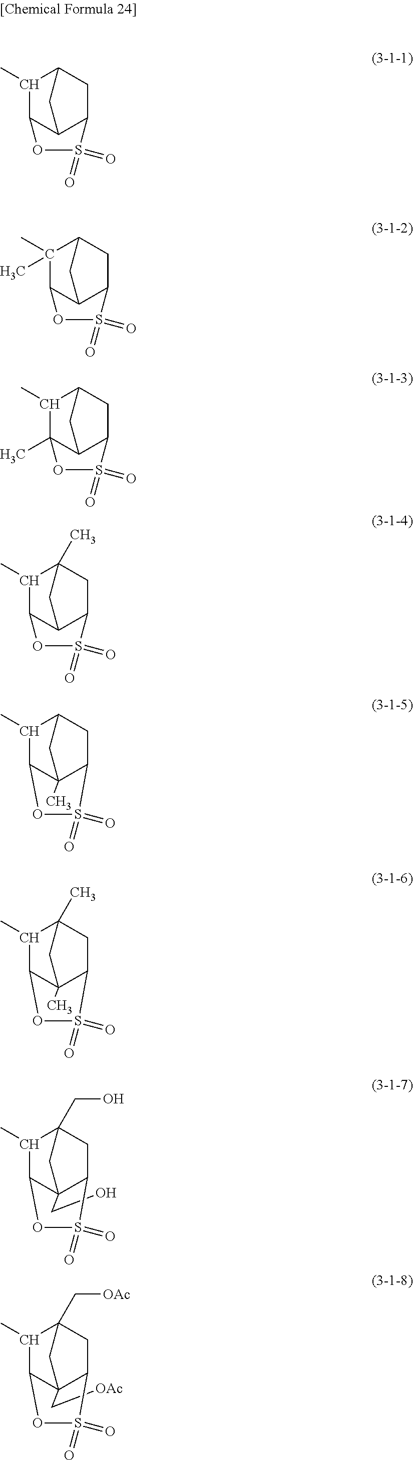

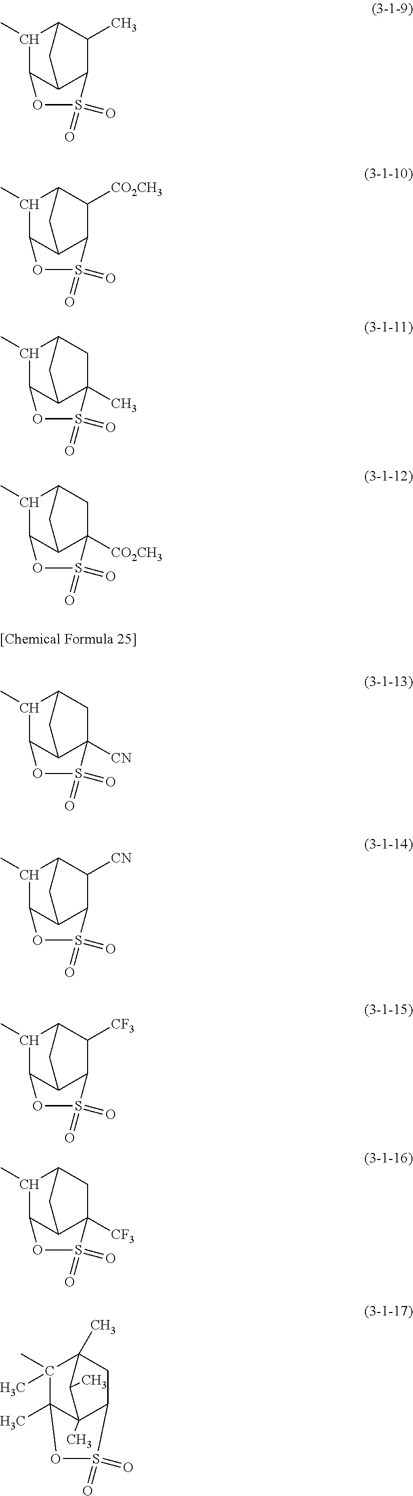

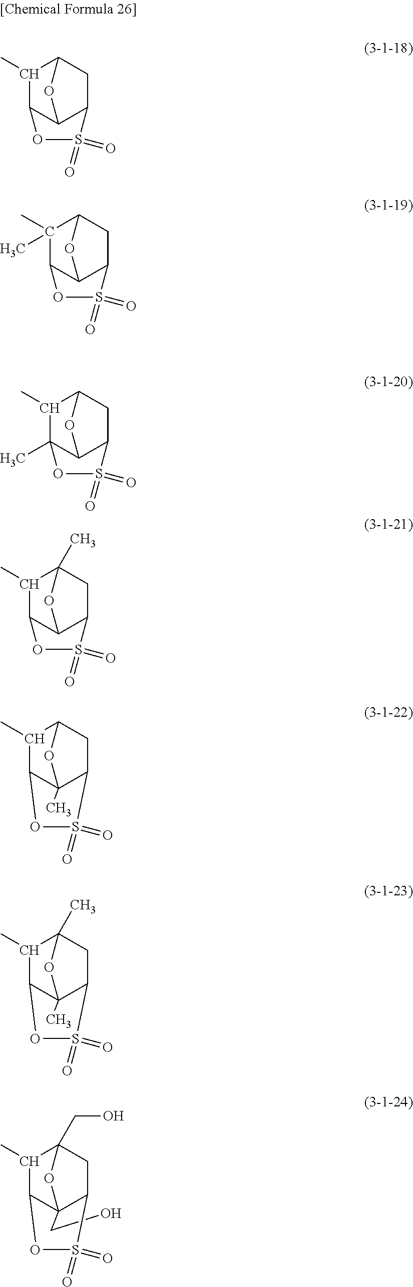

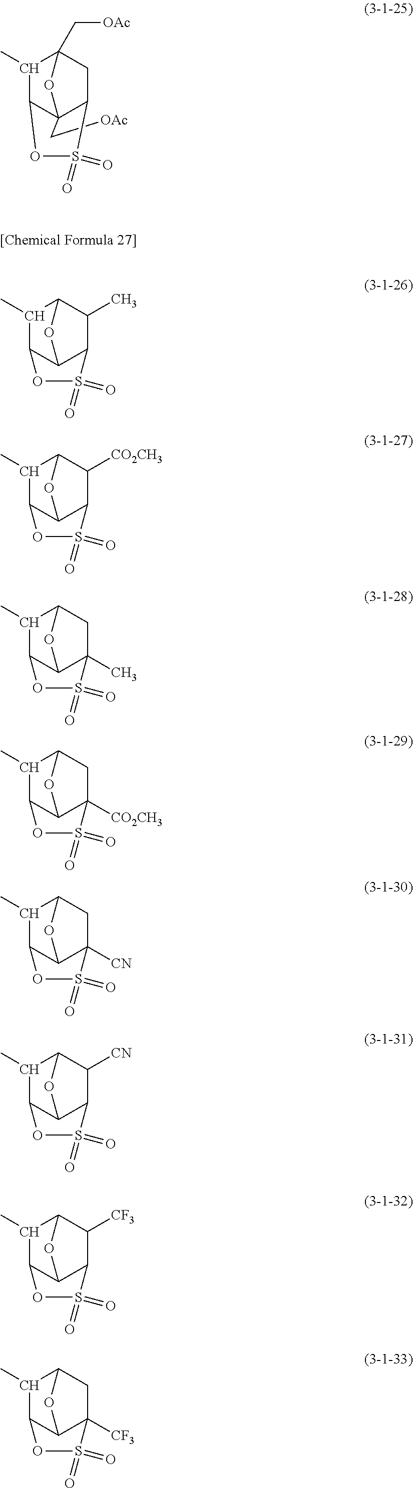

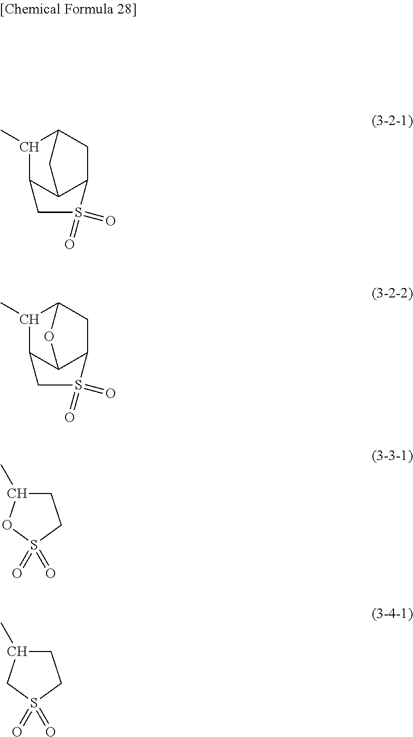

Of the groups shown above, the —SO₂-containing cyclic group is preferably a group represented by the general formula (3-1), more preferably at least one group selected from the group consisting of groups represented by the above chemical formulas (3-1-1), (3-1-18), (3-3-1) and (3-4-1), and most preferably a group represented by the chemical formula (3-1-1).

More specific examples of the structural unit (a0) include structural units represented by a general formula (a0-0) shown below.

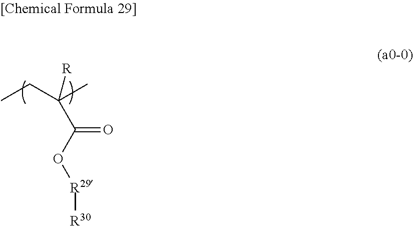

In the formula, R represents a hydrogen atom, an alkyl group of 1 to 5 carbon atoms or a halogenated alkyl group of 1 to 5 carbon atoms, R³⁰ represents an —SO₂-containing cyclic group, and R²⁹′ represents a single bond or a divalent linking group.

In the formula (a0-0), R represents a hydrogen atom, an alkyl group of 1 to 5 carbon atoms, or a halogenated alkyl group of 1 to 5 carbon atoms.

The alkyl group of 1 to 5 carbon atoms for R is preferably a linear or branched alkyl group of 1 to 5 carbon atoms, and specific examples include a methyl group, ethyl group, propyl group, isopropyl group, n-butyl group, isobutyl group, tert-butyl group, pentyl group, isopentyl group and neopentyl group.

The halogenated alkyl group for R is a group in which part or all of the hydrogen atoms of an aforementioned alkyl group of 1 to 5 carbon atoms have each been substituted with a halogen atom. Examples of the halogen atom include a fluorine atom, chlorine atom, bromine atom and iodine atom, and a fluorine atom is particularly desirable.

R is preferably a hydrogen atom, an alkyl group of 1 to 5 carbon atoms, or a fluorinated alkyl group of 1 to 5 carbon atoms, and from the viewpoint of industrial availability, is most preferably a hydrogen atom or a methyl group.

In the formula (a0-0), R³⁰ is the same as the —SO₂-containing cyclic group described above.

R²⁹′ may be either a single bond or a divalent linking group. A divalent linking group is preferable in terms of achieving superior effects for the present invention.

Examples of the divalent linking group for R²⁹′ include the same divalent linking groups as those described above for Y² in the general formula (a1-0-2) within the description relating to the aforementioned structural unit (a1).

The divalent linking group for R²⁹′ is preferably an alkylene group, a divalent alicyclic hydrocarbon group, or a divalent linking group containing a hetero atom. Among these, an alkylene group or a divalent linking group containing an ester linkage (—C(═O)—O—) is preferred.

The alkylene group is preferably a linear or branched alkylene group. Specific examples include the same groups as the linear alkylene groups and branched alkylene groups described above as the aliphatic hydrocarbon group for Y².

As the divalent linking group containing an ester linkage, groups represented by a general formula: —R²⁰—C(═O)—O— (wherein R²⁰ represents a divalent linking group) are preferred. In other words, the structural unit (a0) is preferably a structural unit represented by a general formula (a0-0-1) shown below.

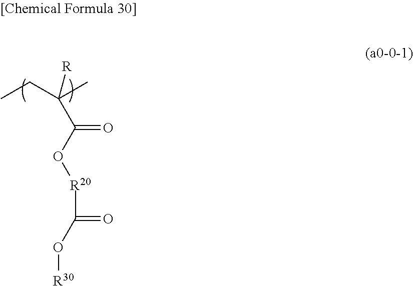

In the formula, R represents a hydrogen atom, an alkyl group of 1 to 5 carbon atoms, or a halogenated alkyl group of 1 to 5 carbon atoms, R²⁰ represents a divalent linking group, and R³⁰ represents an —SO₂-containing cyclic group.

There are no particular limitations on R²⁰, and examples include the same groups as the divalent linking group described above for Y² in the aforementioned general formula (a1-0-2).

As the divalent linking group for R²⁰, a linear or branched alkylene group, a divalent alicyclic hydrocarbon group, or a divalent linking group containing a hetero atom is preferred.

Examples of the linear or branched alkylene group, divalent alicyclic hydrocarbon group, and divalent linking group containing a hetero atom include the same linear or branched alkylene groups, divalent alicyclic hydrocarbon groups, and divalent linking groups containing a hetero atom as those described above as preferred groups for Y².

Of the above groups, a linear or branched alkylene group, or a divalent linking group containing an oxygen atom as a hetero atom is preferred.

As the linear alkylene group, a methylene group or ethylene group is preferred, and a methylene group is particularly desirable.

As the branched alkylene group, an alkylmethylene group or alkylethylene group is preferred, and —CH(CH₃)—, —C(CH₃)₂— and —C(CH₃)₂CH₂— are particularly desirable.

The divalent linking group containing an oxygen atom is preferably a divalent linking group containing an ether linkage or an ester linkage, and is more preferably a group represented by one of the formulas —Y²¹—O—Y²²—, —[Y²¹—C(═O)—O]ₘ′—Y²²— and —Y²¹—O—C(═O)—Y²²—, Y²¹, Y²², and m′ are each the same as defined above.

Of these groups, a group represented by the formula —Y²¹—O—C(═O)—Y²²— is preferred, and a group represented by —(CH₂)_{c}—O—C(═O)—(CH₂)_{d}— is particularly desirable. c represents an integer of 1 to 5, preferably an integer of 1 to 3, and more preferably 1 or 2. d represents an integer of 1 to 5, preferably an integer of 1 to 3, and more preferably 1 or 2.

As the structural unit (a0), a structural unit represented by a general formula (a0-0-11) or (a0-0-12) shown below is preferred, and a structural unit represented by the formula (a0-0-12) is particularly desirable.

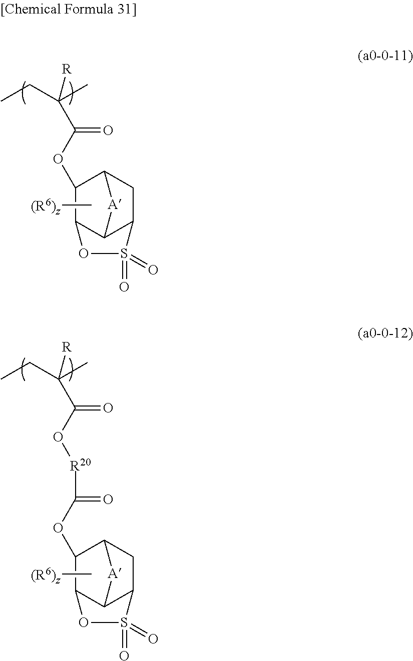

In the formulas, R, A′, R⁶, z and R²⁰ are each the same as defined above.

In the formula (a0-0-11), A′ is preferably a methylene group, an ethylene group, an oxygen atom (—O—) or a sulfur atom (—S—).

R²⁰ is preferably a linear or branched alkylene group, or a divalent linking group containing an oxygen atom. Examples of the linear or branched alkylene group, and the divalent linking group containing an oxygen atom for R²⁰ include the same linear or branched alkylene groups and divalent linking groups containing an oxygen atom as those described above.

As the structural unit represented by formula (a0-0-12), a structural unit represented by a general formula (a0-0-12a) or (a0-0-12b) shown below is particularly desirable.

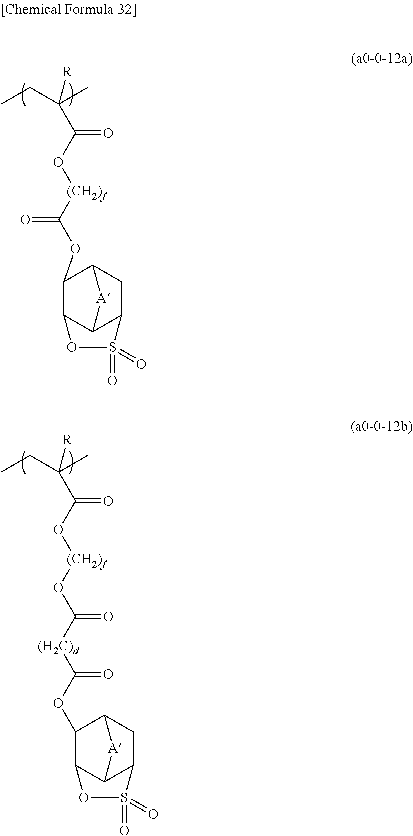

In the formulas, R and A′ are each the same as defined above, c represents an integer of 1 to 5, d represents an integer of 1 to 5, and f represents an integer of 1 to 5 (and preferably an integer of 1 to 3).

The structural unit (a0) contained within the component (A1) may be a single type of structural unit or a combination of two or more types of structural units.

The amount of the structural unit (a0) within the component (A1), based on the combined total of all the structural units that constitute the component (A1), is preferably within a range from 1 to 60 mol %, more preferably from 5 to 55 mol %, still more preferably from 10 to 50 mol %, and most preferably from 15 to 45 mol %, as an amount within this range yields a superior pattern shape for a resist pattern formed using a resist composition containing the component (A1), and the lithography properties such as the EL margin, LWR and mask reproducibility are also excellent.

[Structural Unit (a2)]

The structural unit (a2) is a structural unit derived from an acrylate ester in which the hydrogen atom bonded to the carbon atom on the α-position may be substituted with a substituent and containing a lactone-containing cyclic group.

In this description, the term “lactone-containing cyclic group” refers to a cyclic group including a ring (lactone ring) containing an —O—C(═O)— moiety. The lactone ring is counted as the first ring, and a lactone-containing cyclic group in which the only ring structure is the lactone ring is referred to as a monocyclic group, and groups containing other ring structures are described as polycyclic groups regardless of the structure of the other rings.

When the component (A1) is used in forming a resist film, the lactone-containing cyclic group of the structural unit (a2) is effective in improving the adhesion between the resist film and the substrate, and is also effective in improving the compatibility of the resist with developing solutions containing water (particularly in the case of an alkali developing process).

There are no particular limitations on the structural unit (a2), and an arbitrary structural unit may be used.

Specific examples of lactone-containing monocyclic groups include groups in which one hydrogen atom has been removed from a 4- to 6-membered lactone ring, including a group in which one hydrogen atom has been removed from β-propiolactone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

More specific examples of the structural unit (a2) include structural units represented by general formulas (a2-1) to (a2-5) shown below.

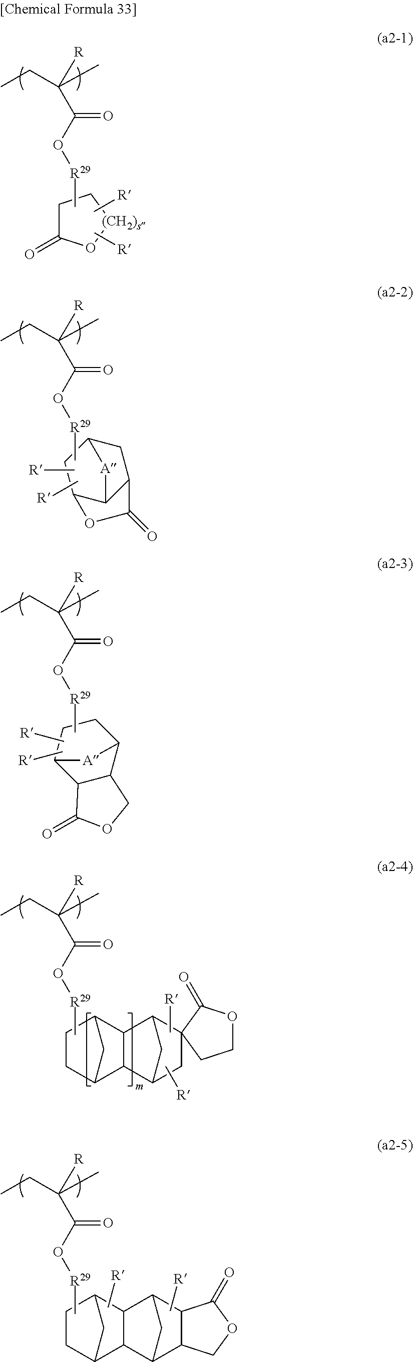

In the above formulas, R represents a hydrogen atom, an alkyl group of 1 to 5 carbon atoms or a halogenated alkyl group of 1 to 5 carbon atoms, each R′ independently represents a hydrogen atom, an alkyl group of 1 to 5 carbon atoms, an alkoxy group of 1 to 5 carbon atoms or —COOR″, wherein R″ represents a hydrogen atom or an alkyl group, R²⁹ represents a single bond or a divalent linking group, s″ represents 0 or an integer of 1 or 2, A″ represents an oxygen atom, a sulfur atom or an alkylene group of 1 to 5 carbon atoms which may contain an oxygen atom or a sulfur atom, and m represents an integer of 0 or 1.

In the general formulas (a2-1) to (a2-5), R is the same as defined above for R in the structural unit (a1).

Examples of the alkyl group of 1 to 5 carbon atoms for R′ include a methyl group, ethyl group, propyl group, n-butyl group and tert-butyl group.

Examples of the alkoxy group of 1 to 5 carbon atoms for R′ include a methoxy group, ethoxy group, n-propoxy group, iso-propoxy group, n-butoxy group and tert-butoxy group.

In terms of factors such as ease of industrial availability, R′ is preferably a hydrogen atom.

R″ preferably represents a hydrogen atom or a linear, branched or cyclic alkyl group of 1 to 15 carbon atoms.

When R″ is a linear or branched alkyl group, the alkyl group preferably contains 1 to 10 carbon atoms, and more preferably 1 to 5 carbon atoms.

When R″ is a cyclic alkyl group, the cycloalkyl group preferably contains 3 to 15 carbon atoms, more preferably 4 to 12 carbon atoms, and most preferably 5 to 10 carbon atoms. Examples include groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane.

A″ is preferably an alkylene group of 1 to 5 carbon atoms, or —O—, is more preferably an alkylene group of 1 to 5 carbon atoms, and is most preferably a methylene group.

R²⁹ represents a single bond or a divalent linking group. Examples of the divalent linking group include the same divalent linking groups as those described above within the description of Y² in the aforementioned general formula (a1-0-2), and of these groups, an alkylene group, an ester linkage (—C(═O)—O—) or a combination thereof is preferred. The alkylene group for the divalent linking group for R²⁹ is preferably a linear or branched alkylene group. Specific examples include the linear alkylene groups and branched alkylene groups among the aliphatic hydrocarbon groups described above for Y².

s″ is preferably an integer of 1 or 2.

Specific examples of the structural units represented by the general formulas (a2-1) to (a2-5) are shown below.

In each of the following formulas, R^{a} represents a hydrogen atom, a methyl group or a trifluoromethyl group.

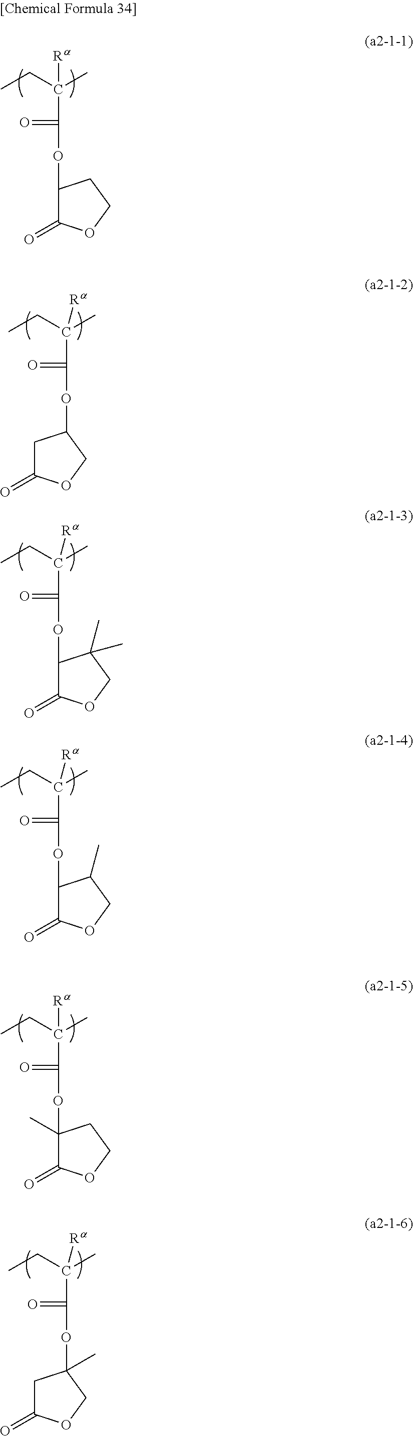

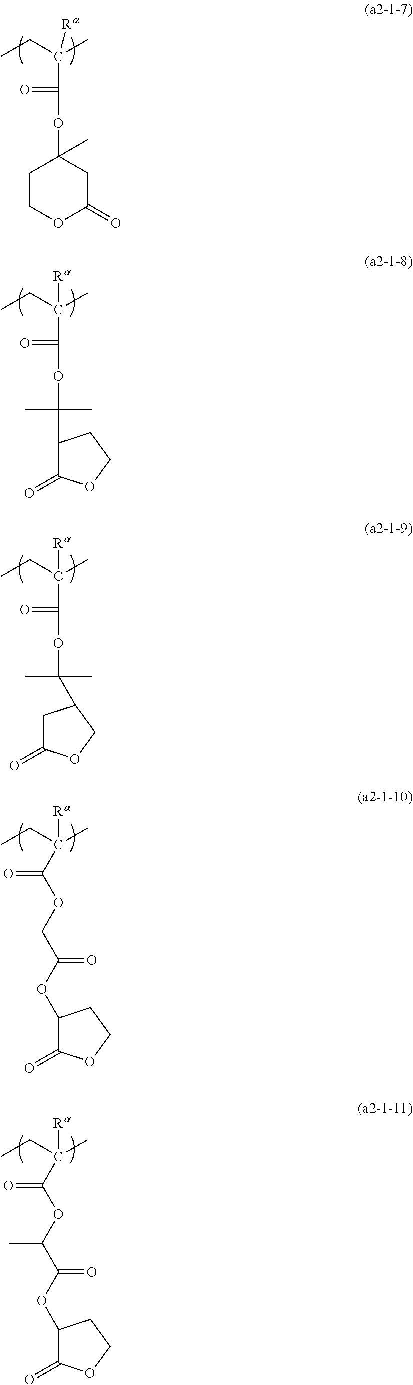

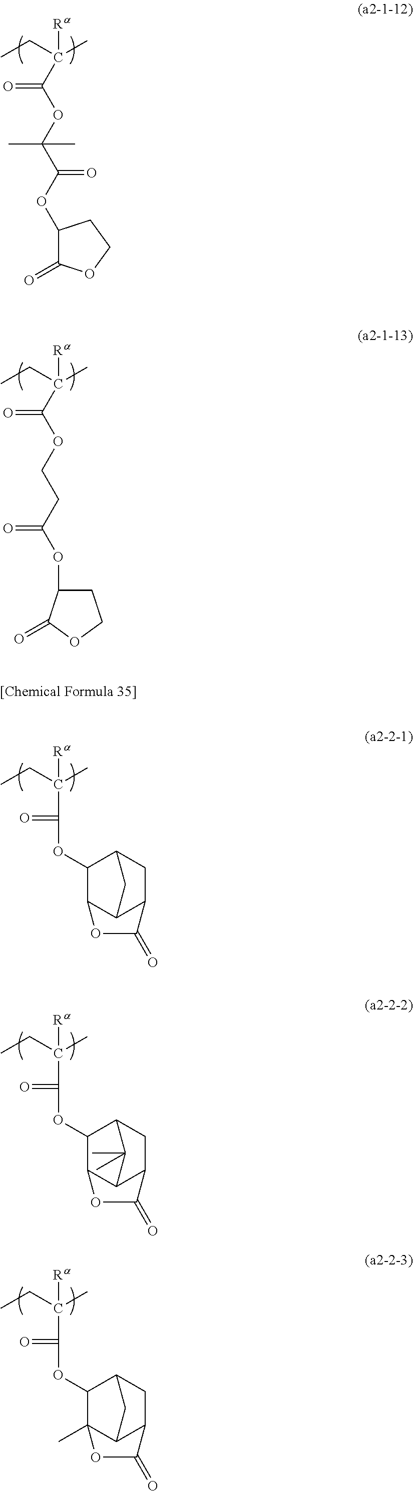

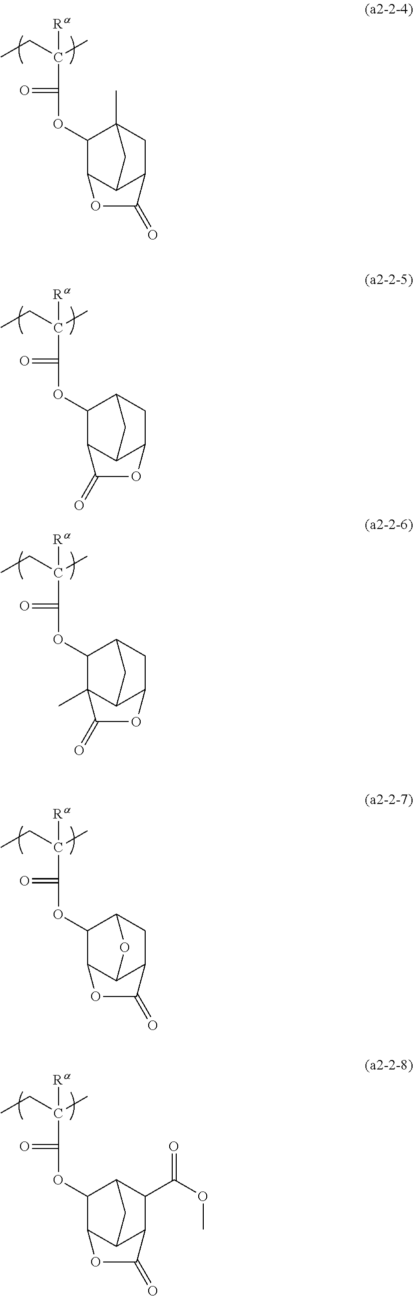

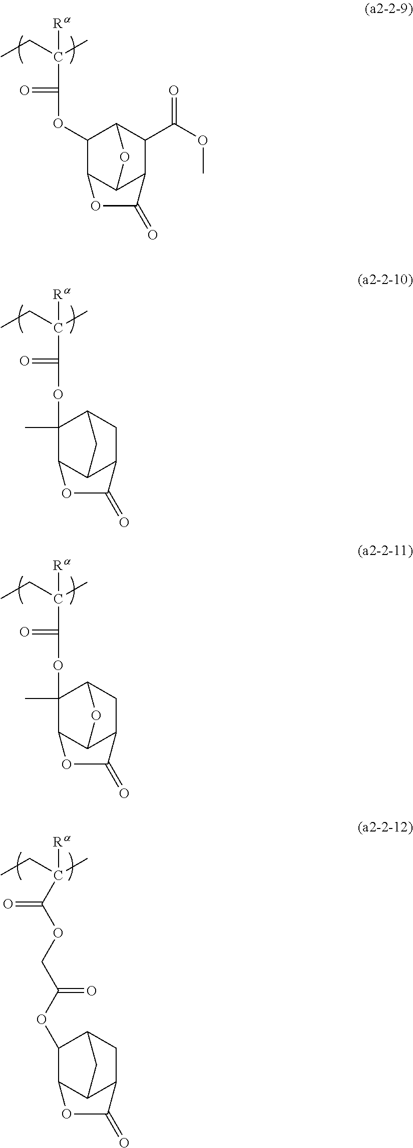

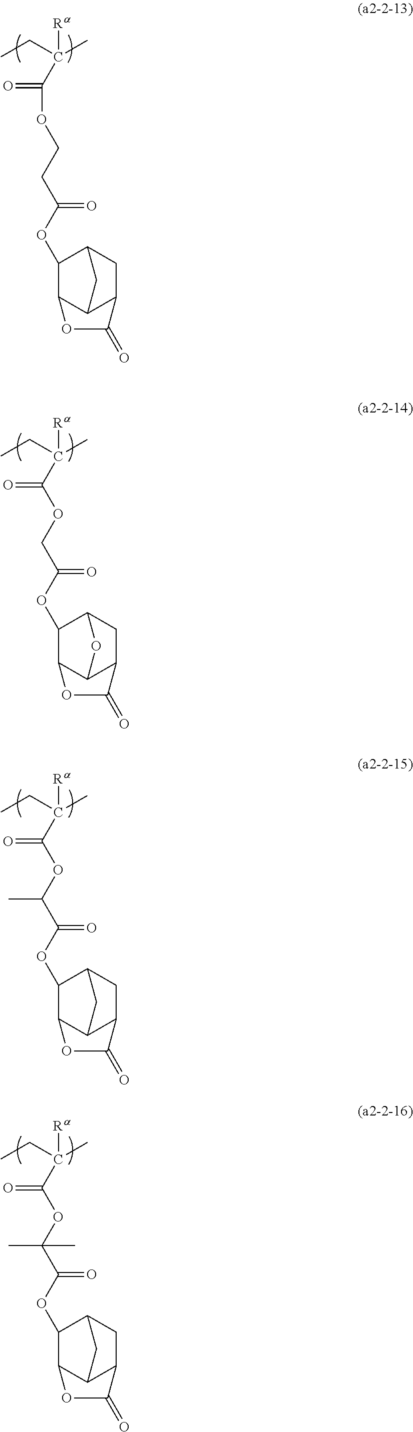

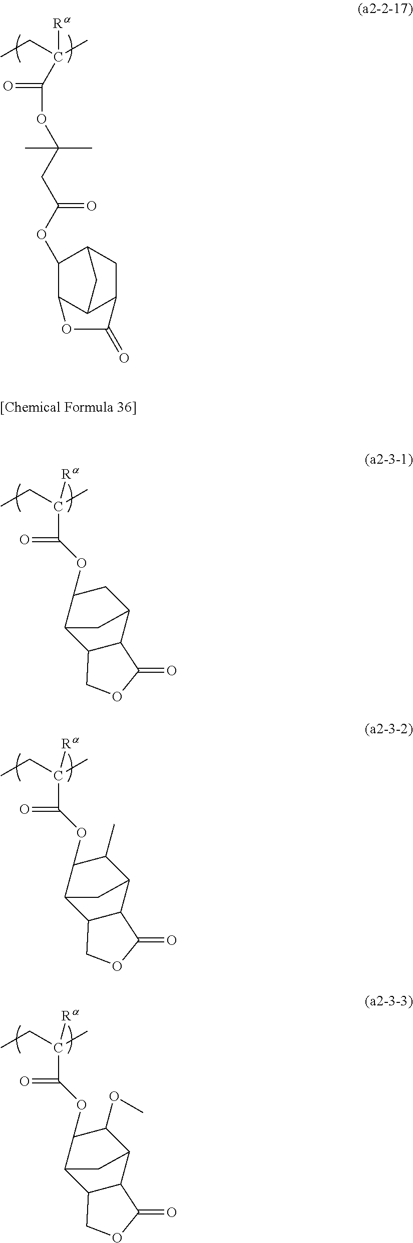

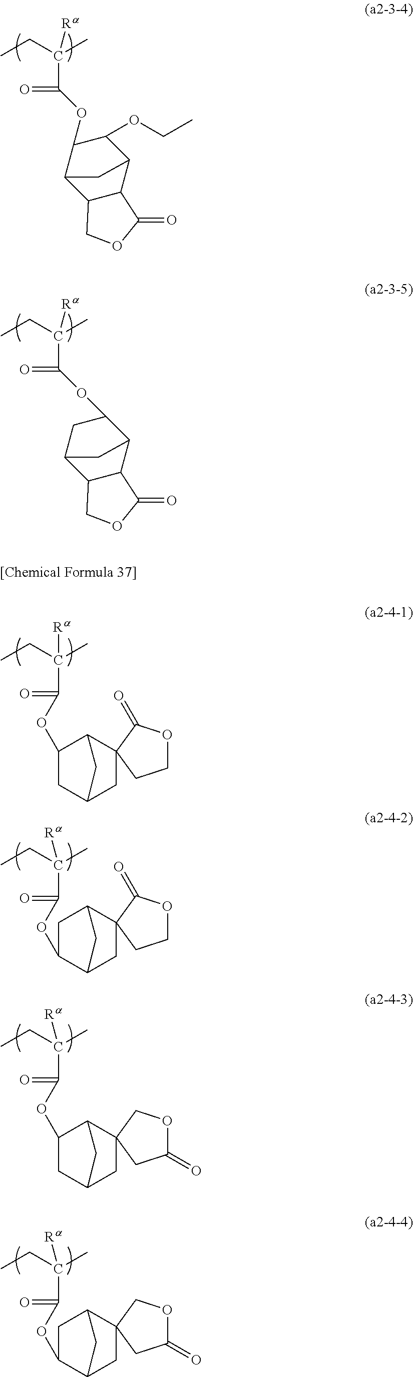

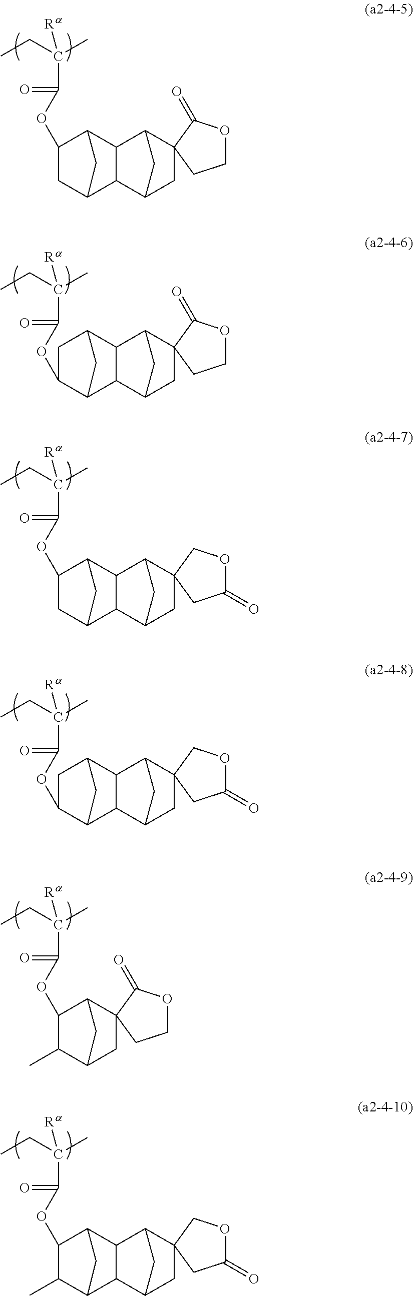

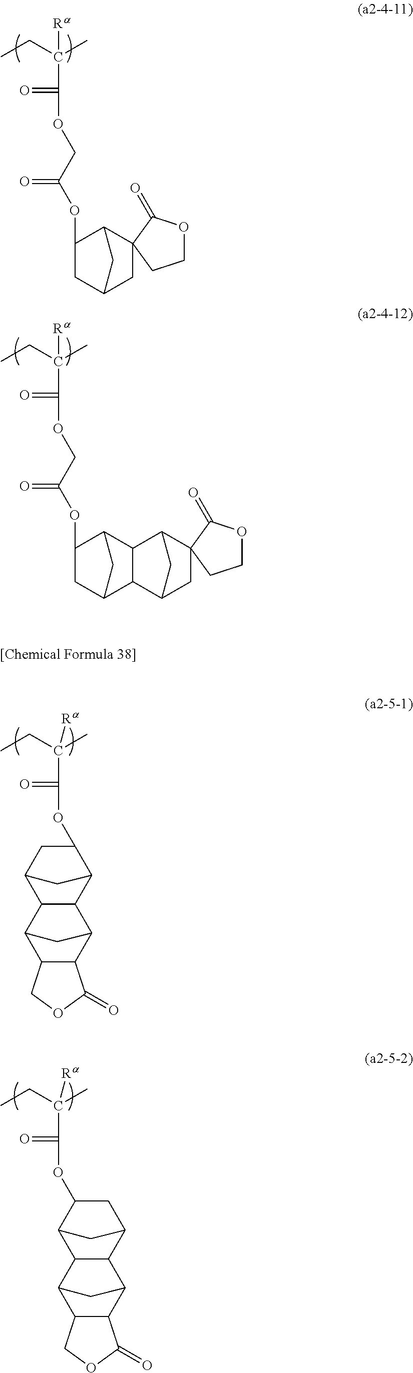

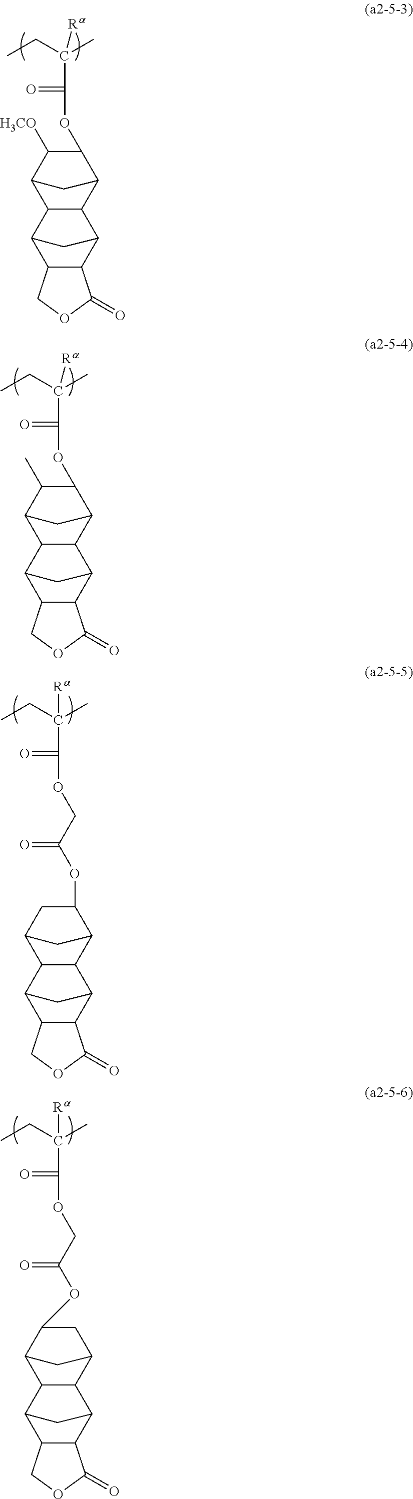

The structural unit (a2) of the component (A1) may be either a single type of structural unit or a combination of two or more types of structural units.

The structural unit (a2) is preferably at least one structural unit selected from the group consisting of structural units represented by the general formulas (a2-1) to (a2-5), and is more preferably at least one structural unit selected from the group consisting of structural units represented by the general formulas (a2-1) to (a2-3). Among these structural units, the structural unit (a2) is preferably at least one structural unit selected from the group consisting of structural units represented by the above chemical formulas (a2-1-1), (a2-1-2), (a2-2-1), (a2-2-7), (a2-3-1) and (a2-3-5).

The amount of the structural unit (a2) within the component (A1), based on the combined total of all the structural units that constitute the component (A1), is preferably within a range from 5 to 60 mol %, more preferably from 10 to 50 mol %, and still more preferably from 10 to 45 mol %.

When the amount of the structural unit (a2) is at least as large as the lower limit of the aforementioned range, the effects achieved be including the structural unit (a2) can be satisfactorily realized. On the other hand, when the amount of the structural unit (a2) is not more than the upper limit of the above range, a good balance can be more readily achieved with the other structural units.

[Structural Unit (a3)]

The structural unit (a3) is a structural unit derived from an acrylate ester in which the hydrogen atom bonded to the carbon atom on the α-position may be substituted with a substituent and containing a polar group-containing aliphatic hydrocarbon group (but excluding structural units that correspond with the aforementioned structural units (a1), (a0) and (a2)).

When the component (A1) includes the structural unit (a3), the hydrophilicity of the component (A) is improved, which contributes to a favorable improvement in the resolution.

Examples of the polar group include a hydroxyl group, cyano group, carboxyl group, or hydroxyalkyl group in which part of the hydrogen atoms of the alkyl group have each been substituted with a fluorine atom, although a hydroxyl group is particularly desirable.

Examples of the aliphatic hydrocarbon group include linear or branched hydrocarbon groups (and preferably alkylene groups) of 1 to 10 carbon atoms, and cyclic aliphatic hydrocarbon groups (cyclic groups). These cyclic groups may be either monocyclic or polycyclic, and can be selected appropriately from the multitude of groups that have been proposed for the resins of resist compositions designed for use with ArF excimer lasers. The cyclic group is preferably a polycyclic group, and a polycyclic group containing 7 to 30 carbon atoms is particularly desirable.

Of the various possibilities, structural units derived from an acrylate ester that includes an aliphatic polycyclic group containing a hydroxyl group, cyano group, carboxyl group or a hydroxyalkyl group in which part of the hydrogen atoms of the alkyl group have each been substituted with a fluorine atom are particularly desirable. Examples of the polycyclic group include groups in which two or more hydrogen atoms have been removed from a bicycloalkane, tricycloalkane, tetracycloalkane or the like. Specific examples include groups in which two or more hydrogen atoms have been removed from a polycycloalkane such as adamantane, norbornane, isobornane, tricyclodecane or tetracyclododecane. Of these polycyclic groups, groups in which two or more hydrogen atoms have been removed from adamantane, norbornane or tetracyclododecane are preferred industrially.

When the hydrocarbon group within the polar group-containing aliphatic hydrocarbon group is a linear or branched hydrocarbon group of 1 to 10 carbon atoms, the structural unit (a3) is preferably a structural unit derived from a hydroxyethyl ester of acrylic acid, whereas when the hydrocarbon group is a polycyclic group, structural units represented by formulas (a3-1), (a3-2) and (a3-3) shown below are preferable.

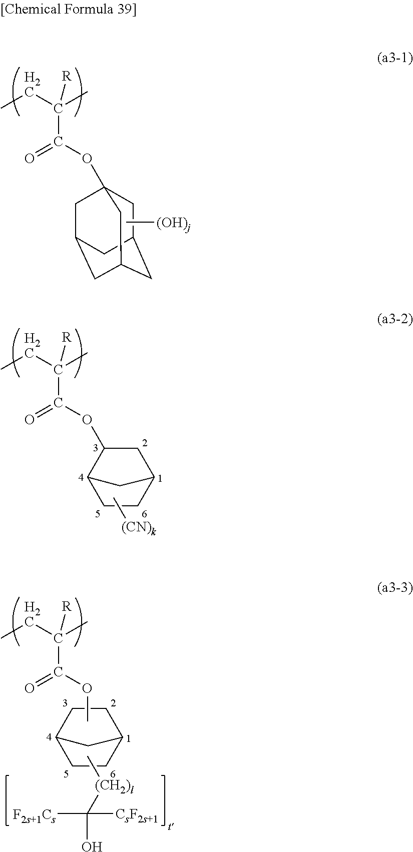

In the formulas, R is the same as defined above, j represents an integer of 1 to 3, k represents an integer of 1 to 3, t′ represents an integer of 1 to 3, 1 represents an integer of 1 to 5, and s represents an integer of 1 to 3.

In the formula (a3-1), j is preferably 1 or 2, and more preferably 1. When j is 2, it is preferable that the hydroxyl groups are bonded to the 3rd and 5th positions of the adamantyl group. When j is 1, it is preferable that the hydroxyl group is bonded to the 3rd position of the adamantyl group.

j is preferably 1, and it is particularly desirable that the hydroxyl group is bonded to the 3rd position of the adamantyl group.

In the formula (a3-2), k is preferably 1. The cyano group is preferably bonded to the 5th or 6th position of the norbornyl group.

In the formula (a3-3), t′ is preferably 1. 1 is preferably 1. s is preferably 1. Further, in the formula (a3-3), it is preferable that a 2-norbornyl group or 3-norbornyl group is bonded to the terminal of the carboxyl group of the acrylic acid. The fluorinated alkyl alcohol is preferably bonded to the 5th or 6th position of the norbornyl group.

The structural unit (a3) contained within the component (A1) may be a single type of structural unit or a combination of two or more types of structural units.

The amount of the structural unit (a3) within the component (A1), based on the combined total of all the structural units that constitute the component (A1), is preferably within a range from 5 to 50 mol %, more preferably from 5 to 40 mol %, and still more preferably from 5 to 25 mol %.

When the amount of the structural unit (a3) is at least as large as the lower limit of the above range, the effects achieved be including the structural unit (a3) can be satisfactorily realized. On the other hand, when the amount of the structural unit (a3) is not more than the upper limit of the above range, a good balance can be more readily achieved with the other structural units.

### [Other Structural Units]

The component (A1) may also include other structural units besides the aforementioned structural units (a1), (a0), (a2) and (a3), as long as the effects of the present invention are not impaired.

As these other structural units, any other structural unit which cannot be classified as one of the above structural units can be used without any particular limitations, and any of the multitude of conventional structural units used within resist resins for ArF excimer lasers or KrF excimer lasers (and particularly for ArF excimer lasers) can be used.

Examples of these other structural units include a structural unit (a4) derived from an acrylate ester in which the hydrogen atom bonded to the carbon atom on the α-position may be substituted with a substituent and containing a non-acid-dissociable aliphatic polycyclic group.

(Structural Unit (a4))

The structural unit (a4) is a structural unit derived from an acrylate ester in which the hydrogen atom bonded to the carbon atom on the α-position may be substituted with a substituent and containing a non-acid-dissociable aliphatic polycyclic group.

In the structural unit (a4), examples of the polycyclic group include the same polycyclic groups as those described above in connection with the structural unit (a1), and any of the multitude of conventional polycyclic groups used within the resin component of resist compositions designed for ArF excimer lasers or KrF excimer lasers (and particularly for ArF excimer lasers) can be used.

In consideration of industrial availability and the like, at least one polycyclic group selected from among a tricyclodecyl group, adamantyl group, tetracyclododecyl group, isobornyl group and norbornyl group is particularly desirable. These polycyclic groups may be substituted with a linear or branched alkyl group of 1 to 5 carbon atoms.

Specific examples of the structural unit (a4) include structural units having structures represented by general formulas (a-4-1) to (a-4-5) shown below.

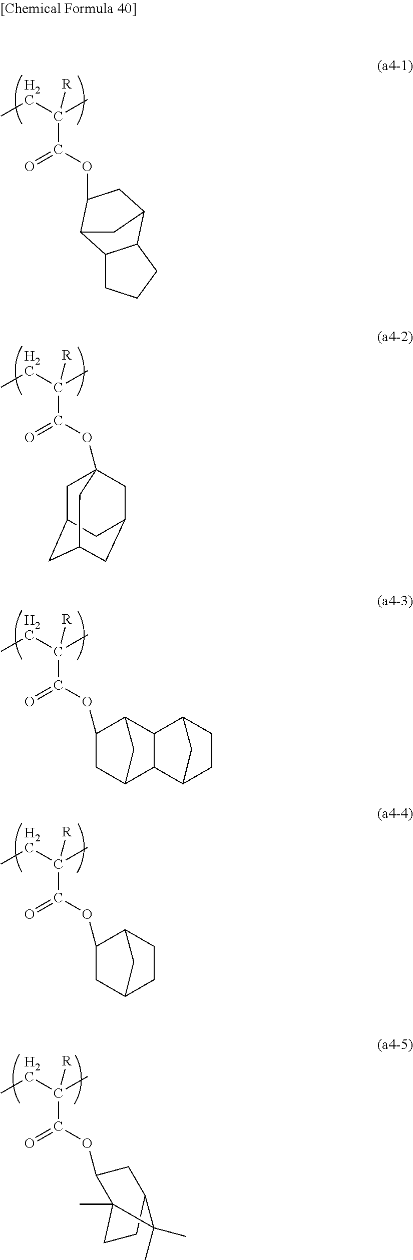

In the formulas, R is the same as defined above.

When the structural unit (a4) is included in the component (A1), the amount of the structural unit (a4), based on the combined total of all the structural units that constitute the component (A1), is preferably within the range from 1 to 30 mol %, and more preferably from 10 to 20 mol %.

In the resist composition of the present invention, the component (A) preferably includes a polymeric compound (A1) containing the structural unit (a1).

Specific examples of the component (A1) include polymeric compounds consisting of the structural units (a1), (a0) and (a3), polymeric compounds consisting of the structural units (a1), (a0), (a2) and (a3).

The weight-average molecular weight (Mw) (the polystyrene equivalent value determined by gel permeation chromatography (GPC)) of the component (A1) is not particularly limited, but is preferably within a range from 1,000 to 50,000, more preferably from 1,500 to 30,000, and most preferably from 2,000 to 20,000. When the weight average molecular weight is not more than the upper limit of the above range, the polymeric compound (A1) exhibits satisfactory solubility in a resist solvent when used as a resist. On the other hand, when the weight average molecular weight is at least as large as the lower limit of the above range, dry etching resistance and the cross-sectional shape of the resist pattern are improved.

Further, although there are no particular limitations on the dispersity (Mw/Mn) of the component (A1), the dispersity is preferably from 1.0 to 5.0, more preferably from 1.0 to 3.0, and most preferably from 1.0 to 2.5. Here, Mn represents the number-average molecular weight.

The component (A1) can be obtained, for example, by a conventional radical polymerization or the like of the monomers corresponding with each of the structural units, using a radical polymerization initiator such as azobisisobutyronitrile (AIBN).

Furthermore, in the component (A1), by using a chain transfer agent such as HS—CH₂—CH₂—CH₂—C(CF₃)₂—OH during the aforementioned polymerization, a —C(CF₃)₂—OH group can be introduced at the terminals of the component (A1). Such a copolymer having an introduced hydroxyalkyl group in which part of the hydrogen atoms of the alkyl group have been substituted with fluorine atoms is effective in reducing developing defects and line edge roughness (LER: unevenness in the side walls of a line pattern).

The monomers used for forming each of the structural units may be commercially available compounds, or may be synthesized using conventional methods.

In the component (A), either a single component (A1) may be used alone, or two or more different types of the component (A1) may be used in combination.

The amount of the component (A1) within the component (A), based on the total weight of the component (A), is preferably not less than 25% by weight, more preferably 50% by weight or more, and still more preferably 75% by weight or more. The amount of the component (A1) may also represent 100% by weight of the component (A). Provided the amount is not less than 25% by weight, various lithography properties such as the MEF and the circularity are improved, and the roughness is reduced.

The component (A) may also include another base component, besides the component (A1), which exhibits changed solubility in a developing solution under the action of acid (hereinafter referred to as “component (A2)”), provided the inclusion of the component (A2) does not impair the effects of the present invention.

In those cases where the resist composition of the present invention is a resist composition that forms a positive-type resist pattern in an alkali developing process and forms a negative-type resist pattern in a solvent developing process, a low molecular weight compound having a molecular weight of at least 500 but less than 2,500, and containing a hydrophilic group and an acid-dissociable group such as those described above in connection with the component (A1) may be used as the component (A2).

Specific examples of the component (A2) include compounds containing a plurality of phenol structures in which part or all of the hydrogen atoms of the hydroxyl groups have each been substituted with an aforementioned acid-dissociable group.

These low molecular weight compounds are preferably low molecular weight phenolic compounds in which part of the hydroxyl group hydrogen atoms have each been substituted with an aforementioned acid-dissociable group. These types of compounds are known, for example, as sensitizers or heat resistance improvers for use in non-chemically amplified g-line or i-line resists, and any of these compounds may be used.

Examples of these low molecular weight phenol compounds include bis(4-hydroxyphenyl)methane, bis(2,3,4-trihydroxyphenyl)methane, 2-(4-hydroxyphenyl)-2-(4′-hydroxyphenyl)propane, 2-(2,3,4-trihydroxyphenyl)-2-(2′,3′,4′-trihydroxyphenyl)propane, tris(4-hydroxyphenyl)methane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-3,5-dimethylphenyl)-3,4-dihydroxyphenylmethane, bis(4-hydroxy-2,5-dimethylphenyl)-3,4-dihydroxyphenylmethane, bis(4-hydroxy-3-methylphenyl)-3,4-dihydroxyphenylmethane, bis(3-cyclohexyl-4-hydroxy-6-methylphenyl)-4-hydroxyphenylmethane, bis(3-cyclohexyl-4-hydroxy-6-methylphenyl)-3,4-dihydroxyphenylmethane, 1-[1-(4-hydroxyphenyl)isopropyl]-4-[1,1-bis(4-hydroxyphenyl)ethyl]benzene, and dimers, trimers, tetramers, pentamers and hexamers of formalin condensation products of phenols such as phenol, m-cresol, p-cresol and xylenol. Needless to say, the low molecular weight phenol compound is not limited to these examples. In particular, a phenol compound having 2 to 6 triphenylmethane structures is preferable, as such compounds yield superior levels of resolution and line width roughness (LWR). There are no particular limitations on the acid-dissociable group, and examples include the groups described above.

In the resist composition of the present invention, the amount of the component (A) may be adjusted in accordance with factors such as the thickness of the resist film that is to be formed.

### <Component (B)>

The component (B) contains a compound (B1) represented by a general formula (b1) shown below (hereinafter referred to as “component (B1)”), and a compound (B2) represented by a general formula (b2) shown below (hereinafter referred to as “component (B2)”).

[Chemical Formula 41]

X-Q¹-Y¹—SO₃⁻A⁺ (b 1)

In the above formula, Q¹ represents a divalent linking group containing an oxygen atom, Y¹ represents an alkylene group of 1 to 4 carbon atoms which may have a substituent or a fluorinated alkylene group of 1 to 4 carbon atoms which may have a substituent, X represents an alicyclic hydrocarbon group of 3 to 30 carbon atoms which may have a substituent, and A⁺ represents an organic cation.

### [Anion Moiety of the Component (B1)]

In the above formula (b1), Q¹ represents a divalent linking group containing an oxygen atom. The divalent linking group may also contain atoms other than the oxygen atom. Examples of these atoms other than the oxygen atom include a carbon atom, hydrogen atom, sulfur atom and nitrogen atom.

Examples of the divalent linking group containing an oxygen atom include non-hydrocarbon, oxygen atom-containing linking groups such as an oxygen atom (an ether bond, —O—), an ester linkage (—C(═O)—O—), an amide linkage (—C(═O)—NH—), a carbonyl group (—C(═O)—), a carbonate linkage (—O—C(═O)—O—), and combinations of these non-hydrocarbon, oxygen atom-containing linking groups with either an alkylene group which may have a substituent or a fluorinated alkylene group which may have a substituent.

The alkylene group or fluorinated alkylene group is preferably a linear or branched group. The alkylene group or fluorinated alkylene group preferably contains 1 to 12 carbon atoms, more preferably 1 to 5 carbon atoms, still more preferably 1 to 4 carbon atoms, and most preferably 1 to 3 carbon atoms.

Specific examples of the alkylene group include a methylene group [—CH₂—], alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—, an ethylene group [—CH₂CH₂—], alkylethylene groups such as —CH(CH₃)CH₂—, —CH(CH₃)CH(CH₃)—, —C(CH₃)₂CH₂— and —CH(CH₂CH₃)CH₂—, a trimethylene group (n-propylene group) [—CH₂CH₂CH₂—], alkyltrimethylene groups such as —CH(CH₃)CH₂CH₂— and —CH₂CH(CH₃)CH₂—, a tetramethylene group [—CH₂CH₂CH₂CH₂—], alkyltetramethylene groups such as —CH(CH₃)CH₂CH₂CH₂— and —CH₂CH(CH₃)CH₂CH₂—, and a pentamethylene group [—CH₂CH₂CH₂CH₂CH₂—].

Examples of the fluorinated alkylene group include groups in which part or all of the hydrogen atoms within an aforementioned alkylene group have each been substituted with a fluorine atom, and specific examples include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—, —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)— and —C(CF₃)₂CH₂—.

Examples of the substituent which the alkylene group or fluorinated alkylene group may have include alkoxy groups of 1 to 4 carbon atoms and a hydroxyl group.

Examples of the divalent linking groups composed of a combination of an above non-hydrocarbon, oxygen atom-containing linking group with either an alkylene group or a fluorinated alkylene group which may have a substituent include —R^{9a}—O—, —R^{9b}—O—C(═O)—, —O—C(═O)—R^{9c}—, —O—R^{9d}—O—C(═O)—, —O—R^{9e}—O—C(═O)—R^{9f}—, —R^{9g}—O—C(═O)—R^{9h}—, —C(═O)—O—R⁹ⁱ—O—C(═O)— and —C(═O)—O—R^{9j}—O—C(═O)—R^{9k}—.

In the above formulas, each of R^{9a} to R^{9k} independently represents an alkylene group or fluorinated alkylene group which may have a substituent. Examples of the alkylene group or fluorinated alkylene group for R^{9a} to R^{9k} include the same groups as those mentioned above. Each of R^{9a} to R^{9k} is preferably an alkylene group.

In the above formula (b1), Y¹ represents an alkylene group of 1 to 4 carbon atoms which may have a substituent or a fluorinated alkylene group of 1 to 4 carbon atoms which may have a substituent.

Examples of the alkylene group of 1 to 4 carbon atoms for Y¹ include those alkylene groups having 1 to 4 carbon atoms among the alkylene groups mentioned above in the description relating to the aforementioned Q¹, and specific examples include a methylene group [—CH₂—], alkylmethylene groups such as —CH(CH₃)—, —CH(CH₂CH₃)—, —C(CH₃)₂—, —C(CH₃)(CH₂CH₃)— and —CH(CH₂CH₂CH₃)—, an ethylene group [—CH₂CH₂—], alkylethylene groups such as —CH(CH₃)CH₂—, —CH(CH₃)CH(CH₃)—, —C(CH₃)₂CH₂— and —CH(CH₂CH₃)CH₂—, a trimethylene group (n-propylene group) [—CH₂CH₂CH₂—], alkyltrimethylene groups such as —CH(CH₃)CH₂CH₂— and —CH₂CH(CH₃)CH₂—, and a tetramethylene group [—CH₂CH₂CH₂CH₂—]. Examples of the fluorinated alkylene group of 1 to 4 carbon atoms for Y¹ include groups in which part or all of the hydrogen atoms within an aforementioned alkylene group of 1 to 4 carbon atoms for Y¹ have each been substituted with a fluorine atom. The fluorinated alkylene group of 1 to 4 carbon atoms is preferably a linear or branched group, and preferably contains 1 to 3 carbon atoms, and more preferably 1 or 2 carbon atoms. Specific examples of these fluorinated alkylene groups include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)— and —C(CF₃)(CF₂CF₃)—, as well as

—CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)— and —C(CF₃)₂CH₂—.

Y¹ is preferably a fluorinated alkylene group of 1 to 4 carbon atoms, and particularly preferably a fluorinated alkylene group in which the carbon atom bonded to the adjacent sulfur atom is fluorinated. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CH₂CF₂—, —CH₂CH₂CF₂—, —CH₂CF₂CF₂—, —CH₂CH₂CH₂CF₂—, —CH₂CH₂CF₂CF₂— and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group for Y¹ may have a substituent.

The expression that the alkylene group or fluorinated alkylene group “may have a substituent” means that part or all of the hydrogen atoms or fluorine atoms in the alkylene group or fluorinated alkylene group may each be substituted, either with an atom other than a hydrogen atom or fluorine atom, or with a group.

Examples of substituents with which the alkylene group or fluorinated alkylene group may be substituted include alkoxy groups of 1 to 4 carbon atoms and a hydroxyl group.

In the above formula (b1), X represents an alicyclic hydrocarbon group of 3 to 30 carbon atoms which may have a substituent.

The alicyclic hydrocarbon group for X may be either a monocyclic hydrocarbon group or a polycyclic hydrocarbon group, but is preferably a polycyclic hydrocarbon group.

The alicyclic hydrocarbon group for X contains 3 to 30 carbon atoms, preferably 5 to 30 carbon atoms, more preferably 5 to 20 carbon atoms, still more preferably 6 to 15 carbon atoms, and most preferably 6 to 12 carbon atoms.

The alicyclic hydrocarbon group may be either saturated or unsaturated, but is preferably saturated.

Examples of the alicyclic hydrocarbon group include groups in which one or more hydrogen atoms have been removed from a monocycloalkane, and groups in which one or more hydrogen atoms have been removed from a polycycloalkane such as a bicycloalkane, tricycloalkane or tetracycloalkane. More specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane.

The alicyclic hydrocarbon group may have a substituent. For example, part of the carbon atoms that constitute the alicyclic hydrocarbon group (for example, the carbon atoms that constitute the ring structure) may be substituted with a substituent containing a hetero atom, or part or all of the hydrogen atoms that constitute the alicyclic hydrocarbon group may each be substituted with a substituent containing a hetero atom.

There are no particular limitations on the above “hetero atom”, provided it is an atom other than a carbon atom or a hydrogen atom. Examples of the hetero atom include a halogen atom, oxygen atom, sulfur atom and nitrogen atom. Examples of the halogen atom include a fluorine atom, chlorine atom, iodine atom and bromine atom.

The substituent containing a hetero atom (hereinafter also referred to as a “hetero atom-containing substituent”) may consist solely of the hetero atom, or may be a group that also contains a group or atom other than the hetero atom.

Specific examples of the hetero atom-containing substituent which may substitute part of the carbon atoms that constitute the alicyclic hydrocarbon group include —O—, —C(═O)—O—, —C(═O)—, —O—C(═O)—O—, —C(═O)—NH—, —NH— (wherein H may be substituted with a substituent such as an alkyl group or an acyl group), —S—, —S(═O)₂— and —S(═O)₂—O—. When the substituent is —NH—, the substituent (alkyl group or acyl group) which may substitute the H preferably contains 1 to 10 carbon atoms, more preferably 1 to 8 carbon atoms, and still more preferably 1 to 5 carbon atoms. These substituents may be included within the ring structure of the alicyclic hydrocarbon group.

Examples of the substituent for substituting part or all of the hydrogen atoms that constitute the alicyclic hydrocarbon group include a halogen atom, alkoxy group, hydroxyl group, —C(═O)—R⁸⁰ (wherein R⁸⁰ represents an alkyl group), —COOR⁸¹ (wherein R⁸¹ represents a hydrogen atom or an alkyl group), —OC(═O)—R⁸² (wherein R⁸² represents a hydrogen atom or an alkyl group), halogenated alkyl group, halogenated alkoxy group, hydroxyalkyl group, oxo group (═O), sulfur atom and sulfonyl group (SO₂).

Examples of the halogen atom for the substituent include a fluorine atom, chlorine atom, bromine atom and iodine atom, and a fluorine atom is preferable.

The alkoxy group for the substituent is preferably an alkoxy group of 1 to 5 carbon atoms, is more preferably a methoxy group, ethoxy group, n-propoxy group, iso-propoxy group, n-butoxy group or tert-butoxy group, and is most preferably a methoxy group or an ethoxy group.

In the groups represented by —C(═O)—R⁸⁰, —COOR⁸¹ and —OC(═O)R⁸² for the aforementioned substituent, the alkyl groups for R⁸⁰ to R⁸² may be linear, branched or cyclic, or may be combinations thereof. The alkyl group preferably contains 1 to 30 carbon atoms. When the alkyl group is a linear or branched group, the alkyl group preferably contains 1 to 20 carbon atoms, more preferably 1 to 17 carbon atoms, still more preferably 1 to 15 carbon atoms, and most preferably 1 to 10 carbon atoms. Specific examples include a methyl group, ethyl group, n-propyl group, isopropyl group, n-butyl group, isobutyl group, n-pentyl group, hexyl group, nonyl group and decyl group. When the alkyl group is a cyclic group (namely, a cycloalkyl group), the cycloalkyl group preferably contains 3 to 30 carbon atoms, more preferably 3 to 20 carbon atoms, still more preferably 3 to 15 carbon atoms, still more preferably 4 to 12 carbon atoms, and most preferably 5 to 10 carbon atoms. The cycloalkyl group may be either monocyclic or polycyclic. Examples include groups in which one or more hydrogen atoms have been removed from a monocycloalkane and groups in which one or more hydrogen atom have been removed from a polycycloalkane such as a bicycloalkane, tricycloalkane or tetracycloalkane. Specific examples of the monocycloalkane include cyclopentane and cyclohexane. Specific examples of the polycycloalkane include adamantane, norbornane, isobornane, tricyclodecane and tetracyclododecane.

Examples of the halogenated alkyl group for the substituent include groups in which part or all of the hydrogen atoms of an aforementioned alkyl group substituent have each been substituted with an aforementioned halogen atom. A fluorinated alkyl group is particularly desirable as the halogenated alkyl group.

Examples of the halogenated alkoxy group for the substituent include groups in which part or all of the hydrogen atoms of an aforementioned alkoxy group substituent have each been substituted with an aforementioned halogen atom. A fluorinated alkoxy group is preferred as the halogenated alkoxy group.

Examples of the hydroxyalkyl group for the substituent include groups in which at least one hydrogen atom within an aforementioned alkyl group substituent has been substituted with a hydroxyl group. The hydroxyalkyl group preferably has 1 to 3 hydroxyl groups, and most preferably one hydroxyl group.

In those cases where the alicyclic hydrocarbon group does not include a hetero atom-containing substituent within the ring structure, the alicyclic hydrocarbon group is preferably a polycyclic group, is more preferably a group in which one or more hydrogen atoms have been removed from a polycycloalkane, and is most preferably a group in which one or more hydrogen atoms have been removed from adamantane.

In those cases where the alicyclic hydrocarbon group includes a hetero atom-containing substituent within the ring structure, the hetero atom-containing substituent is preferably —O—, —C(═O)—O—, —S—, —S(═O)₂— or —S(═O)₂—O—. Specific examples of such alicyclic hydrocarbon groups include groups represented by formulas (L1) to (L6) and (S1) to (S4) shown below.

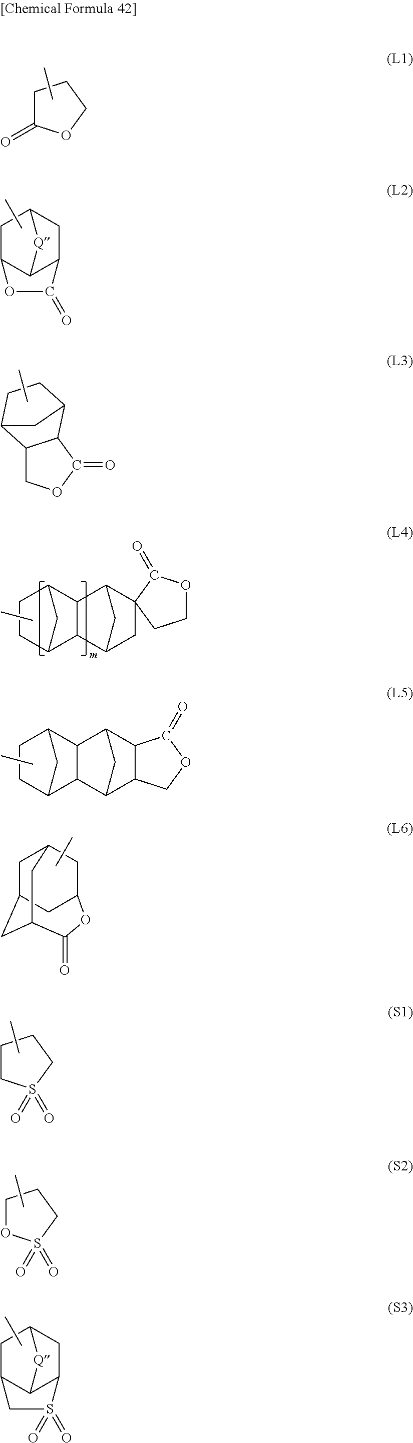

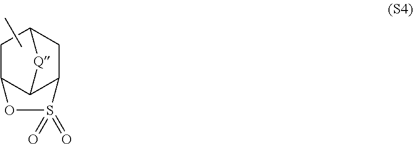

In the above formulas, Q″ represents an alkylene group of 1 to 5 carbon atoms, —O—, —S—, —O—R⁹⁴— or —S—R⁹⁵—, wherein each of R⁹⁴ and R⁹⁵ independently represents an alkylene group of 1 to 5 carbon atoms, and m represents an integer of 0 or 1.

Examples of the alkylene groups for Q″, R⁹⁴ and R⁹⁵ include the same alkylene groups as those described above for R^{9a} to R^{9k} within the above description relating to Q¹.

In these alicyclic hydrocarbon groups, part of the hydrogen atoms bonded to the carbon atoms that constitute the ring structure may each be substituted with a substituent. Examples of this substituent include an alkyl group, alkoxy group, halogen atom, halogenated alkyl group, hydroxyl group or oxo group (═O).

As the alkyl group, an alkyl group of 1 to 5 carbon atoms is preferable, and a methyl group, ethyl group, propyl group, n-butyl group or tert-butyl group is particularly desirable.

Examples of the alkoxy group and the halogen atom include the same groups and atoms as those listed above for the substituent used for substituting part or all of the hydrogen atoms that constitute the alicyclic hydrocarbon group.

Among the various possibilities described above, the anion (X-Q¹-Y¹—SO₃⁻) of the compound represented by the general formula (b1) is preferably an anion in which Q¹ is a divalent linking group containing an ester linkage (—C(═O)—O—) and/or an oxygen atom (ether bond: —O—), and is more preferably an anion in which Q¹ is a divalent linking group containing an ester linkage, or a divalent linking group containing an ether bond but not containing an ester linkage.

Examples of the divalent linking group containing an ester linkage include the groups —R^{9b}—O—C(═O)—, —O—C(═O)—R^{9c}—, —O—R^{9d}—O—C(═O)—, —O—R^{9e}—O—C(═O)—R^{9f}—, —R^{9g}—O—C(═O)—R^{9h}—, —C(═O)—O—R⁹ⁱ—O—C(═O)— and —C(═O)—O—R^{9j}—O—C(═O)—R^{9k}— mentioned above within the description relating to Q¹, and a lone ester linkage. R^{9b} to R^{9k} are preferably alkylene groups.

Examples of the divalent linking group containing an ether bond but not containing an ester linkage include the group —R^{9a}—O— mentioned above within the description relating to Q¹, and a lone ether linkage. R^{9a} is preferably an alkylene group.

More preferred examples of the anion in which Q¹ is a divalent linking group containing an ester linkage (—C(═O)—O—) include anions represented by a general formula (11) shown below.

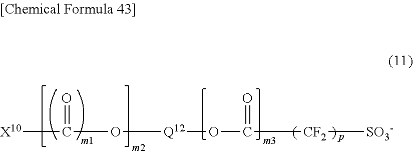

In the formula (11), X¹⁰ represents an alicyclic hydrocarbon group of 3 to 30 carbon atoms which may have a substituent, Q¹² represents a single bond or an alkylene group, p represents an integer of 1 to 4, and each of m1 to m3 represents 0 or 1, provided that neither m2+m3 nor m1+m3 equals zero.

In the formula (11), X¹⁰ is the same as defined for X in the above formula (b1).

X¹⁰ is preferably an aliphatic cyclic group that includes a hetero atom-containing substituent within the ring structure.

Examples of the alkylene group for Q¹² include the same alkylene groups as those mentioned above for R^{9a} to R^{9k} within the description relating to Q¹.

Q¹² is preferably a single bond or a methylene group, and is most preferably a single bond.

Each of m1 to m3 represents 0 or 1. However, neither m2+m3 nor m1+m3 must equal zero. In other words, m2+m3 and m1+m3 must both equal 1 or 2. For example, when m3=0, m2 is 1 and m1 is 1.

p is preferably an integer of 1 to 3, and more preferably 1 or 2.

Preferred examples of anions in which Q¹ within the above general formula (b1) represents either a divalent linking group containing an ester linkage or a divalent linking group containing an ether bond but not containing an ester linkage include anions represented by general formulas (11a) to (11d) shown below.

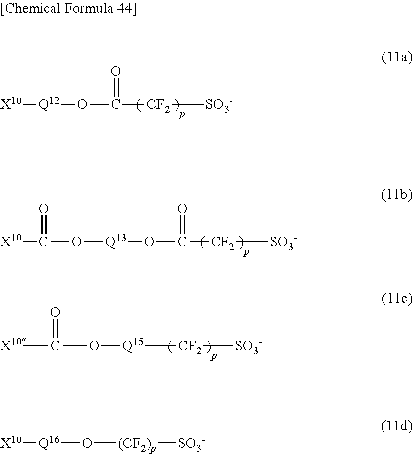

In the formula (11a), X¹⁰, Q¹² and a are each the same as defined above, in the formula (11b), X¹⁰ and p are each the same as defined above, and Q¹³ represents an alkylene group, in the formula (11c), X^{10″} represents an aliphatic cyclic group of 3 to 30 carbon atoms which may have a substituent, Q¹⁵ represents an alkylene group which may have a substituent, and p is the same as defined above, and in the formula (11d), X¹⁰ and p are each the same as defined above, and Q¹⁶ represents an alkylene group.

In the formula (11a), X¹⁰, Q¹² and p are the same as defined above for X¹⁰, Q¹² and p in the formula (11).

In the formula (11b), X¹⁰ and p are the same as defined above for X¹⁰ and p in the formula (11).

Examples of the alkylene group for Q¹³ include the same alkylene groups as those described above for R^{9a} to R^{9k} within the above description relating to Q¹.

In the formula (11c), p is the same as defined above for p in the formula (11).

Examples of the aliphatic cyclic group for X^{10″} include the same groups as the alicyclic hydrocarbon groups described above for X, and an adamantyl group is particularly desirable. The alicyclic hydrocarbon group may have a substituent. Examples of the substituent include the same substituents as those mentioned above, within the description relating to the alicyclic hydrocarbon group, for substituting part or all of the hydrogen atoms of the alicyclic hydrocarbon group.

Examples of the alkylene group for Q¹⁵ include the same alkylene groups as those described above for R^{9a} to R^{9k} within the above description relating to Q¹. Q¹⁵ is preferably a linear or branched alkylene group. The alkylene group preferably has a main chain containing 1 to 12 carbon atoms. This number of carbon atoms within the main chain is more preferably 1 to 5, still more preferably 1 to 3, and most preferably 1. In other words, Q¹⁵ is most preferably a methylene group or alkylmethylene group.

The alkyl group within the alkylmethylene group is preferably an alkyl group of 1 to 5 carbon atoms.

The alkylene group may have a substituent. Examples of the substituent include the same substituents that the alicyclic hydrocarbon group may have within the above description relating to the alicyclic hydrocarbon group for X, and of these, a halogen atom is preferable, and a fluorine atom is particularly desirable.

In the formula (11d), X¹⁰ and p are the same as defined above for X¹⁰ and p in the formula (11).

Examples of the alkylene group for Q¹⁶ include the same alkylene groups as those described above for R^{9a} to R^{9k} within the above description relating to Q¹. As the alkylene group, an alkylene group of 1 to 5 carbon atoms is particularly desirable.

Preferred examples of the anions represented by the above general formulas (11a) to (11d) include anions represented by general formulas (b1-a1) to (b1-a6) shown below.

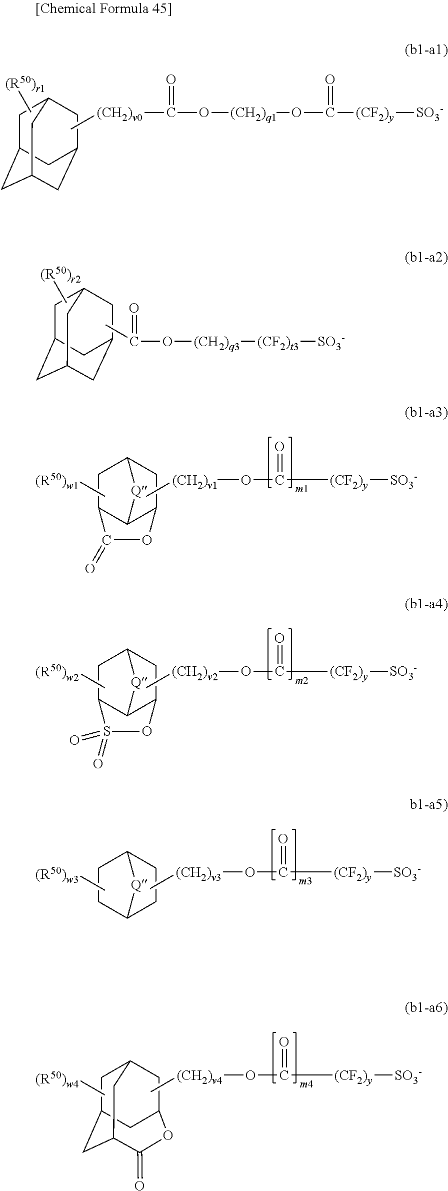

In the above formulas, y represents an integer of 1 to 3, q1 represents an integer of 1 to 5, q3 represents an integer of 1 to 12, t3 represents an integer of 1 to 3, each of r1 and r2 independently represents an integer of 0 to 3, R⁵⁰ represents a substituent, each of m1 to m4 independently represents 0 or 1, each of v0 to v4 independently represents an integer of 0 to 3, each of w1 to w4 independently represents an integer of 0 to 3, and Q″ is the same as defined above.

Examples of the substituent for R⁵⁰ include the same substituents as those mentioned above, within the description of X, for substituting part or all of the hydrogen atoms of the alicyclic hydrocarbon group.

When the subscripts (r1, r2, and w1 to w4) appended to R⁵⁰ represent an integer of 2 or more, the corresponding plurality of R⁵⁰ groups within the compound may be the same or different from each other.

### [Cation Moiety of the Component (B1)]

In the above formula (b1), A⁺ represents an organic cation.

There are no particular limitations on A⁺, and any of the cation moieties proposed for acid generators for use within conventional chemically amplified resists may be used.

Examples of preferred cation moieties include the cation moieties of onium salt acid generators such as iodonium salts and sulfonium salts. Specific examples of such cation moieties include the cations represented by general formulas (b-c1) and (b-c2) shown below. Of these, a cation represented by the formula (b-c1) is preferred.

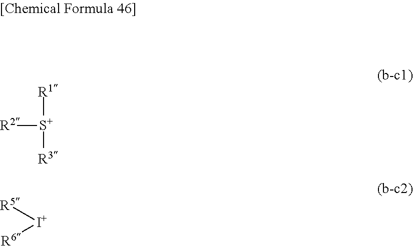

In the formulas, each of R¹″ to R³″ independently represents an aryl group, alkyl group or alkenyl group which may have a substituent, wherein two of R¹″ to R³″ may be bonded to each other to form a ring together with the sulfur atom in the formula, and each of R⁵″ and R⁶″ independently represents an aryl group, alkyl group or alkenyl group which may have a substituent.

In the formula (b-c1), each of R¹″ to R³″ independently represents an aryl group, alkyl group or alkenyl group which may have a substituent. Two of R¹″ to R³″ may be bonded to each other to form a ring together with the sulfur atom in the formula.

Examples of the aryl group for R¹″ to R³″ include unsubstituted aryl groups of 6 to 20 carbon atoms, and substituted aryl groups in which part or all of the hydrogen atoms of an aforementioned unsubstituted aryl group have each been substituted with a substituent.

The unsubstituted aryl group for R¹″ to R³″ is preferably an aryl group of 6 to 10 carbon atoms because such groups enable lower cost synthesis. Specific examples include a phenyl group and a naphthyl group.

Examples of the substituent within the substituted aryl group for R¹″ to R³″ include an alkyl group, alkoxy group, halogen atom, hydroxyl group, oxo group (═O), aryl group, alkoxyalkyloxy group, alkoxycarbonylalkyloxy group, —C—(=O)—O—R⁶′, —O—C(═O)—R⁷′ and —O—R⁸′.

The alkyl group as the substituent for the substituted aryl group is preferably an alkyl group having 1 to 5 carbon atoms, and most preferably a methyl group, ethyl group, propyl group, n-butyl group or tert-butyl group.

The alkoxy group as the substituent for the substituted aryl group is preferably an alkoxy group having 1 to 5 carbon atoms, and most preferably a methoxy group, ethoxy group, n-propoxy group, iso-propoxy group, n-butoxy group or tert-butoxy group.

The halogen atom as the substituent for the substituted aryl group is preferably a fluorine atom.

Examples of the aryl group as the substituent for the substituted aryl group include the same aryl groups as those described above for R¹″ to R³″, and of these, aryl groups of 6 to 20 carbon atoms are preferred, aryl groups of 6 to 10 carbon atoms are more preferred, and a phenyl group or a naphthyl group is particularly desirable.

Examples of the alkoxyalkyloxy group as the substituent for the substituted aryl group include groups represented by the general formula shown below.)

—O—C(R⁴⁷)(R⁴⁸)—O—R⁴⁹

In this formula, each of R⁴⁷ and R⁴⁸ independently represents a hydrogen atom or a linear or branched alkyl group, and R⁴⁹ represents an alkyl group.

The alkyl group for R⁴⁷ and R⁴⁸ preferably has 1 to 5 carbon atoms and may be either linear or branched, is preferably an ethyl group or a methyl group, and is most preferably a methyl group.

It is preferable that at least one of R⁴⁷ and R⁴⁸ is a hydrogen atom, and it is particularly desirable that either one of R⁴⁷ and R⁴⁸ is a hydrogen atom and the other is a hydrogen atom or a methyl group.

The alkyl group for R⁴⁹ preferably has 1 to 15 carbon atoms, and may be linear, branched or cyclic.

The linear or branched alkyl group for R⁴⁹ preferably has 1 to 5 carbon atoms, and examples thereof include a methyl group, ethyl group, propyl group, n-butyl group or tert-butyl group.

The cyclic alkyl group for R⁴⁹ preferably has 4 to 15 carbon atoms, more preferably 4 to 12 carbon atoms, and most preferably 5 to 10 carbon atoms. Specific examples include groups in which one or more hydrogen atoms have been removed from a monocycloalkane or a polycycloalkane such as a bicycloalkane, tricycloalkane or tetracycloalkane, which may or may not be substituted with an alkyl group of 1 to 5 carbon atoms, a fluorine atom or a fluorinated alkyl group. Examples of the monocycloalkane include cyclopentane and cyclohexane. Examples of the polycycloalkane include adamantane, norbornane, isobornane, tricyclodecane and tetracyclododecane. Among these, groups in which one or more hydrogen atoms have been removed from adamantane are preferable.

Examples of the alkoxycarbonylalkyloxy group as the substituent for the substituted aryl group include groups represented by the general formula shown below.

—O—R⁵⁵—C(═O)—O—R⁵⁶

In this formula, R⁵⁵ represents a linear or branched alkylene group, and R⁵⁶ represents a tertiary alkyl group.

The linear or branched alkylene group for R⁵⁵ preferably has 1 to 5 carbon atoms, and examples include a methylene group, ethylene group, trimethylene group, tetramethylene group and 1,1-dimethylethylene group.

Examples of the tertiary alkyl group for R⁵⁶ include a 2-methyl-2-adamantyl group, 2-ethyl-2-adamantyl group, 1-methyl-1-cyclopentyl group, 1-ethyl-1-cyclopentyl group, 1-methyl-1-cyclohexyl group, 1-ethyl-1-cyclohexyl group, 1-(1-adamantyl)-1-methylethyl group, 1-(1-adamantyl)-1-methylpropyl group, 1-(1-adamantyl)-1-methylbutyl group, 1-(1-adamantyl)-1-methylpentyl group, 1-(1-cyclopentyl)-1-methylethyl group, 1-(1-cyclopentyl)-1-methylpropyl group, 1-(1-cyclopentyl)-1-methylbutyl group, 1-(1-cyclopentyl)-1-methylpentyl group, 1-(1-cyclohexyl)-1-methylethyl group, 1-(1-cyclohexyl)-1-methylpropyl group, 1-(1-cyclohexyl)-1-methylbutyl group, 1-(1-cyclohexyl)-1-methylpentyl group, tert-butyl group, tert-pentyl group and tert-hexyl group.

Moreover, groups in which R⁵⁶ in the general formula —O—R⁵⁵—C(═O)—O—R⁵⁶ has been substituted with R⁵⁶′ may also be used. R⁵⁶′ represents a hydrogen atom, an alkyl group, a fluorinated alkyl group, or an aliphatic cyclic group which may contain a hetero atom.

Examples of the alkyl group for R⁵⁶′ include the same groups as those described above for the alkyl group for R⁴⁹.

Examples of the fluorinated alkyl group for R⁵⁶′ include groups in which part or all of the hydrogen atoms within an aforementioned alkyl group for R⁴⁹ have each been substituted with a fluorine atom.

Examples of the aliphatic cyclic group which may contain a hetero atom for R⁵⁶′ include aliphatic cyclic groups that do not contain a hetero atom, aliphatic cyclic groups containing a hetero atom within the ring structure, and groups in which one or more hydrogen atoms within an aliphatic cyclic group have each been substituted with a hetero atom.

For R⁵⁶′, examples of the aliphatic cyclic groups that do not contain a hetero atom include groups in which one or more hydrogen atoms have been removed from a monocycloalkane or a polycycloalkane such as a bicycloalkane, tricycloalkane or tetracycloalkane. Examples of the monocycloalkane include cyclopentane and cyclohexane. Examples of the polycycloalkane include adamantane, norbornane, isobornane, tricyclodecane and tetracyclododecane. Among these, groups in which one or more hydrogen atoms have been removed from adamantane are preferable.

For R⁵⁶′, specific examples of the aliphatic cyclic groups containing a hetero atom within the ring structure include groups represented by the above formulas (L1) to (L6) and (S1) to (S4).

For R⁵⁶′, specific examples of the groups in which one or more hydrogen atoms within the aliphatic cyclic group have been substituted with a hetero atom include groups in which two hydrogen atoms within an aliphatic cyclic group have been substituted with an oxygen atom (═O).

Each of R⁶′, R⁷′ and R⁸′ in the formulas —C—(=O)—O—R⁶′, —O—C(═O)—R⁷′ and —O—R⁸′ represents a linear or branched saturated hydrocarbon group of 1 to 25 carbon atoms, a cyclic saturated hydrocarbon group of 3 to 20 carbon atoms, or a linear or branched aliphatic unsaturated hydrocarbon group of 2 to 5 carbon atoms.

The linear or branched saturated hydrocarbon group contains 1 to 25 carbon atoms, preferably 1 to 15 carbon atoms, and more preferably 4 to 10 carbon atoms.

Examples of the linear saturated hydrocarbon group include a methyl group, ethyl group, propyl group, butyl group, pentyl group, hexyl group, heptyl group, octyl group, nonyl group and decyl group.

Examples of the branched saturated hydrocarbon group, excluding tertiary alkyl groups, include a 1-methylethyl group, 1-methylpropyl group, 2-methylpropyl group, 1-methylbutyl group, 2-methylbutyl group, 3-methylbutyl group, 1-ethylbutyl group, 2-ethylbutyl group, 1-methylpentyl group, 2-methylpentyl group, 3-methylpentyl group and 4-methylpentyl group.

The linear or branched saturated hydrocarbon group may have a substituent. Examples of the substituent include an alkoxy group, halogen atom, halogenated alkyl group, hydroxyl group, oxygen atom (═O), cyano group or carboxyl group.

The alkoxy group as the substituent for the linear or branched saturated hydrocarbon group is preferably an alkoxy group having 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom as the substituent for the linear or branched saturated hydrocarbon group include a fluorine atom, chlorine atom, bromine atom and iodine atom, and a fluorine atom is preferable.

Examples of the halogenated alkyl group as the substituent for the linear or branched saturated hydrocarbon group include groups in which part or all of the hydrogen atoms within an aforementioned linear or branched saturated hydrocarbon group have each been substituted with an aforementioned halogen atom.

The cyclic saturated hydrocarbon group of 3 to 20 carbon atoms for R⁶′, R⁷′ and R⁸′ may be either a polycyclic group or a monocyclic group. Examples include groups in which one hydrogen atom has been removed from a monocycloalkane, and groups in which one hydrogen atom has been removed from a polycycloalkane such as a bicycloalkane, tricycloalkane or tetracycloalkane. More specific examples include groups in which one hydrogen atom has been removed from a monocycloalkane such as cyclopentane, cyclohexane, cycloheptane or cyclooctane, and groups in which one hydrogen atom has been removed from a polycycloalkane such as adamantane, norbornane, isobornane, tricyclodecane or tetracyclododecane.

The cyclic saturated hydrocarbon group may have a substituent. For example, part of the carbon atoms that constitute a ring within the cyclic saturated hydrocarbon group may be substituted with a hetero atom, or a hydrogen atom bonded to a ring within the cyclic saturated hydrocarbon may be substituted with a substituent.

Examples of the former case include groups in which one or more hydrogen atoms have been removed from a heterocycloalkane in which part of the carbon atoms that constitute the ring(s) of an aforementioned monocycloalkane or a polycycloalkane have been substituted with a hetero atom such as an oxygen atom, sulfur atom or nitrogen atom. Further, the ring structure may include an ester linkage (—C(═O)—O—). Specific examples include lactone-containing monocyclic groups such as groups in which one hydrogen atom has been removed from γ-butyrolactone, and lactone-containing polycyclic groups in which one hydrogen atom has been removed from a lactone ring-containing bicycloalkane, tricycloalkane or tetracycloalkane.

In the latter case, examples of the substituent include the same substituents that the aforementioned linear or branched saturated hydrocarbon group may have, or a lower alkyl group of 1 to 5 carbon atoms. Further, R⁶′, R⁷′ and R⁸′ may be a combination of a linear or branched alkyl group and a cyclic alkyl group.

Examples of combinations of a linear or branched alkyl group and a cyclic alkyl group include groups in which a cyclic alkyl group is bonded as a substituent to a linear or branched alkyl group, and groups in which a linear or branched alkyl group is bonded as a substituent to a cyclic alkyl group.

Examples of the linear aliphatic unsaturated hydrocarbon group for R⁶′, R⁷′ and R⁸′ include a vinyl group, propenyl group (allyl group), and butynyl group.

Examples of the branched aliphatic unsaturated hydrocarbon group for R⁶′, R⁷′ and R⁸′ include a 1-methylpropenyl group and 2-methylpropenyl group.

The linear or branched aliphatic unsaturated hydrocarbon group may have a substituent. Examples of the substituent include the same substituents that the aforementioned linear or branched saturated hydrocarbon group may have.

Of the various possibilities described above, each of R⁶′, R⁷′ and R⁸′ is preferably a linear or branched saturated hydrocarbon group of 1 to 15 carbon atoms, or a cyclic saturated hydrocarbon group of 3 to 20 carbon atoms, as such groups yield superior lithography properties and resist pattern shape.

The aryl group for each of R″ to R³″ is preferably a phenyl group or a naphthyl group.

Examples of the alkyl group for R¹″ to R³″ include unsubstituted alkyl groups, and substituted alkyl groups in which part or all of the hydrogen atoms of an unsubstituted alkyl group have each been substituted with a substituent.

The unsubstituted alkyl group may be linear, branched, cyclic, or a combination thereof. The alkyl group preferably contains 1 to 30 carbon atoms.

When the alkyl group is a linear or branched group, the alkyl group preferably contains 1 to 20 carbon atoms, more preferably 1 to 15 carbon atoms, still more preferably 1 to 10 carbon atoms, and most preferably 1 to 5 carbon atoms. Specific examples include a methyl group, ethyl group, n-propyl group, isopropyl group, n-butyl group, isobutyl group, n-pentyl group, hexyl group, nonyl group and decyl group. A methyl group is most preferable because it yields excellent resolution and enables synthesis to be conducted at a low cost.

When the alkyl group is a cyclic group, the cycloalkyl group preferably contains 3 to 30 carbon atoms, more preferably 3 to 20 carbon atoms, still more preferably 3 to 15 carbon atoms, still more preferably 4 to 12 carbon atoms, and most preferably 5 to 10 carbon atoms. The cycloalkyl group may be either monocyclic or polycyclic. Examples include groups in which one or more hydrogen atoms have been removed from a monocycloalkane and groups in which one or more hydrogen atom have been removed from a polycycloalkane such as a bicycloalkane, tricycloalkane or tetracycloalkane. Specific examples of the monocycloalkane include cyclopentane and cyclohexane. Specific examples of the polycycloalkane include adamantane, norbornane, isobornane, tricyclodecane and tetracyclododecane.

Examples of the substituent for the substituted alkyl group include the same substituents as those mentioned above for the substituted aryl group.

Examples of the alkenyl group for R¹″ to R³″ include unsubstituted alkenyl groups, and substituted alkenyl groups in which part or all of the hydrogen atoms of an unsubstituted alkenyl group have each been substituted with a substituent.

The unsubstituted alkenyl group may be linear, branched, cyclic, or a combination thereof. The unsubstituted alkenyl group preferably contains 2 to 10 carbon atoms, more preferably 2 to 5 carbon atoms, and still more preferably 2 to 4 carbon atoms. Specific examples include a vinyl group, propenyl group (allyl group), butynyl group, 1-methylpropenyl group and 2-methylpropenyl group.

Examples of the substituent for the substituted alkenyl group include the same substituents as those mentioned above for the substituted aryl group.

Two of R¹″ to R³″ may be bonded to each other to form a ring together with the sulfur atom in the formula. The thus formed ring may be either monocyclic or polycyclic.

Further, the ring may be either an aromatic ring or an aliphatic ring. The aliphatic ring may be either a saturated aliphatic ring or an unsaturated aliphatic ring.

In those cases where two of R¹″ to R³″ are bonded to each other to form a ring, the ring that includes the sulfur atom from the formula as part of the ring structure is preferably a 3- to 10-membered ring, and more preferably a 5- to 7-membered ring, including the sulfur atom.

The atoms that constitute the ring structure of this ring may include another hetero atom besides the sulfur atom bonded to two of R¹″ to R³″. Examples of this other hetero atom include a sulfur atom, an oxygen atom and a nitrogen atom.

Specific examples of the ring that is formed include a thiophene ring, thiazole ring, benzothiophene ring, thianthrene ring, dibenzothiophene ring, 9H-thioxanthene ring, thioxanthone ring, phenoxathiin ring, tetrahydrothiophenium ring and tetrahydrothiopyranium ring.

Specific examples of the cation moiety represented by the above formula (b-c1) include triphenylsulfonium, (3,5-dimethylphenyl)diphenylsulfonium, (4-(2-adamantoxymethyloxy)-3,5-dimethylphenyl)diphenylsulfonium, (4-(2-adamantoxymethyloxy)phenyl)diphenylsulfonium, (4-(tert-butoxycarbonylmethyloxy)phenyl)diphenylsulfonium, (4-(tert-butoxycarbonylmethyloxy)-3,5-dimethylphenyl)diphenylsulfonium, (4-(2-methyl-2-adamantyloxycarbonylmethyloxy)phenyl)diphenylsulfonium, (4-(2-methyl-2-adamantyloxycarbonylmethyloxy)-3,5-dimethylphenyl)diphenylsulfonium, tri(4-methylphenyl)sulfonium, dimethyl(4-hydroxynaphthyl)sulfonium, monophenyldimethylsulfonium, diphenylmonomethylsulfonium, (4-methylphenyl)diphenylsulfonium, (4-methoxyphenyl)diphenylsulfonium, tri(4-tert-butyl)phenylsulfonium, diphenyl(1-(4-methoxy)naphthyl)sulfonium, di(1-naphthyl)phenylsulfonium, 1-phenyltetrahydrothiophenium, 1-(4-methylphenyl)tetrahydrothiophenium, 1-(3,5-dimethyl-4-hydroxyphenyl)tetrahydrothiophenium, 1-(4-methoxynaphthalene-1-yl)tetrahydrothiophenium, 1-(4-ethoxynaphthalene-1-yl)tetrahydrothiophenium, 1-(4-n-butoxynaphthalene-1-yl)tetrahydrothiophenium, 1-phenyltetrahydrothiopyranium, 1-(4-hydroxyphenyl)tetrahydrothiopyranium, 1-(3,5-dimethyl-4-hydroxyphenyl)tetrahydrothiopyranium and 1-(4-methylphenyl)tetrahydrothiopyranium.

Furthermore, specific examples of preferred cations among those represented by the above formula (b-c1) include the cations represented by formulas (b-c1-1) to (b-c1-33) shown below.

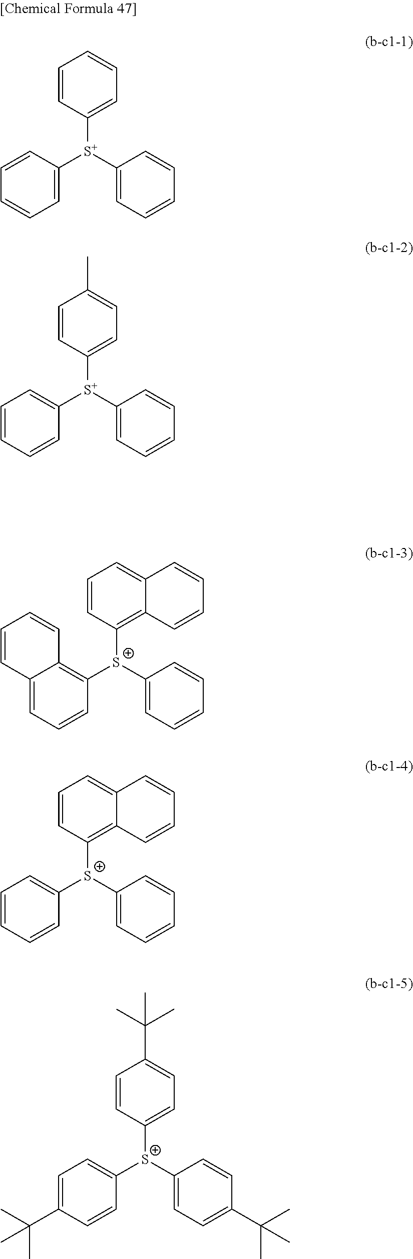

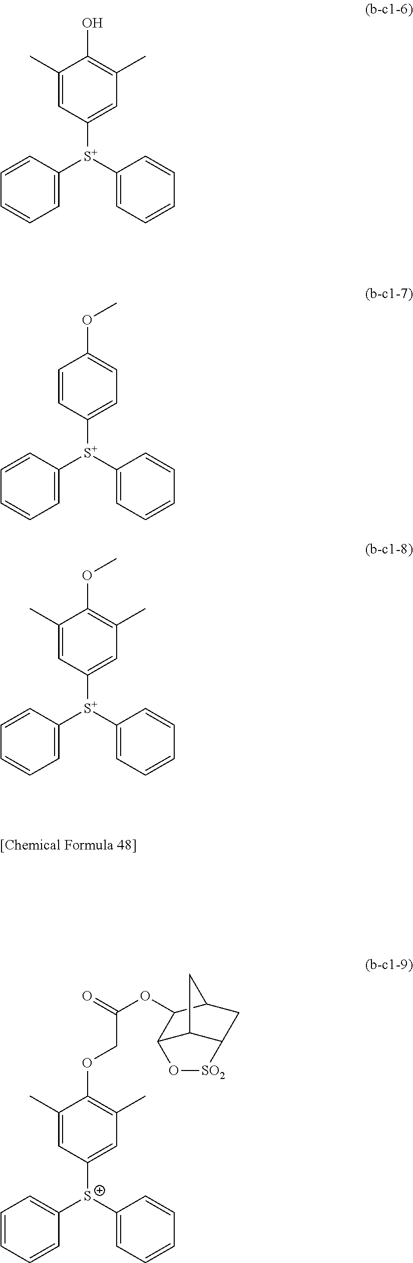

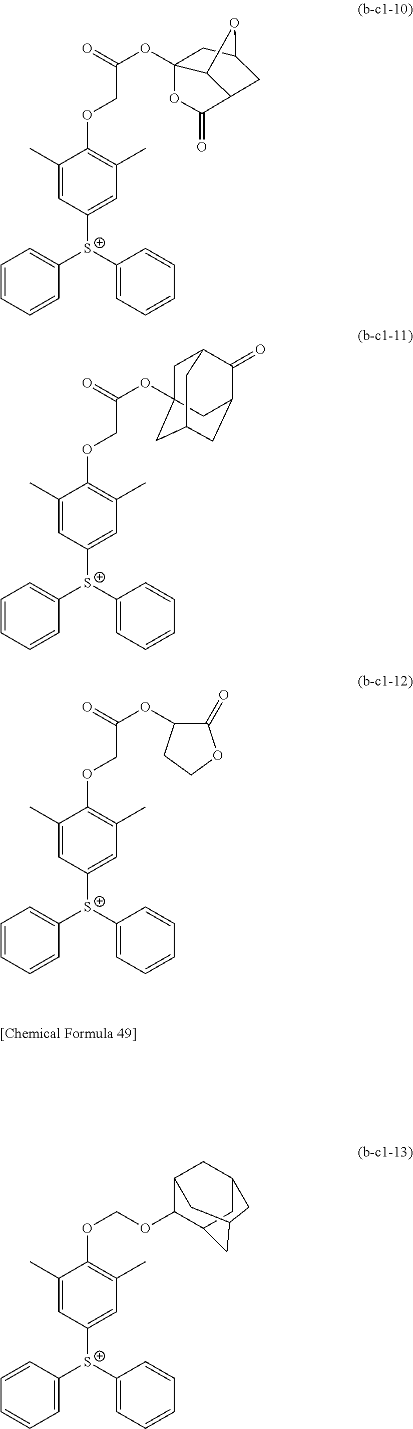

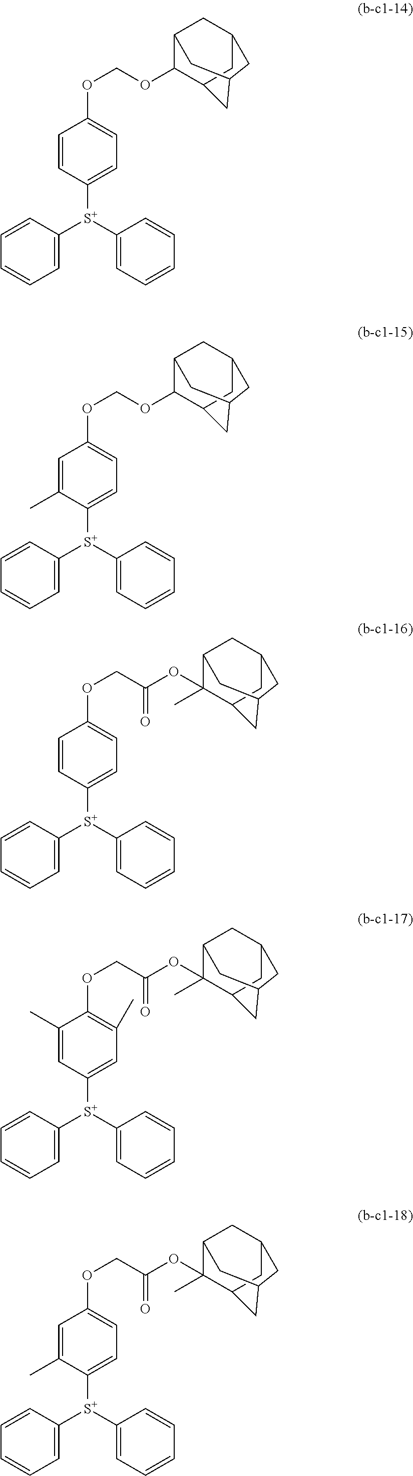

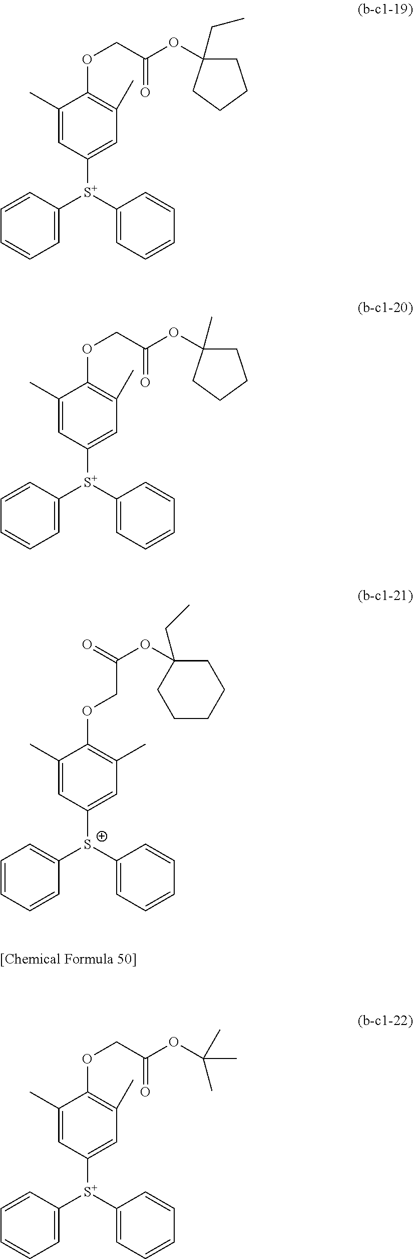

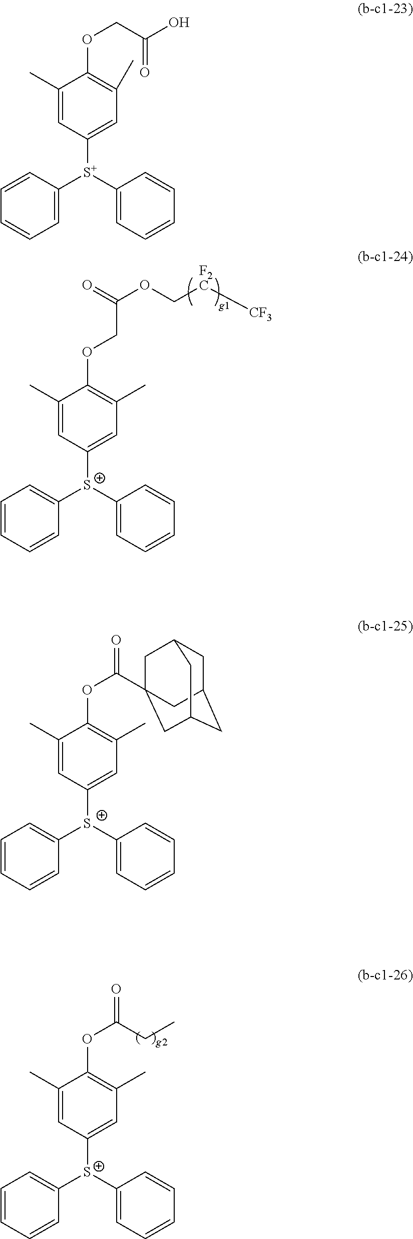

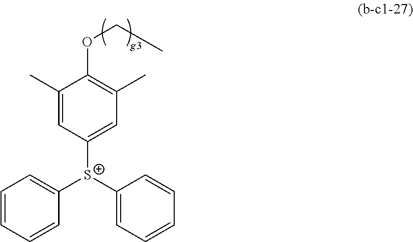

In the above formulas, each of g1 to g3 represents a number of repeating units, wherein g1 represents an integer of 1 to 5, g2 represents an integer of 0 to 20, and g3 represents an integer of 0 to 20.

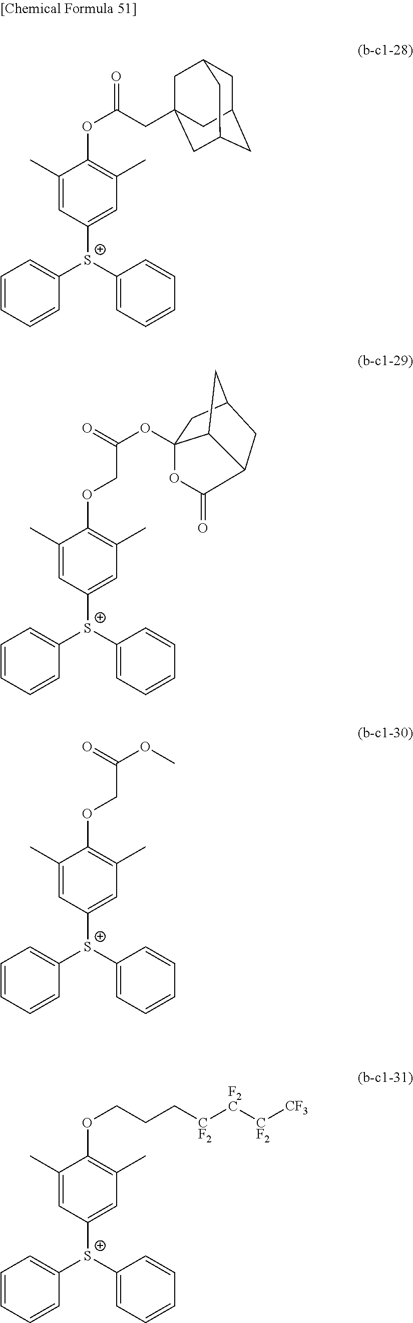

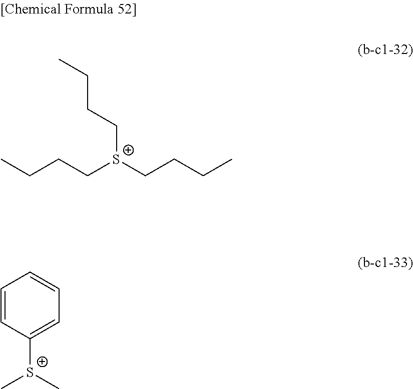

Further, in the cation represented by the above formula (b-c1), specific examples of preferred cations in the case where two of R¹″ to R³″ are bonded to each other to form a ring together with the sulfur atom in the formula include the cations represented by formulas (b-c12) to (b-c15) shown below.

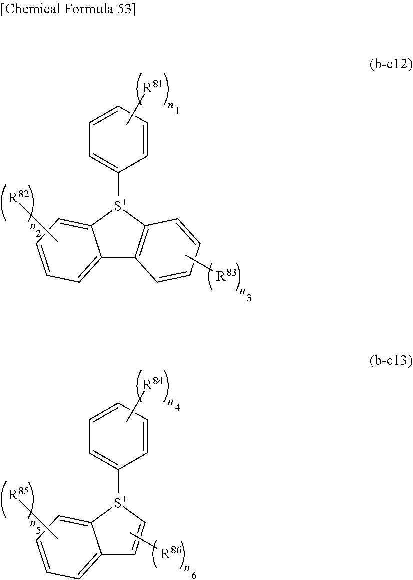

In the above formulas, each of R⁸¹ to R⁸⁶ independently represents an alkyl group, acetyl group, alkoxy group, carboxyl group, hydroxyl group or hydroxyalkyl group, each of n₁ to n₅ independently represents an integer of 0 to 3, and n₆ represents an integer of 0 to 2.

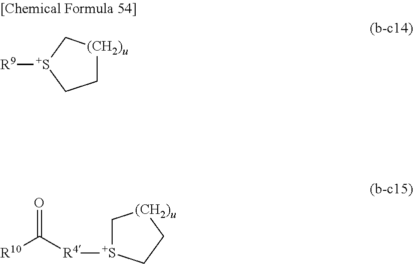

In the above formulas, each of R⁹ and R¹⁰ independently represents a phenyl group or naphthyl group which may have a substituent, an alkyl group or alkoxy group of 1 to 5 carbon atoms, or a hydroxyl group, R⁴′ represents an alkylene group of 1 to 5 carbon atoms, and u represents an integer of 1 to 3.

In the formulas (b-c12) and (b-c13), the alkyl group for R⁸¹ to R⁸⁶ is preferably an alkyl group of 1 to 5 carbon atoms, and among such groups, is more preferably a linear or branched alkyl group, and most preferably a methyl group, ethyl group, propyl group, isopropyl group, n-butyl group or tert-butyl group.

In the formulas (b-c12) and (b-c13), the alkoxy group for R⁸¹ to R⁸⁶ is preferably an alkoxy group of 1 to 5 carbon atoms, and among such groups, is more preferably a linear or branched alkoxy group, and most preferably a methoxy group or an ethoxy group.

In the formulas (b-c12) and (b-c13), the hydroxyalkyl group for R⁸¹ to R⁸⁶ is preferably a group in which one or more of the hydrogen atoms within an aforementioned alkyl group have each been substituted with a hydroxyl group, and is more preferably a hydroxymethyl group, hydroxyethyl group or hydroxypropyl group.

When the subscripts n₁ to n₆ appended to R⁸¹ to R⁸⁶ represent an integer of 2 or more, the corresponding plurality of R⁸¹ to R⁸⁶ groups may be the same or different from each other.

n₁ is preferably 0 to 2, more preferably 0 or 1, and still more preferably 0.

It is preferable that each of n₂ and n₃ independently represents 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

Specific examples of preferred cations represented by the above formula (b-c12) or (b-c13) include the cations shown below.

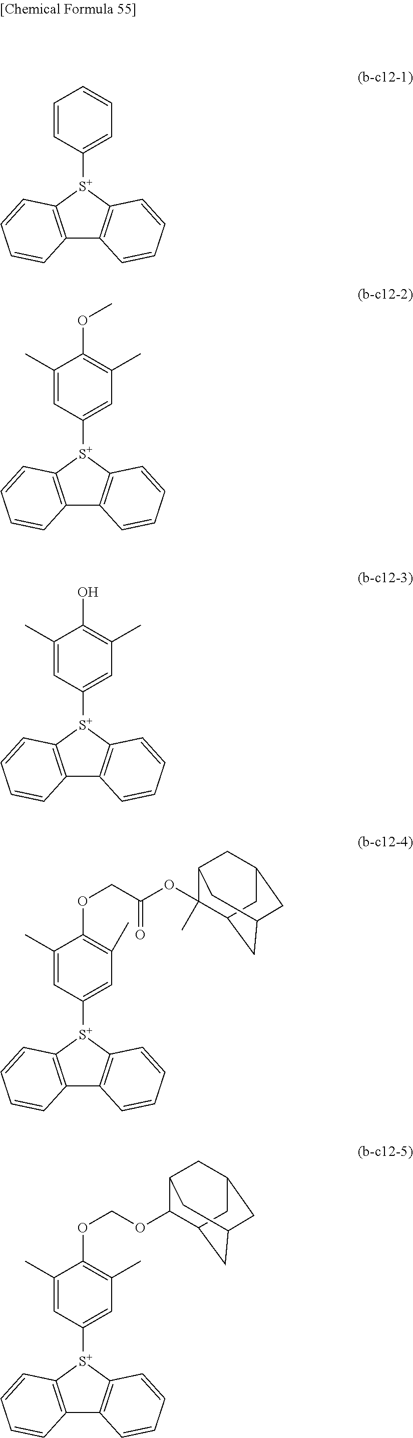

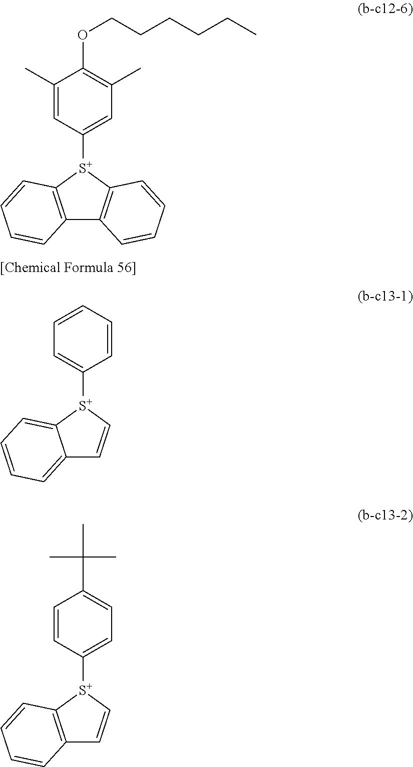

In formulas (b-c14) and (b-c15), each of R⁹ and R¹⁰ independently represents a phenyl group or naphthyl group which may have a substituent, an alkyl group or alkoxy group of 1 to 5 carbon atoms, or a hydroxyl group. Examples of the substituent include the same substituents as those described above for the substituted aryl groups mentioned within the description relating to the aryl groups of R¹″ to R³″ (such as an alkyl group, alkoxy group, alkoxyalkyloxy group, alkoxycarbonylalkyloxy group, halogen atom, hydroxyl group, oxo group (═O), aryl group, —C—(=O)—O—R⁶′, —O—C(═O)—R⁷′ or —O—R⁸′, or group represented by the above general formula —O—R⁵⁵—C(═O)—O—R⁵⁶ in which R⁵⁶ has been substituted with R⁵⁶′).

R⁴′ represents an alkylene group of 1 to 5 carbon atoms.

u represents an integer of 1 to 3, and is most preferably 1 or 2.

Examples of preferred cations represented by the formula (b-c14) or (b-c15) include the cations shown below.

In the formula below, R^{C} represents a substituent mentioned above within the description relating to the substituted aryl groups (namely, an alkyl group, alkoxy group, alkoxyalkyloxy group, alkoxycarbonylalkyloxy group, halogen atom, hydroxyl group, oxo group (═O), aryl group, —C—(=O)—O—R⁶′ or —O—C(═O)—R⁷′, or —O—R⁸′).

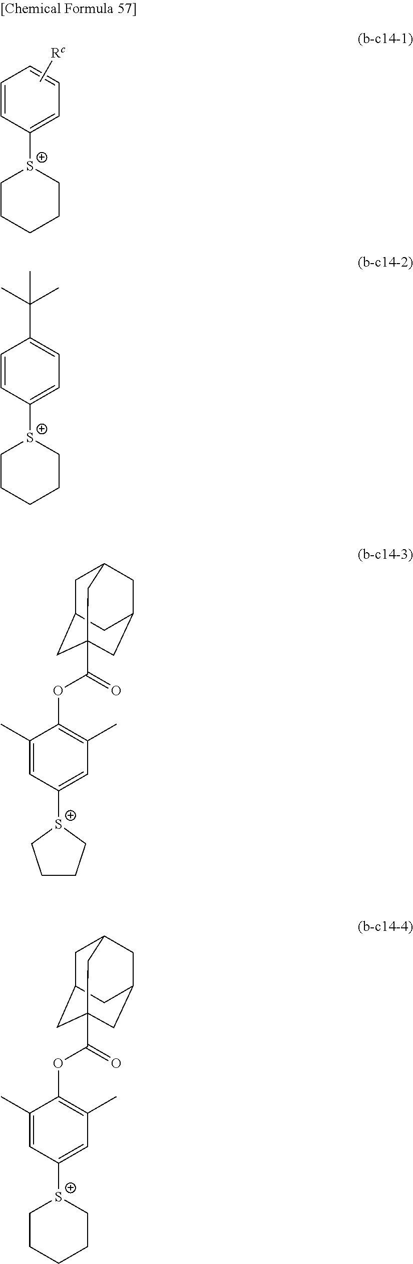

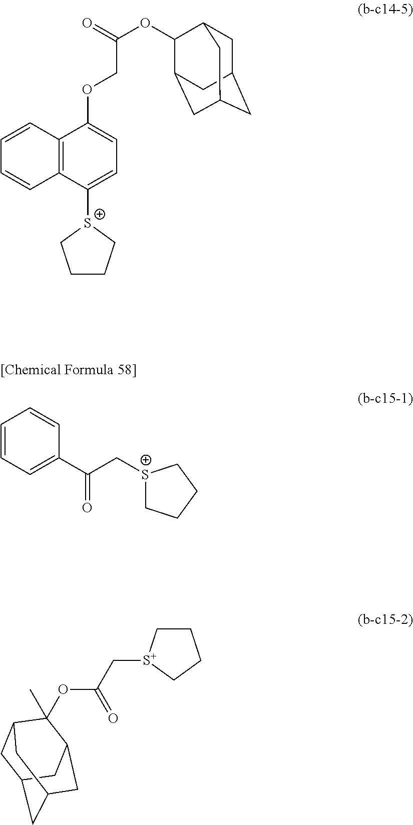

In the above formula (b-c2), each of R⁵″ and R⁶″ independently represents an aryl group, alkyl group or alkenyl group which may have a substituent.

Examples of the aryl group for R⁵″ and R⁶″ include the same aryl groups as those described for R¹″ to R³″.

Examples of the alkyl group for R⁵″ and R⁶″ include the same alkyl groups as those described for R″ to R³″.

Examples of the alkenyl group for R⁵″ and R⁶″ include the same alkenyl groups as those described for R¹″ to R³″.

In terms of achieving better improvement in the lithography properties and the resist pattern shape, it is preferable that at least one of R⁵″ and R⁶″ is an aryl group, and more preferable that both of R⁵″ and R⁶″ are aryl groups.

Among the various possibilities, the case in which R⁵″ and R⁶″ are both phenyl groups is the most desirable.

Specific examples of the cation represented by the above formula (b-c2) include diphenyliodonium and bis(4-tert-butylphenyl)iodonium.

As the component (B1), a single component may be used alone, or two or more components may be used in combination.

The amount of the component (B1) within the component (B), based on the total weight of the component (B), is preferably at least 60% by weight, more preferably within a range from 70 to 99% by weight, and still more preferably from 80 to 90% by weight.

Further, the amount of the component (B1) is preferably within a range from 7 to 50 parts by weight, and more preferably from 7 to 30 parts by weight, relative to 100 parts by weight of the component (A).

When the amount of the component (B1) is at least as large as the lower limit of the preferable range, lithography properties are improved, e.g., reduction of roughness, improvement in circularity, and the like. On the other hand, when the amount of the component (B1) is not more than the upper limit of the above range, a good blend balance can be more easily achieved with the component (B2), and the verticalness of the resist pattern shape is enhanced.

[Chemical Formula 59]

R¹—Y⁵—SO₃⁻A⁺ (b 2)

In the above formula, R¹ represents a monovalent chain-like aliphatic hydrocarbon group containing a hetero atom at an arbitrary position, Y⁵ represents an alkylene group of 1 to 4 carbon atoms which may have a substituent or a fluorinated alkylene group of 1 to 4 carbon atoms which may have a substituent, and A⁺ represents an organic cation.

### [Anion Moiety of the Component (B2)]

In the above formula (b2), R¹ represents a monovalent chain-like aliphatic hydrocarbon group containing a hetero atom at an arbitrary position.

The expression “containing a hetero atom at an arbitrary position” includes both those cases where part of the carbon atoms that constitute the monovalent chain-like aliphatic hydrocarbon group have been substituted with a hetero atom or a hetero atom-containing group, and those cases where part or all of the hydrogen atoms that constitute the monovalent chain-like aliphatic hydrocarbon group have been substituted with a hetero atom or a hetero atom-containing group. There are no particular limitations on the hetero atom, provided it is an atom other than a carbon atom or a hydrogen atom. Examples of the hetero atom include a halogen atom, oxygen atom, sulfur atom and nitrogen atom, and an oxygen atom or nitrogen atom is preferable. A hetero atom-containing group describes a group containing at least one hetero atom and one or more other atoms besides the hetero atom.

Examples of the monovalent chain-like aliphatic hydrocarbon group for R¹ (prior to substitution with the hetero atom) include linear and branched saturated hydrocarbon groups, and linear and branched unsaturated hydrocarbon groups. The aliphatic hydrocarbon group for R¹ preferably contains 1 to 20 carbon atoms, more preferably 3 to 20 carbon atoms, and still more preferably 3 to 15 carbon atoms.

The linear saturated hydrocarbon group preferably contains 1 to 20 carbon atoms, more preferably 2 to 15 carbon atoms, still more preferably 3 to 12 carbon atoms, and most preferably 3 to 10 carbon atoms. Specific examples include a methyl group, ethyl group, propyl group, butyl group, pentyl group, hexyl group, heptyl group, octyl group, nonyl group, decyl group, undecyl group, dodecyl group, tridecyl group, isotridecyl group, tetradecyl group, pentadecyl group, hexadecyl group, isohexadecyl group, heptadecyl group, octadecyl group, nonadecyl group, eicosyl group, heneicosyl group and docosyl group.

The branched saturated hydrocarbon group preferably contains 3 to 20 carbon atoms, more preferably 3 to 15 carbon atoms, and most preferably 3 to 10 carbon atoms. Specific examples include a 1-methylethyl group, 1-methylpropyl group, 2-methylpropyl group, 1-methylbutyl group, 2-methylbutyl group, 3-methylbutyl group, 1-ethylbutyl group, 2-ethylbutyl group, 1-methylpentyl group, 2-methylpentyl group, 3-methylpentyl group and 4-methylpentyl group.

The unsaturated hydrocarbon group preferably contains 2 to 10 carbon atoms, more preferably 2 to 5 carbon atoms, still more preferably 2 to 4 carbon atoms, and most preferably 3 carbon atoms. Examples of linear monovalent unsaturated hydrocarbon groups include a vinyl group, a propenyl group (allyl group) and a butynyl group. Examples of branched monovalent unsaturated hydrocarbon groups include a 1-methylpropenyl group and a 2-methylpropenyl group. Among the above examples, a propenyl group is particularly desirable as the unsaturated hydrocarbon group.

Examples of the hetero atom or hetero atom-containing group contained within the monovalent chain-like aliphatic hydrocarbon group for R¹ include an oxygen atom (ether bond: —O—), ester linkage (—O—C(═O)—), amide linkage (—NH—C(═O)—), >N—C(═O)—, carbonyl group (—C(═O)—) and carbonate linkage (—O—C(═O)—O—).

In the above formula (b2), Y⁵ represents an alkylene group of 1 to 4 carbon atoms which may have a substituent or a fluorinated alkylene group of 1 to 4 carbon atoms which may have a substituent, and is the same as defined above for Y¹ in the formula (b1).

Preferred examples of the anion moiety of the component (B2) include anions represented by general formulas (12a) to (12e) shown below.

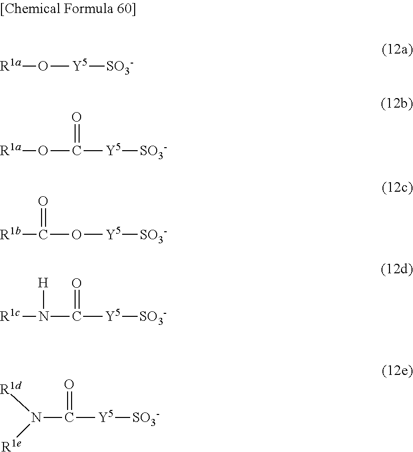

In the above formulas, each of R^{1a}, R^{1b}, R^{1c}, R^{1d} and R^{1e} represents a monovalent chain-like aliphatic hydrocarbon group which may contain an oxygen atom at an arbitrary position, and Y⁵ is the same as defined above for Y⁵ in the formula (b2).

The expression “contain an oxygen atom at an arbitrary position” includes both those cases where part of the carbon atoms that constitute the monovalent chain-like aliphatic hydrocarbon group have been substituted with an oxygen atom or an oxygen atom-containing group, and those cases where part or all of the hydrogen atoms that constitute the monovalent chain-like aliphatic hydrocarbon group have been substituted with an oxygen atom or an oxygen atom-containing group. The “oxygen atom-containing group” describes a group containing an oxygen atom and one or more other atoms besides the oxygen atom. Specific examples include an oxygen atom (ether bond: —O—), ester linkage (—O—C(═O)—), carbonyl group (—C(═O)—) and carbonate linkage (—O—C(═O)—O—).

In the above formulas, examples of the monovalent chain-like aliphatic hydrocarbon groups represented by R^{1a}, R^{1b}, R^{1c}, R^{1d} and R^{1e} include the same groups as those mentioned above for the monovalent chain-like aliphatic hydrocarbon groups for R¹ in the aforementioned formula (b2).

Among the above anions, in order to enhance the verticalness during pattern formation of a line or hole resist pattern, an anion represented by the general formula (12a) or an anion represented by the general formula (12b) is particularly desirable.

Specific examples of preferred anion moieties for the component (B2) include the anions represented by formulas (b2-a1) to (b2-a16) shown below.

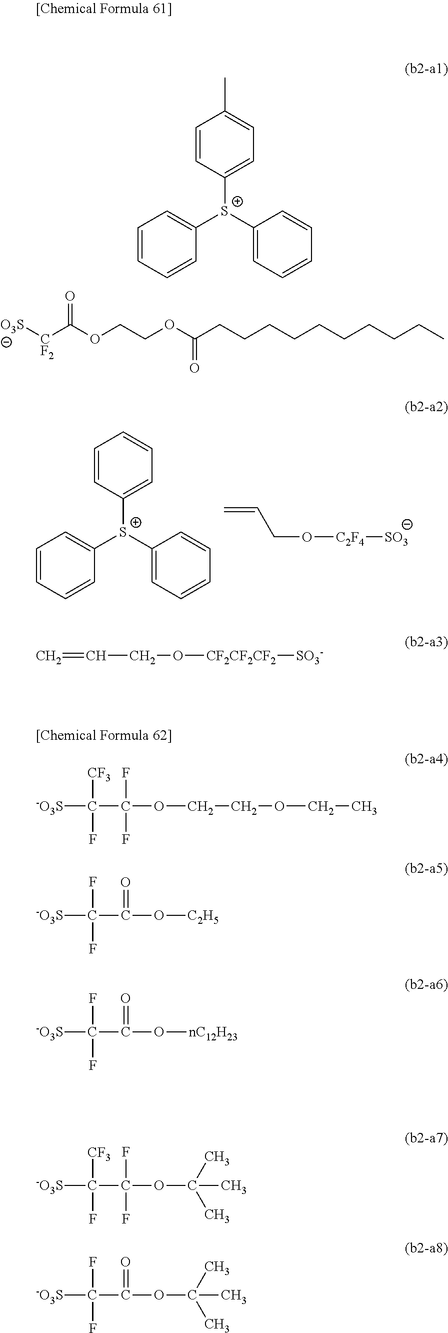

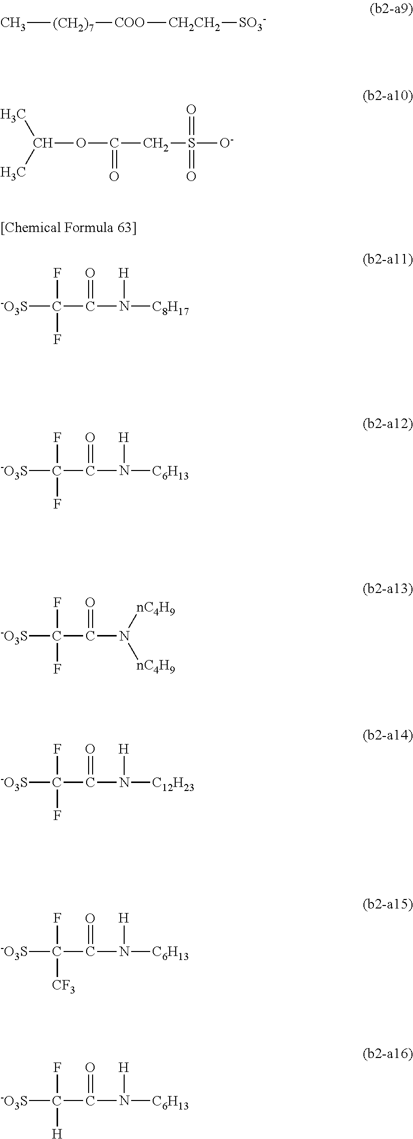

### [Cation Moiety of the Component (B2)]

In the above formula (b2), A⁺ is the same as defined above for A⁺ in the aforementioned formula (b1).

As the component (B2), a single component may be used alone, or two or more components may be used in combination.

The amount of the component (B2) within the component (B), based on the total weight of the component (B), is preferably at least 1% by weight, more preferably within a range from 2 to 40% by weight, and still more preferably from 3 to 15% by weight.

Further, the amount of the component (B2) is preferably within a range from 0.5 to 10 parts by weight, more preferably from 0.7 to 8 parts by weight, and most preferably from 1 to 5 parts by weight, relative to 100 parts by weight of the component (A).

When the amount of the component (B2) is at least as large as the lower limit of the preferable range, the verticalness of the resist pattern shape is enhanced. On the other hand, when the amount of the component (B2) is not more than the upper limit of the above range, a good blend balance can be more easily achieved with the component (B1), lithography properties are improved, e.g., reduction of roughness, improvement in circularity, and the like.

In the resist composition of the present invention, the amount of the component (B2) is preferably not more than 60 mol % relative to the sum of the component (B1) and the component (B2) (namely, the molar ratio represented by (Component (B2))/[Component (B1)+Component (B2)] is preferably not more than 60), and the amount of the component (B2) relative to the sum of the component (B1) and the component (B2) is more preferably not more than 50 mol %, still more preferably within a range from 1 to 50 mol %, still more preferably from 1 to 30 mol %, and most preferably from 3 to 25 mol %.

When the amount of the component (B2) is not more than the upper limit of this preferred range, the verticalness of the resist pattern shape is enhanced.

The aforementioned molar ratio (Component (B2))/[Component (B1)+Component (B2)] represents the ratio (molar ratio) of the number of mols of the component (B2) relative to the total number of mols of the component (B1) and the component (B2) within the resist composition.

The resist composition of the present invention may also include another acid generator (B3) that generates acid upon exposure but does not correspond with the components (B1) and (B2) described above (hereinafter referred to as “component (B3)”), provided the effects of the present invention are not impaired.

There are no particular limitations on the component (B3), and any of the known acid generators used in conventional chemically amplified resist compositions can be used. Examples of these acid generators are numerous, and include onium salt acid generators such as iodonium salts and sulfonium salts, oxime sulfonate acid generators, diazomethane acid generators such as bisalkyl or bisaryl sulfonyl diazomethanes and poly(bis-sulfonyl)diazomethanes, nitrobenzylsulfonate acid generators, iminosulfonate acid generators, and disulfone acid generators.

Examples of onium salt acid generators for the component (B3) include compounds represented by a general formula (b-1) or (b-2) shown below.

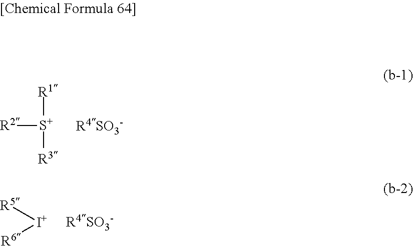

In the formulas, each of R¹″ to R³″ independently represents an aryl group, alkyl group or alkenyl group which may have a substituent, wherein two of R¹″ to R³″ may be bonded to each other to form a ring together with the sulfur atom in the formula, each of R⁵″ and R⁶″ independently represents an aryl group, alkyl group or alkenyl group which may have a substituent, and R⁴″ represents an alkyl group, halogenated alkyl group, aryl group or alkenyl group which may have a substituent.

R¹″ to R³″ in the formula (b-1) are the same as defined above for R″ to R³″ in the general formula (b-c1) within the description relating to the component (B1).

R⁵″ and R⁶″ in the formula (b-2) are the same as defined above for R⁵″ and R⁶″ in the general formula (b-c2) within the description relating to the component (B1).

R⁴″ represents an alkyl group, halogenated alkyl group, aryl group or alkenyl group which may have a substituent.

The alkyl group for R⁴″ may be any of linear, branched or cyclic.

The linear or branched alkyl group preferably has 1 to 10 carbon atoms, more preferably 1 to 8 carbon atoms, and most preferably 1 to 4 carbon atoms.

The cyclic alkyl group preferably has 4 to 15 carbon atoms, more preferably 4 to 10 carbon atoms, and most preferably 6 to 10 carbon atoms.

Examples of the halogenated alkyl group for R⁴″ include groups in which part or all of the hydrogen atoms of an aforementioned linear, branched or cyclic alkyl group have each been substituted with a halogen atom. Examples of the halogen atom include a fluorine atom, chlorine atom, bromine atom and iodine atom, and a fluorine atom is preferable.

In the halogenated alkyl group, the percentage of the number of halogen atoms relative to the total number of halogen atoms and hydrogen atoms within the halogenated alkyl group (namely, the halogenation ratio (%)) is preferably within a range from 10 to 100%, more preferably from 50 to 100%, and most preferably 100%. A higher halogenation ratio is preferable because the acid strength increases.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part or all of the hydrogen atoms within the aforementioned alkyl group, halogenated alkyl group, aryl group or alkenyl group may each be substituted with a substituent (an atom other than a hydrogen atom, or a group).

Examples of the substituent include a halogen atom, a hetero atom and an alkyl group. Examples of the halogen atom and the alkyl group include the same halogen atoms and alkyl groups as those described above with respect to the halogenated alkyl group for R⁴″. Examples of the hetero atom include an oxygen atom, a sulfur atom and a nitrogen atom.

R⁴″ may have one substituent, or two or more substituents.

Specific examples of the onium salt acid generators represented by the formula (b-1) or (b-2) include diphenyliodonium trifluoromethanesulfonate or nonafluorobutanesulfonate; bis(4-tert-butylphenyl)iodonium trifluoromethanesulfonate or nonafluorobutanesulfonate; triphenylsulfonium trifluoromethanesulfonate, heptafluoropropanesulfonate or nonafluorobutanesulfonate; tri(4-methylphenyl)sulfonium trifluoromethanesulfonate, heptafluoropropanesulfonate or nonafluorobutanesulfonate; dimethyl(4-hydroxynaphthyl)sulfonium trifluoromethanesulfonate, heptafluoropropanesulfonate or nonafluorobutanesulfonate; monophenyldimethylsulfonium trifluoromethanesulfonate, heptafluoropropanesulfonate or nonafluorobutanesulfonate; diphenylmonomethylsulfonium trifluoromethanesulfonate, heptafluoropropanesulfonate or nonafluorobutanesulfonate; (4-methylphenyl)diphenylsulfonium trifluoromethanesulfonate, heptafluoropropanesulfonate or nonafluorobutanesulfonate; (4-methoxyphenyl)diphenylsulfonium trifluoromethanesulfonate, heptafluoropropanesulfonate or nonafluorobutanesulfonate; tri(4-tert-butyl)phenylsulfonium trifluoromethanesulfonate, heptafluoropropanesulfonate or nonafluorobutanesulfonate; diphenyl(1-(4-methoxy)naphthyl)sulfonium trifluoromethanesulfonate, heptafluoropropanesulfonate or nonafluorobutanesulfonate; di(1-naphthyl)phenylsulfonium trifluoromethanesulfonate, heptafluoropropanesulfonate or nonafluorobutanesulfonate; 1-phenyltetrahydrothiophenium trifluoromethanesulfonate, heptafluoropropanesulfonate or nonafluorobutanesulfonate; 1-(4-methylphenyl)tetrahydrothiophenium trifluoromethanesulfonate, heptafluoropropanesulfonate or nonafluorobutanesulfonate; 1-(3,5-dimethyl-4-hydroxyphenyl)tetrahydrothiophenium trifluoromethanesulfonate, heptafluoropropanesulfonate or nonafluorobutanesulfonate; 1-(4-methoxynaphthalene-1-yl)tetrahydrothiophenium trifluoromethanesulfonate, heptafluoropropanesulfonate or nonafluorobutanesulfonate; 1-(4-ethoxynaphthalene-1-yl)tetrahydrothiophenium trifluoromethanesulfonate, heptafluoropropanesulfonate or nonafluorobutanesulfonate; 1-(4-n-butoxynaphthalene-1-yl)tetrahydrothiophenium trifluoromethanesulfonate, heptafluoropropanesulfonate or nonafluorobutanesulfonate; 1-phenyltetrahydrothiopyranium trifluoromethanesulfonate, heptafluoropropanesulfonate or nonafluorobutanesulfonate; 1-(4-hydroxyphenyl)tetrahydrothiopyranium trifluoromethanesulfonate, heptafluoropropanesulfonate or nonafluorobutanesulfonate; 1-(3,5-dimethyl-4-hydroxyphenyl)tetrahydrothiopyranium trifluoromethanesulfonate, heptafluoropropanesulfonate or nonafluorobutanesulfonate; and 1-(4-methylphenyl)tetrahydrothiopyranium trifluoromethanesulfonate, heptafluoropropanesulfonate or nonafluorobutanesulfonate.

Further, it is also possible to use onium salts in which the anion moiety of these onium salts has been replaced by an alkyl sulfonate such as methanesulfonate, n-propanesulfonate, n-butanesulfonate, n-octanesulfonate, 1-adamantanesulfonate or 2-norbornanesulfonate, by a substituted alkyl sulfonate such as d-camphor-10-sulfonate, or by an aromatic sulfonate such as benzenesulfonate, perfluorobenzenesulfonate or p-toluenesulfonate.

Further, onium salt acid generators in which the anion moiety (R⁴″SO₃) in the above general formula (b-1) or (b-2) has been replaced with an anion moiety represented by a general formula (b-3) or (b-4) shown below (but in which the cation moiety is the same as the cation shown in the formula (b-1) or (b-2)) may also be used as the onium salt acid generator.

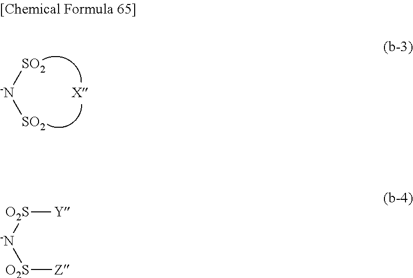

In the formulas, X″ represents an alkylene group of 2 to 6 carbon atoms in which at least one hydrogen atom has been substituted with a fluorine atom, and each of Y″ and Z″ independently represents an alkyl group of 1 to 10 carbon atoms in which at least one hydrogen atom has been substituted with a fluorine atom.

X″ represents a linear or branched alkylene group in which at least one hydrogen atom has been substituted with a fluorine atom, wherein the alkylene group has 2 to 6 carbon atoms, preferably 3 to 5 carbon atoms, and most preferably 3 carbon atoms.

Each of Y″ and Z″ independently represents a linear or branched alkyl group in which at least one hydrogen atom has been substituted with a fluorine atom, wherein the alkyl group has 1 to 10 carbon atoms, preferably 1 to 7 carbon atoms, and most preferably 1 to 3 carbon atoms.

The smaller the number of carbon atoms in the alkylene group for X″ or the alkyl group for Y″ and Z″ within the above-mentioned ranges of the number of carbon atoms, the more the solubility in a resist solvent is improved, and therefore a smaller number of carbon atoms is preferred.

Further, in the alkylene group for X″ or the alkyl group for Y″ and Z″, it is preferable that the number of hydrogen atoms substituted with fluorine atoms is as large as possible, because the acid strength increases and the transparency to high energy radiation of 200 nm or less or electron beam is improved.

The proportion of fluorine atoms within the alkylene group or alkyl group, namely the fluorination ratio, is preferably within a range from 70 to 100%, and more preferably from 90 to 100%. A perfluoroalkylene or perfluoroalkyl group in which all the hydrogen atoms are substituted with fluorine atoms is the most desirable.

As the onium salt acid generator, onium salts of the above general formula (b-1) or (b-2) in which the anion moiety (R⁴″SO₃⁻) has been substituted with R^{a}—COO⁻ (wherein R^{a} represents an alkyl group or a fluorinated alkyl group) (and in which the cation moiety is the same as that of the general formula (b-1) or (b-2)) may also be used.

Examples of R^{a} in the above formula include the same alkyl groups and halogenated alkyl groups (in which the halogen atoms are fluorine atoms) as those mentioned above within the description for R⁴″.

Specific examples of R^{a}—COO⁻ include a trifluoroacetate ion, an acetate ion, and a 1-adamantanecarboxylate ion.

An oxime sulfonate acid generator for the component (B3) is a compound having at least one group represented by a general formula (B-1) shown below, and has a feature of generating acid upon irradiation (exposure).

Such oxime sulfonate acid generators are widely used for chemically amplified resist compositions, and any of these known compounds may be selected as appropriate for the oxime sulfonate acid generator for the component (B3).

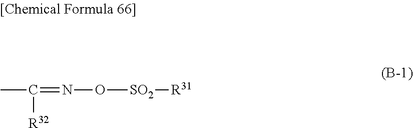

In the formula (B-1), each of R³¹ and R³² independently represents an organic group.

The organic group for R³¹ and R³² refers to a group containing a carbon atom, and may also include atoms other than the carbon atom (such as a hydrogen atom, oxygen atom, nitrogen atom, sulfur atom or halogen atom (such as a fluorine atom or chlorine atom) or the like).

The organic group for R³¹ is preferably a linear, branched or cyclic alkyl group, or an aryl group. The alkyl group or aryl group may have a substituent. There are no particular limitations on the substituent, and examples include a fluorine atom or a linear, branched or cyclic alkyl group having 1 to 6 carbon atoms. The expression that the alkyl group or aryl group “may have a substituent” means that part or all of the hydrogen atoms of the alkyl group or aryl group may each be substituted with a substituent.

The alkyl group for the organic group for R³¹ preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. A “partially halogenated alkyl group” refers to an alkyl group in which part of the hydrogen atoms are each substituted with a halogen atom, whereas a “completely halogenated alkyl group” refers to an alkyl group in which all of the hydrogen atoms are substituted with halogen atoms. Examples of the halogen atom include a fluorine atom, chlorine atom, bromine atom or iodine atom, and a fluorine atom is particularly desirable. In other words, the halogenated alkyl group is preferably a fluorinated alkyl group.

The aryl group for the organic group for R³¹ preferably has 4 to 20 carbon atoms, more preferably 4 to 10 carbon atoms, and most preferably 6 to 10 carbon atoms. As the aryl group, a partially or completely halogenated aryl group is particularly desirable. A “partially halogenated aryl group” refers to an aryl group in which part of the hydrogen atoms are each substituted with a halogen atom, whereas a “completely halogenated aryl group” refers to an aryl group in which all of hydrogen atoms are substituted with halogen atoms.

As the organic group for R³¹, an alkyl group of 1 to 4 carbon atoms which has no substituent, or a fluorinated alkyl group of 1 to 4 carbon atoms is particularly desirable.

The organic group for R³² is preferably a linear, branched or cyclic alkyl group, an aryl group, or a cyano group. Examples of the alkyl group and the aryl group for R³² include the same alkyl groups and aryl groups as those described above for R³¹.

As the organic group for R³², a cyano group, an alkyl group of 1 to 8 carbon atoms having no substituent, or a fluorinated alkyl group of 1 to 8 carbon atoms is particularly desirable.

Preferred examples of the oxime sulfonate acid generator include compounds represented by a general formula (B-2) or (B-3) shown below.

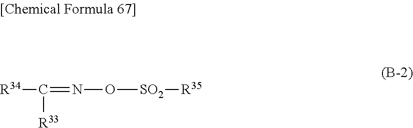

In the formula (B-2), R³³ represents a cyano group, an alkyl group having no substituent or a halogenated alkyl group, R³⁴ represents an aryl group, and R³⁵ represents an alkyl group having no substituent or a halogenated alkyl group.

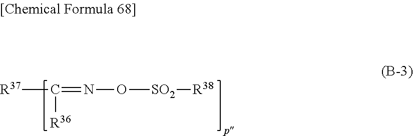

In the formula (B-3), R³⁶ represents a cyano group, an alkyl group having no substituent or a halogenated alkyl group, R³⁷ represents a divalent or trivalent aromatic hydrocarbon group, R³⁸ represents an alkyl group having no substituent or a halogenated alkyl group, and p″ represents 2 or 3.

In the general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

R³³ is preferably a halogenated alkyl group, and more preferably a fluorinated alkyl group.

The fluorinated alkyl group for R³³ preferably has 50% or more of the hydrogen atoms thereof fluorinated, more preferably 70% or more fluorinated, and most preferably 90% or more fluorinated.

Examples of the aryl group for R³⁴ include groups in which one hydrogen atom has been removed from an aromatic hydrocarbon ring, such as a phenyl group, biphenylyl group, fluorenyl group, naphthyl group, anthryl group and phenanthryl group, and heteroaryl groups in which part of the carbon atoms that constitute the ring(s) of these groups are substituted with hetero atoms such as an oxygen atom, a sulfur atom or a nitrogen atom. Of these, a fluorenyl group is preferable.

The aryl group for R³⁴ may have a substituent such as an alkyl group, a halogenated alkyl group or an alkoxy group of 1 to 10 carbon atoms. The alkyl group or halogenated alkyl group as the substituent preferably contains 1 to 8 carbon atoms, and more preferably 1 to 4 carbon atoms. The halogenated alkyl group is preferably a fluorinated alkyl group.

The alkyl group having no substituent or the halogenated alkyl group for R³⁵ preferably contains 1 to 10 carbon atoms, more preferably 1 to 8 carbon atoms, and most preferably 1 to 6 carbon atoms.

R³⁵ is preferably a halogenated alkyl group, and more preferably a fluorinated alkyl group.

In terms of enhancing the strength of the acid generated, the fluorinated alkyl group for R³⁵ preferably has 50% or more of the hydrogen atoms within the alkyl group fluorinated, more preferably 70% or more fluorinated, and still more preferably 90% or more fluorinated. A completely fluorinated alkyl group in which 100% of the hydrogen atoms have been substituted with fluorine atoms is particularly desirable.

In the general formula (B-3), examples of the alkyl group having no substituent and the halogenated alkyl group for R³⁶ include the same groups as those described above for the alkyl group having no substituent and the halogenated alkyl group for R³³.

Examples of the divalent or trivalent aromatic hydrocarbon group for R³⁷ include groups in which an additional one or two hydrogen atoms have been removed from the aryl group described above for R³⁴.

Examples of the alkyl group having no substituent or the halogenated alkyl group for R³⁸ include the same groups as those described above for the alkyl group having no substituent or the halogenated alkyl group for R³⁵.

p″ is preferably 2.

Specific examples of suitable oxime sulfonate acid generators include α-(p-toluenesulfonyloxyimino)-benzyl cyanide, α-(p-chlorobenzenesulfonyloxyimino)-benzyl cyanide, Δ-(4-nitrobenzenesulfonyloxyimino)-benzyl cyanide, α-(4-nitro-2-trifluoromethylbenzenesulfonyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulfonyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate acid generators disclosed in Japanese Unexamined Patent Application, First Publication No. Hei 09-208554 (Chemical Formulas 18 and 19 shown in paragraphs [0012] to [0014]) and oxime sulfonate acid generators disclosed in WO 2004/074242 A2 pamphlet (Examples 1 to 40 described on pages 65 to 85) may also be used favorably.

Furthermore, the following compounds may also be used as preferred examples.

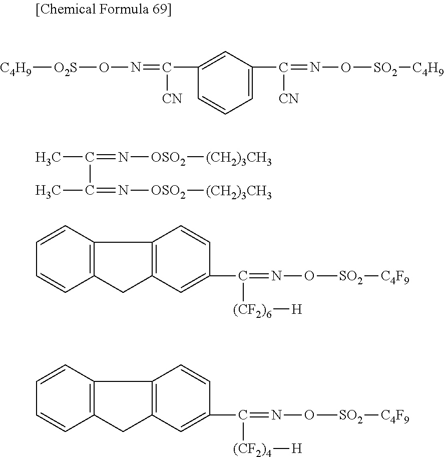

Of the aforementioned diazomethane acid generators for the component (B3), specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may also be used favorably.

Furthermore, examples of poly(bis-sulfonyl)diazomethanes include those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane.

The amount of the component (B) within the resist composition is preferably within a range from 0.5 to 80 parts by weight, more preferably from 1 to 60 parts by weight, and still more preferably from 1 to 50 parts by weight, relative to 100 parts by weight of the component (A). When the amount of the component (B) is within the above range, pattern formation can be performed satisfactorily. Further, a uniform solution can be obtained when each of the components of the resist composition is dissolved in an organic solvent, and the storage stability of the composition tends to improve.

### <Optional Components>

The resist composition of the present invention preferably also includes a nitrogen-containing organic compound (D) (hereinafter referred to as “component (D)”) that does not correspond with the aforementioned component (A) or component (B) as an optional component.

There are no particular limitations on the component (D) provided it functions as an acid diffusion control agent, namely, a quencher which traps the acid generated from the component (B) upon exposure. Examples include amines such as aliphatic amines and aromatic amines, and of these, an aliphatic amine, and particularly a secondary aliphatic amine or tertiary aliphatic amine, is preferable.

An “aliphatic amine” is an amine having one or more aliphatic groups, wherein each of the aliphatic groups preferably contains 1 to 20 carbon atoms.

Examples of these aliphatic amines include amines in which at least one hydrogen atom of ammonia (NH₃) has been substituted with an alkyl group or hydroxyalkyl group of not more than 20 carbon atoms (namely, alkylamines or alkyl alcohol amines), and cyclic amines.

The alkyl group within the alkylamine may be linear, branched or cyclic.

When the alkyl group is a linear or branched group, the alkyl group preferably contains 2 to 20 carbon atoms, and more preferably 2 to 8 carbon atoms.

When the alkyl group is a cyclic group (namely, a cycloalkyl group), the cycloalkyl group preferably contains 3 to 30 carbon atoms, more preferably 3 to 20 carbon atoms, still more preferably 3 to 15 carbon atoms, still more preferably 4 to 12 carbon atoms, and most preferably 5 to 10 carbon atoms. The cycloalkyl group may be either monocyclic or polycyclic. Examples include groups in which one or more hydrogen atoms have been removed from a monocycloalkane, and groups in which one or more hydrogen atoms have been removed from a polycycloalkane such as a bicycloalkane, tricycloalkane or tetracycloalkane. Specific examples of the monocycloalkane include cyclopentane and cyclohexane. Further, specific examples of the polycycloalkane include adamantane, norbornane, isobornane, tricyclodecane and tetracyclododecane.

Specific examples of the alkylamine include monoalkylamines such as n-hexylamine, n-heptylamine, n-octylamine, n-nonylamine and n-decylamine, dialkylamines such as diethylamine, di-n-propylamine, di-n-heptylamine, di-n-octylamine and dicyclohexylamine, and trialkylamines such as trimethylamine, triethylamine, tri-n-propylamine, tri-n-butylamine, tri-n-pentylamine, tri-n-hexylamine, tri-n-heptylamine, tri-n-octylamine, tri-n-nonylamine, tri-n-decanylamine and tri-n-dodecylamine.

Examples of the alkyl group of the hydroxyalkyl group within the aforementioned alkyl alcohol amine include the same groups as those mentioned above for the alkyl group within the alkylamine.

Specific examples of the alkyl alcohol amine include diethanolamine, triethanolamine, diisopropanolamine, triisopropanolamine, di-n-octanolamine, tri-n-octanolamine, stearyldiethanolamine and lauryldiethanolamine.

Examples of the cyclic amine include heterocyclic compounds containing a nitrogen atom as a hetero atom. The heterocyclic compound may be a monocyclic compound (aliphatic monocyclic amine) or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples include 1,5-diazabicyclo[4.3.0]-5-nonene, 1,8-diazabicyclo[5.4.0]-7-undecene, hexamethylenetetramine and 1,4-diazabicyclo[2.2.2]octane.

Examples of other aliphatic amines include tris(2-methoxymethoxyethyl)amine, tris {2-(2-methoxyethoxy)ethyl}amine, tris {2-(2-methoxyethoxymethoxy)ethyl}amine, tris {2-(1-methoxyethoxy)ethyl}amine, tris {2-(1-ethoxyethoxy)ethyl}amine, tris {2-(1-ethoxypropoxy)ethyl}amine, tris [2-{2-(2-hydroxyethoxy)ethoxy}ethyl]amine and triethanolamine triacetate.

Examples of the aromatic amines include aniline, pyridine, 4-dimethylaminopyridine, pyrrole, indole, pyrazole, imidazole and derivatives thereof, diphenylamine, triphenylamine, tribenzylamine, 2,6-diisopropylaniline and N-tert-butoxycarbonyl pyrrolidine.

Further, compounds represented by a general formula (d1) shown below may also be used.

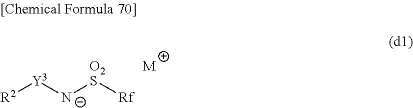

In the formula, R² represents an organic group, Y³ represents a linear, branched or cyclic alkylene group, an arylene group or a single bond, Rf represents a hydrocarbon group containing a fluorine atom, and M⁺ represents a sulfonium or iodonium cation that has no aromaticity.

Anion Moiety of the Compound represented by the General Formula (d1)

In the formula (d1), R² represents an organic group.

There are no particular limitations on the organic group for R², and examples include an alkyl group, an alkoxy group, —O—C(═O)—C(R^{c2})═CH₂ (wherein R^{C2} represents a hydrogen atom, an alkyl group of 1 to 5 carbon atoms or a halogenated alkyl group of 1 to 5 carbon atoms), —O—C(═O)—R^{C3}, —C(—O—C(═O)—R^{C3})—C—O—C(═O)—R^{C3}, and —NH—C(═O)—R^{C3} (wherein each R^{C3} independently represents a hydrocarbon group).

The alkyl group for R² is preferably a linear or branched alkyl group of 1 to 5 carbon atoms, and specific examples include a methyl group, ethyl group, propyl group, isopropyl group, n-butyl group, isobutyl group, tert-butyl group, pentyl group, isopentyl group and neopentyl group. Part of the hydrogen atoms within the alkyl group for R² may each be substituted with a hydroxyl group or a cyano group or the like.

The alkoxy group for R² is preferably an alkoxy group of 1 to 5 carbon atoms, and specific examples of the alkoxy group of 1 to 5 carbon atoms include a methoxy group, ethoxy group, n-propoxy group, iso-propoxy group, n-butoxy group and tert-butoxy group. Among these, a methoxy group or an ethoxy group is particularly desirable.

When R² is a group represented by —O—C(═O)—C(R^{C2})═CH₂, R^{C2} represents a hydrogen atom, an alkyl group of 1 to 5 carbon atoms or a halogenated alkyl group of 1 to 5 carbon atoms.

The alkyl group of 1 to 5 carbon atoms for R^{C2} is preferably a linear or branched alkyl group of 1 to 5 carbon atoms, and specific examples include a methyl group, ethyl group, propyl group, isopropyl group, n-butyl group, isobutyl group, tert-butyl group, pentyl group, isopentyl group and neopentyl group.

The halogenated alkyl group for R^{C2} is a group in which part or all of the hydrogen atoms of an aforementioned alkyl group of 1 to 5 carbon atoms have each been substituted with a halogen atom. Examples of the halogen atom include a fluorine atom, chlorine atom, bromine atom and iodine atom, and a fluorine atom is particularly desirable.

As R^{C2}, a hydrogen atom, an alkyl group of 1 to 3 carbon atoms or a fluorinated alkyl group of 1 to 3 carbon atoms is preferable, and in terms of industrial availability, a hydrogen atom or a methyl group is particularly desirable.

When R² is a group represented by —O—C(═O)—R^{C3}, —C(—O—C(═O)—R^{C3})—C—C(═O)—R^{C3} or —NH—C(═O)—R^{C3}, each R^{C3} independently represents a hydrocarbon group.

The hydrocarbon group for R^{C3} may be either an aromatic hydrocarbon group or an aliphatic hydrocarbon group.

The aromatic hydrocarbon group for R^{C3} is a hydrocarbon group that has aromaticity. The aromatic hydrocarbon group preferably contains 3 to 30 carbon atoms, more preferably 5 to 30 carbon atoms, still more preferably 5 to 20 carbon atoms, still more preferably 6 to 15 carbon atoms, and most preferably 6 to 12 carbon atoms. Here, the number of carbon atoms within substituents is not included in the number of carbon atoms of the aromatic hydrocarbon group.

Specific examples of the aromatic hydrocarbon group include aryl groups in which one hydrogen atom has been removed from an aromatic hydrocarbon ring, such as a phenyl group, biphenylyl group, fluorenyl group, naphthyl group, anthryl group and phenanthryl group, and arylalkyl groups such as a benzyl group, phenethyl group, 1-naphthylmethyl group, 2-naphthylmethyl group, 1-naphthylethyl group and 2-naphthylethyl group. The alkyl chain within the arylalkyl group preferably has 1 to 4 carbon atoms, more preferably 1 or 2 carbon atoms, and most preferably 1 carbon atom.

The aromatic hydrocarbon group may have a substituent. For example, part of the carbon atoms that constitute the aromatic ring within the aromatic hydrocarbon group may be substituted with a hetero atom, or a hydrogen atom bonded to the aromatic ring within the aromatic hydrocarbon group may be substituted with a substituent.

Examples of the former case include heteroaryl groups in which part of the carbon atoms that constitute the ring within an aforementioned aryl group have been substituted with a hetero atom such as an oxygen atom, a sulfur atom or a nitrogen atom, and heteroarylalkyl groups in which part of the carbon atoms that constitute the aromatic hydrocarbon ring within an aforementioned arylalkyl group have been substituted with an aforementioned hetero atom.

In the latter case, examples of the substituent for the aromatic hydrocarbon group include an alkyl group, alkoxy group, halogen atom, halogenated alkyl group, hydroxyl group or oxygen atom (═O) or the like.

The alkyl group as the substituent for the aromatic hydrocarbon group is preferably an alkyl group of 1 to 5 carbon atoms, and most preferably a methyl group, ethyl group, propyl group, n-butyl group or tert-butyl group.

The alkoxy group as the substituent for the aromatic hydrocarbon group is preferably an alkoxy group of 1 to 5 carbon atoms, is more preferably a methoxy group, ethoxy group, n-propoxy group, iso-propoxy group, n-butoxy group or tert-butoxy group, and is most preferably a methoxy group or an ethoxy group.

Examples of the halogen atom as the substituent for the aromatic hydrocarbon group include a fluorine atom, chlorine atom, bromine atom and iodine atom, and a fluorine atom is preferable.

Examples of the halogenated alkyl group as the substituent for the aromatic hydrocarbon group include groups in which part or all of the hydrogen atoms within an aforementioned alkyl group have each been substituted with an aforementioned halogen atom.

The aliphatic hydrocarbon group for R^{C3} may be either a saturated aliphatic hydrocarbon group or an unsaturated aliphatic hydrocarbon group. Further, the aliphatic hydrocarbon group may be linear, branched or cyclic.

In the aliphatic hydrocarbon group for R^{C3}, part of the carbon atoms that constitute the aliphatic hydrocarbon group may be substituted with a substituent containing a hetero atom, or part or all of the hydrogen atoms that constitute the aliphatic hydrocarbon group may each be substituted with a substituent containing a hetero atom.

There are no particular limitations on this “hetero atom” within R^{C3}, provided it is an atom other than a carbon atom or a hydrogen atom. Examples of the hetero atom include a halogen atom, oxygen atom, sulfur atom and nitrogen atom. Examples of the halogen atom include a fluorine atom, chlorine atom, iodine atom and bromine atom. The substituent containing a hetero atom may consist solely of the hetero atom, or may be a group that also contains a group or atom other than the hetero atom.

Specific examples of the substituent for substituting part of the carbon atoms include —O—, —C(═O)—O—, —C(═O)—, —O—C(═O)—O—, —C(═O)—NH—, —NH— (wherein H may be substituted with a substituent such as an alkyl group or an acyl group), —S—, —S(═O)₂— and —S(═O)₂—O—. When the aliphatic hydrocarbon group is cyclic, any of these substituents may be included within the ring structure of the aliphatic hydrocarbon group.

Examples of the substituent for substituting part or all of the hydrogen atoms include an alkoxy group, halogen atom, halogenated alkyl group, hydroxyl group, oxygen atom (═O) and cyano group.

The alkoxy group is preferably an alkoxy group of 1 to 5 carbon atoms, more preferably a methoxy group, ethoxy group, n-propoxy group, iso-propoxy group, n-butoxy group or tert-butoxy group, and most preferably a methoxy group or an ethoxy group.

Examples of the halogen atom include a fluorine atom, chlorine atom, bromine atom and iodine atom, and a fluorine atom is preferable.

Examples of the halogenated alkyl group include groups in which part or all of the hydrogen atoms within an alkyl group of 1 to 5 carbon atoms (such as a methyl group, ethyl group, propyl group, n-butyl group or tert-butyl group) have each been substituted with an aforementioned halogen atom.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably contains 1 to 20 carbon atoms, more preferably 1 to 15 carbon atoms, and most preferably 1 to 10 carbon atoms. Specific examples include a methyl group, ethyl group, propyl group, butyl group, pentyl group, hexyl group, heptyl group, octyl group, nonyl group, decyl group, undecyl group, dodecyl group, tridecyl group, isotridecyl group, tetradecyl group, pentadecyl group, hexadecyl group, isohexadecyl group, heptadecyl group, octadecyl group, nonadecyl group, eicosyl group, heneicosyl group and docosyl group.

The branched saturated hydrocarbon group (alkyl group) preferably contains 3 to 20 carbon atoms, more preferably 3 to 15 carbon atoms, and most preferably 3 to 10 carbon atoms. Specific examples include a 1-methylethyl group, 1-methylpropyl group, 2-methylpropyl group, 1-methylbutyl group, 2-methylbutyl group, 3-methylbutyl group, 1-ethylbutyl group, 2-ethylbutyl group, 1-methylpentyl group, 2-methylpentyl group, 3-methylpentyl group and 4-methylpentyl group.

The unsaturated hydrocarbon group preferably contains 2 to 10 carbon atoms, more preferably 2 to 5 carbon atoms, still more preferably 2 to 4 carbon atoms, and most preferably 3 carbon atoms. Examples of linear monovalent unsaturated hydrocarbon groups include a vinyl group, a propenyl group (allyl group) and a butynyl group. Examples of branched monovalent unsaturated hydrocarbon groups include a 1-methylpropenyl group and a 2-methylpropenyl group.

Among the above examples, a propenyl group is particularly desirable as the unsaturated hydrocarbon group.

Examples of the aliphatic cyclic group include the same groups as those mentioned above for the aliphatic cyclic group for X within the formula (b1).

Among these, the hydrocarbon group for R^{C3} is preferably an alicyclic group in which one or more hydrogen atoms have been removed from a cycloalkane such as cyclopentane, cyclohexane, adamantane, norbornane, isobornane, tricyclodecane or tetracyclododecane, or an aromatic group such as a phenyl group or a naphthyl group. When R^{C3} is an alicyclic group, the resist composition can be dissolved favorably in an organic solvent, thereby improving the lithography properties. Alternatively, when R^{C3} is an aromatic group, the resist composition exhibits excellent photoabsorption efficiency in a lithography process using EUV or the like as the exposure source, resulting in improvements in the sensitivity and the lithography properties.

Of the various possibilities, R² is preferably a group represented by —O—C(═O)—C(R^{C2}′)═CH₂ (wherein R^{C2}′ represents a hydrogen atom or a methyl group) or —O—C(═O)—R^{C3}′ (wherein R^{C3}′ represents an aliphatic cyclic group).

In the formula (d1), Y³ represents a linear, branched or cyclic alkylene group, an arylene group or a single bond.

Examples of the linear, branched or cyclic alkylene group or the arylene group for Y³ include the same groups as the “linear or branched aliphatic hydrocarbon group”, “aliphatic hydrocarbon group that includes a ring within the structure” (including alicyclic hydrocarbon groups (groups in which two hydrogen atoms have been removed from an aliphatic hydrocarbon ring), groups in which an alicyclic hydrocarbon group is bonded to the terminal of a linear or branched aliphatic hydrocarbon group, and groups in which an alicyclic hydrocarbon group is interposed within the chain of a linear or branched aliphatic hydrocarbon group), and “aromatic hydrocarbon group” described above as the divalent linking group for Y² in the aforementioned formula (a1-0-2).

Among these, Y³ is preferably a “linear or branched aliphatic hydrocarbon group” or a single bond. Of these, an alkylene group is preferred, a linear or branched alkylene group is more preferred, and a methylene group or an ethylene group is particularly desirable.

In the formula (d1), Rf represents a hydrocarbon group containing a fluorine atom.

The hydrocarbon group containing a fluorine atom for Rf is preferably a fluorinated alkyl group, wherein the fluorinated alkyl group for Rf may be either a chain-like group or a cyclic group, but is preferably a linear or branched group. The fluorinated alkyl group preferably contains 1 to 11 carbon atoms, more preferably 1 to 8 carbon atoms, and still more preferably 1 to 4 carbon atoms.

Specific examples include groups in which part or all of the hydrogen atoms that constitute a linear alkyl group such as a methyl group, ethyl group, propyl group, butyl group, pentyl group, hexyl group, heptyl group, octyl group, nonyl group or decyl group have each been substituted with a fluorine atom, and groups in which part or all of the hydrogen atoms that constitute a branched alkyl group such as a 1-methylethyl group, 1-methylpropyl group, 2-methylpropyl group, 1-methylbutyl group, 2-methylbutyl group or 3-methylbutyl group have each been substituted with a fluorine atom.

Furthermore, the fluorinated alkyl group for Rf may also include an atom besides a fluorine atom, carbon atom or hydrogen atom, such as an oxygen atom, sulfur atom or nitrogen atom.

Among the above possibilities, the fluorinated alkyl group for Rf is preferably a group in which part or all of the hydrogen atoms that constitute a linear alkyl group have each been substituted with a fluorine atom, and is more preferably a group in which all of the hydrogen atoms that constitute a linear alkyl group have each been substituted with a fluorine atom (namely, a perfluoroalkyl group).

Specific examples of preferred anion moieties for the compound represented by the above formula (d1) are shown below.

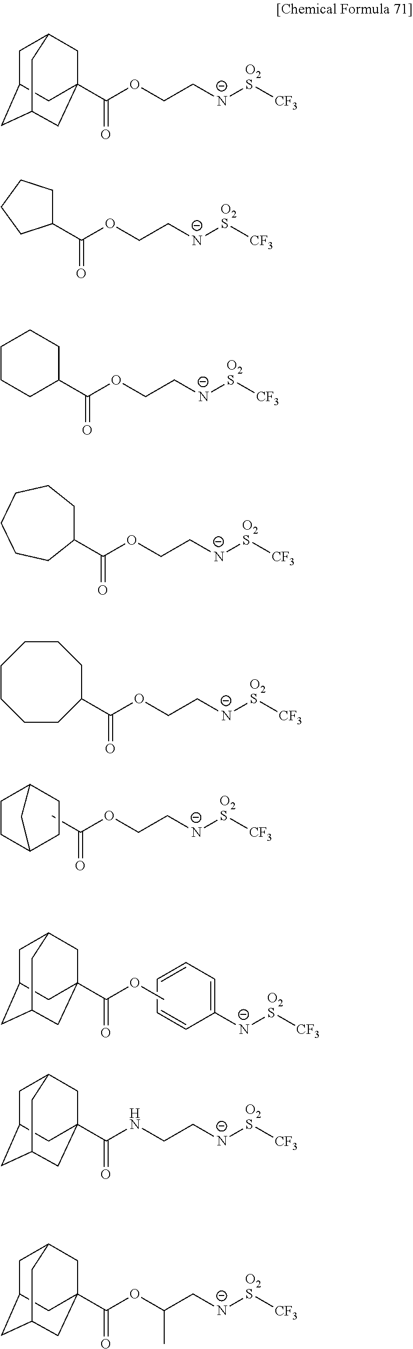

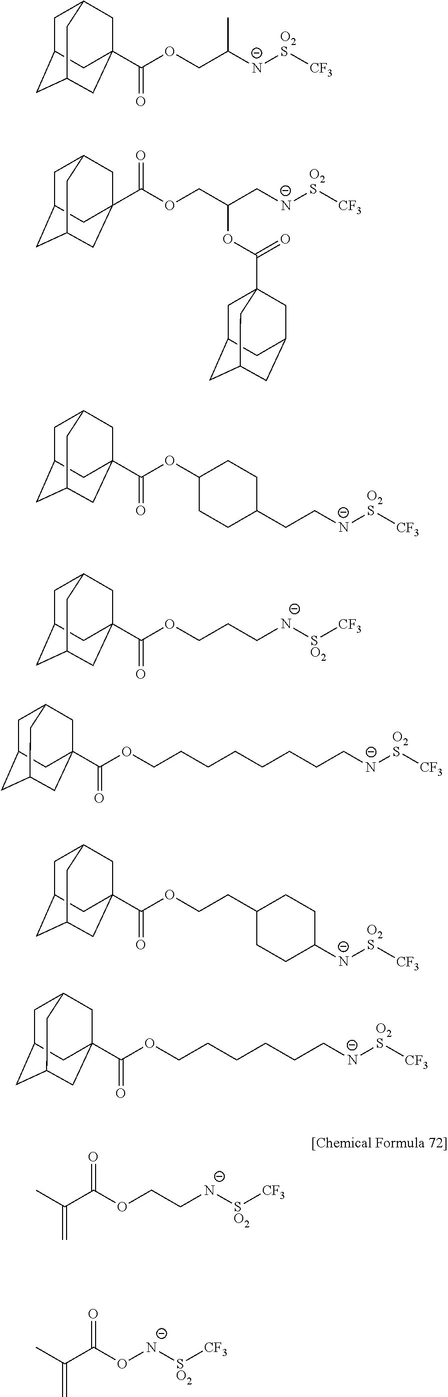

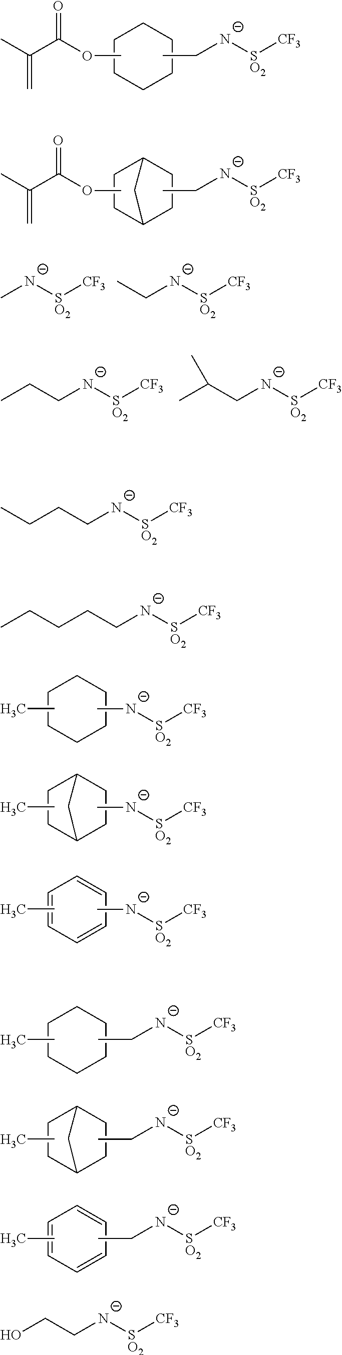

Cation Moiety of the Compound Represented by the General Formula (d1)

In the formula (d1), M⁺ represents a sulfonium or iodonium cation that has no aromaticity. By using a cation that has no aromaticity as M⁺, the cation M⁺ exhibits no photoabsorption of the exposure wavelength in those cases where ArF or the like is used as the exposure source, thus improving the transparency of the component (D).

In the present invention, M⁺ is preferably a cation represented by a general formula (d1-01) or (d1-02) shown below.

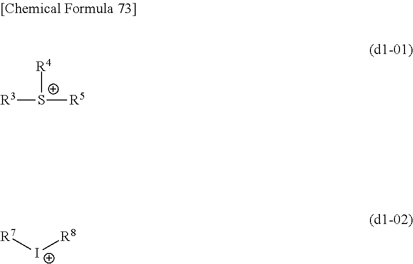

In the above formulas, each of R³ to R⁷ independently represents a chain-like or cyclic alkyl group, wherein two of R³ to R⁵ may be bonded to each other to form a ring together with the sulfur atom in the formula.

In the formula (d1-01), there are no particular limitations on the alkyl groups for R³ to R⁵, and examples include linear, branched or cyclic alkyl groups of 1 to 10 carbon atoms. An alkyl group of 1 to 5 carbon atoms is preferred in terms of achieving superior resolution. Specific examples include a methyl group, ethyl group, n-propyl group, isopropyl group, n-butyl group, isobutyl group, n-pentyl group, cyclopentyl group, hexyl group, cyclohexyl group, nonyl group and decyl group. Among these, a methyl group is the most preferable because it yields excellent resolution and enables synthesis to be conducted at a low cost.

In those cases where two of R³ to R⁵ in the formula (d1-01) are bonded to each other to form a ring together with the sulfur atom in the formula, the ring is preferably a 3- to 10-membered ring, and more preferably a 5- to 7-membered ring, including the sulfur atom.

In the formula (d1-02), the alkyl groups for R⁷ and R⁸ are the same as defined above for the alkyl groups for R³ to R⁵ in the formula (d1-01).

There are no particular limitations on the method used for producing the compound represented by the general formula (d1), and for example in those cases where the terminal of the R² group in the above formula (d1) is an oxygen atom, wherein this oxygen atom is bonded to Y³, the compound of the general formula (d1) can be produced by reacting a compound (i-1) represented by a general formula (i-1) shown below with a compound (i-2) represented by a general formula (i-2) shown below to obtain a compound (i-3) represented by a general formula (i-3) shown below, and subsequently reacting this compound (i-3) with a compound Z⁻M⁺ (i-4) having the desired cation M⁺.

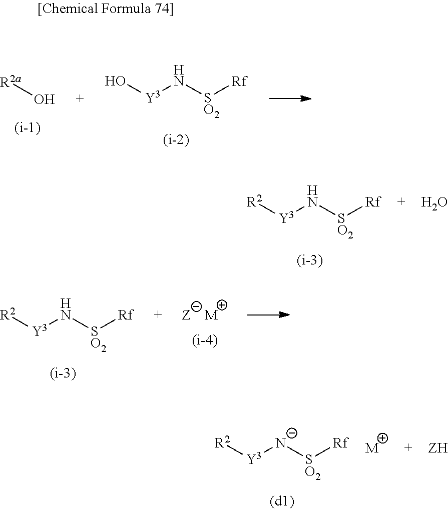

In the above formulas, R², Y³, Rf, and M⁺ are the same as defined above for R², Y³, Rf, and M⁺ in the above general formula (d1). R^{2a} a is a group in which the oxygen atom at the terminal of the R² group has been removed, and Z⁻ represents a counter anion.

First, the compound (i-1) and the compound (i-2) are reacted to obtain the compound (i-3).

In the formula (i-1), R^{2a} is a group in which the oxygen atom at the terminal of the R² group has been removed. In the formula (i-2), Y³ and Rf are the same as defined above.

Commercially available compounds may be used as the compound (i-1) and the compound (i-2), or the compounds may be synthesized.

There are no particular limitations on the method used for reacting the compound (i-1) and the compound (i-2) to obtain the compound (i-3). For example, the compound (i-1) and the compound (i-2) may be reacted together within an organic solvent in the presence of an appropriate acid catalyst, with the reaction mixture then being washed and the product recovered.

There are no particular limitations on the acid catalyst in the above reaction, and examples include toluenesulfonic acid and the like. The amount used of the acid catalyst is preferably within a range from approximately 0.05 to 5 mols relative to 1 mol of the compound (i-2).

The organic solvent used in the above reaction may be any solvent that is capable of dissolving the compound (i-1) and the compound (i-2) that represent the reaction raw materials, and specific examples include toluene and the like. The amount used of the solvent is preferably within a range from 0.5 to 100 parts by weight, and more preferably from 0.5 to 20 parts by weight, per 1 part of the compound (i-1). A single solvent may be used alone, or a combination of two or more solvents may be used.

The amount of the compound (i-2) used in the above reaction is preferably within a range from approximately 0.5 to 5 mols, and more preferably from approximately 0.8 to 4 mols, relative to 1 mol of the compound (i-1).

The reaction time for the above reaction may be determined appropriately in accordance with factors such as the reactivity between the compound (i-1) and the compound (i-2), and the reaction temperature, but in most cases, is preferably within a range from 1 to 80 hours, and more preferably from 3 to 60 hours.

The reaction temperature for the above reaction is preferably within a range from 20 to 200° C., and more preferably from approximately 20 to 150° C.

Subsequently, the obtained compound (i-3) is reacted with a compound (i-4) to obtain a compound represented by the formula (d1).

In the formula (i-4), M⁺ is the same as defined above, and Z⁻ represents a counter anion.

There are no particular limitations on the method used for reacting the compound (i-3) with the compound (i-4) to obtain the compound represented by the formula (d1). For example, the compound (i-3) may be dissolved in an appropriate organic solvent and water in the presence of a suitable alkali metal hydroxide, with the compound (i-4) then being added and stirred to effect the reaction and obtain the compound represented by the formula (d1).

There are no particular limitations on the alkali metal hydroxide used in the above reaction, and examples include sodium hydroxide and potassium hydroxide. The amount used of the alkali metal hydroxide is preferably within a range from approximately 0.3 to 3 mols relative to 1 mol of the compound (i-3).

Examples of the organic solvent used in the above reaction include dichloromethane, chloroform and ethyl acetate, and the amount used of the solvent is preferably within a range from 0.5 to 100 parts by weight, and more preferably from 0.5 to 20 parts by weight, par 1 part of the compound (i-3). A single solvent may be used alone, or a combination of two or more solvents may be used.

The amount of the compound (i-4) used in the above reaction is preferably within a range from approximately 0.5 to 5 mols, and more preferably from approximately 0.8 to 4 mols, relative to 1 mol of the compound (i-3).

The reaction time for the above reaction may be determined appropriately in accordance with factors such as the reactivity between the compound (i-3) and the compound (i-4), and the reaction temperature, but in most cases, is preferably within a range from 1 to 80 hours, and more preferably from 3 to 60 hours.

The reaction temperature for the above reaction is preferably within a range from 20 to 200° C., and more preferably from approximately 20 to 150° C.

Following completion of the reaction, the compound represented by the formula (d1) may be isolated from the reaction solution and purified. Isolation and purification may be conducted using conventional methods, and for example, one or more techniques such as concentration, solvent extraction, distillation, crystallization, recrystallization and chromatography may be used.

The structure of the compound represented by the formula (d1) obtained in the manner described above can be confirmed by general organic analysis methods such as ¹H nuclear magnetic resonance (NMR) spectrometry, ¹³C-NMR spectrometry, ¹⁹F-NMR spectrometry, infrared (IR) absorption spectrometry, mass spectrometry (MS), elemental analysis methods, and X-ray crystal diffraction analysis.

As the component (D), a single compound may be used alone, or two or more compounds may be used in combination.

The amount of the component (D) within the resist composition is typically within a range from 0.01 to 10 parts by weight relative to 100 parts by weight of the component (A). When the amount of the component (D) is within the above range, the shape of the resist pattern and the post exposure stability of the latent image formed by the pattern-wise exposure of the resist layer are improved.

Furthermore, in the resist composition of the present invention, for the purposes of preventing any deterioration in sensitivity, and improving the resist pattern shape and the post exposure stability of the latent image formed by the pattern-wise exposure of the resist layer, at least one compound (E) (hereinafter referred to as “component (E)”) selected from the group consisting of organic carboxylic acids, and phosphorus oxo acids and derivatives thereof may also be added as an optional component.

Examples of the organic carboxylic acids include acetic acid, malonic acid, citric acid, malic acid, succinic acid, benzoic acid and salicylic acid.

Examples of the phosphorus oxo acids include phosphoric acid, phosphonic acid and phosphinic acid. Among these, phosphonic acid is particularly desirable.

Examples of the phosphorus oxo acid derivatives include esters in which a hydrogen atom within an aforementioned oxo acid is substituted with a hydrocarbon group. Examples of the hydrocarbon group include alkyl groups of 1 to 5 carbon atoms and aryl groups es of phosphoric acid derivatives include phosphate esters such as di-n-butyl phosphate and diphenyl phosphate.

Examples of phosphonic acid derivatives include phosphonate esters such as dimethyl phosphonate, di-n-butyl phosphonate, diphenyl phosphonate and dibenzyl phosphonate, as well as phenylphosphonic acid.

Examples of phosphinic acid derivatives phosphinate esters of phenylphosphinic acid and the like.

Salicylic acid is particularly preferred as the component (E).

As the component (E), one compound may be used alone, or two or more different compounds may be used in combination.

In the resist composition, the amount of the component (E) is typically within a range from 0.01 to 10 parts by weight relative to 100 parts by weight of the component (A).

### <Component (F)>

A fluorine additive (hereinafter referred to as “component (F)”) may also be added to the resist composition of the present invention for the purpose of imparting the resist film with water repellency.

Examples of the component (F) include the fluorine-containing polymeric compounds disclosed in Japanese Unexamined Patent Application, First Publication No. 2010-002870.

Specific examples of preferred compounds for the component (F) include polymers having a structural unit represented by a general formula (f1) shown below. More specifically, polymers (homopolymers) composed solely of a structural unit represented by the formula (f1) shown below, copolymers containing a structural unit represented by the formula (f1) shown below and an aforementioned structural unit (a1), and copolymers containing a structural unit represented by the formula (f1) shown below, a structural unit derived from acrylic acid or methacrylic acid, and an aforementioned structural unit (a1) are particularly preferred. Among the various structural units (a1), a structural unit represented by the above formula (a1-1-32) is particularly desirable.

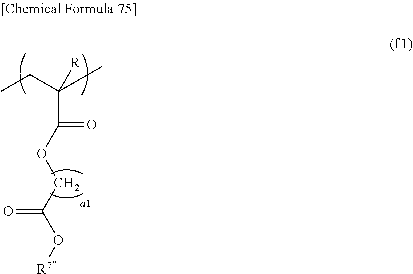

In the formula, R represents a hydrogen atom, an alkyl group of 1 to 5 carbon atoms or a halogenated alkyl group of 1 to 5 carbon atoms, a1 represents an integer of 1 to 5, and R⁷″ represents an organic group containing a fluorine atom.

In the above formula (f1), R⁷″ represents an organic group containing a fluorine atom, and is preferably a hydrocarbon group containing a fluorine atom. Examples of the hydrocarbon group containing a fluorine atom include the same groups as those mentioned above for Rf within the above formula (d1). Among these groups, R⁷″ is preferably a group represented by a formula —(CH₂)ₒ—CF₃ (wherein o represents the number of repeating CH₂ units, and is typically an integer of 1 to 3). In the formula (f1), a1 represents an integer of 1 to 5, preferably an integer of 1 to 3, and more preferably 1 or 2.

In the formula (f1), R represents a hydrogen atom, an alkyl group of 1 to 5 carbon atoms or a halogenated alkyl group of 1 to 5 carbon atoms. R is preferably a hydrogen atom or a methyl group.

As the component (F), a single compound may be used alone, or two or more compounds may be used in combination.

The amount of the component (F) within the resist composition is preferably within a range from 1 to 10 parts by weight relative to 100 parts by weight of the component (A).

If desired, other miscible additives may also be added to the resist composition of the present invention in appropriate amounts. Examples of such miscible additives include additive resins for improving the performance of the resist film, surfactants for improving the applicability, dissolution inhibitors, plasticizers, stabilizers, colorants, halation prevention agents, and dyes.

The resist composition of the present invention can be prepared by dissolving the materials for the resist composition in an organic solvent (hereinafter also referred to as “component (S)”).

The component (S) may be any organic solvent which can dissolve each of the components used to give a uniform solution, and one or more types of organic solvent may be selected appropriately from those solvents that have been conventionally known as solvents for a chemically amplified resists.

Examples include lactones such as γ-butyrolactone; ketones such as acetone, methyl ethyl ketone, cyclohexanone, methyl-n-pentyl ketone, methyl isopentyl ketone and 2-heptanone; polyhydric alcohols such as ethylene glycol, diethylene glycol, propylene glycol and dipropylene glycol; polyhydric alcohol derivatives, including compounds having an ester bond such as ethylene glycol monoacetate, diethylene glycol monoacetate, propylene glycol monoacetate and dipropylene glycol monoacetate, and compounds having an ether bond, such as a monoalkyl ether (such as a monomethyl ether, monoethyl ether, monopropyl ether or monobutyl ether) or a monophenyl ether of any of the above polyhydric alcohols or compounds having an ester bond [among these derivatives, propylene glycol monomethyl ether acetate (PGMEA) and propylene glycol monomethyl ether (PGME) are preferred]; cyclic ethers such as dioxane; esters such as methyl lactate, ethyl lactate (EL), methyl acetate, ethyl acetate, butyl acetate, methyl pyruvate, ethyl pyruvate, methyl methoxypropionate and ethyl ethoxypropionate; and aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene and mesitylene.

These organic solvents may be used individually, or as a mixed solvent containing two or more solvents.

Among the above solvents, propylene glycol monomethyl ether acetate (PGMEA), propylene glycol monomethyl ether (PGME), γ-butyrolactone, cyclohexanone, and ethyl lactate (EL) are preferred.

Further, among the mixed solvents, a mixed solvent obtained by mixing PGMEA with a polar solvent is preferable. The mixing ratio (weight ratio) of the mixed solvent may be determined as appropriate, with due consideration of the compatibility of the PGMEA with the polar solvent, but is preferably within a range from 1:9 to 9:1, and more preferably from 2:8 to 8:2. For example, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably from 3:7 to 7:3. Furthermore, when PGME and cyclohexanone are mixed as the polar solvent, the PGMEA:(PGME+cyclohexanone) weight ratio is preferably from 1:9 to 9:1, more preferably from 2:8 to 8:2, and still more preferably from 3:7 to 7:3.

Further, as the component (S), a mixed solvent of PGMEA, EL or an aforementioned mixed solvent of PGMEA and a polar solvent, with γ-butyrolactone is also preferable. In this case, the mixing ratio (former:latter) of such a mixed solvent is preferably from 70:30 to 95:5.

There are no particular limitations on the amount used of the component (S), which may be adjusted appropriately to produce a concentration that enables application of a coating solution onto a substrate in accordance with the thickness of the coating film. In general, the organic solvent is used in an amount that yields a solid fraction concentration for the resist composition that is within a range from 1 to 20% by weight, and preferably from 2 to 15% by weight.

The resist composition of the present invention described above is capable of forming a resist pattern having an excellent shape with a high rectangularity. The reason why these effects can be achieved has not elucidated yet, but the following is presumed.

As pattern miniaturization progresses, it becomes more difficult for the light to reach those portions near the substrate during the exposure process that is performed during resist pattern formation.

It is considerated that the acid generator (B1) which generates an alicyclic hydrocarbon group-containing acid exhibits short diffusion properties. As a result, it is presumed that a resist composition containing the component (B1) is effective in improving the resolution. However, depending on the optical conditions, the deprotection reaction may not proceed satisfactorily near the substrate interface, so that footing of the formed resist pattern is likely to occur (i.e., the formed resist pattern is likely to have a trapezoidal shape). Conventionally used acid generators having a fluorinated alkyl sulfona

te ion such as C₄F₉SO₃⁻ as the anion moiety exhibit long diffusion properties, but they also have comparatively high hydrophobicity, and tend to be segregated near the resist film surface. Therefore, in the case where a positive-type resist pattern is formed using an alkali developing process, even if an acid generator having a fluorinated alkyl sulfonate ion as the anion moiety is used in combination with the aforementioned acid generator (B1) in a resist composition, the acid generated upon exposure from the acid generator having a fluorinated alkyl sulfonate ion as the anion moiety does not readily diffuse through to the vicinity of the substrate, meaning so that deprotection of the resin component does not occur readily in the portions of the resist film near the substrate. As such, the resist film cannot be satisfactorily resolved through to the interface between the resist film and the substrate, and hence, the formed resist pattern tends to exhibit footing (the formed resist pattern tends to have a trapezoidal shape).

The resist composition according to the present invention (a positive-type composition in this case) includes the acid generator (B1) having short diffusion properties that generates an alicyclic hydrocarbon group-containing acid, and the acid generator (B2) having long diffusion properties that generates a chain-like aliphatic hydrocarbon group-containing acid. These acid generators include oxygen atoms and the like, and it is presumed that the interaction between these oxygen atoms and the base component (A) facilitates uniform distribution of the acid generators within the resist film. Further, by combining the component (B1) and the component (B2) that have different diffusion properties, acid can be satisfactorily diffused to the vicinity of the substrate where it is difficult for light to reach mainly by the action of component (B2). On the other hand, at the central portions of the resist film where the energy levels have been increased significantly by the exposure, diffusion of the acid generated from the component (B2) is appropriately controlled by the component (B1). As a result, the deprotection or the like of the resin component near the substrate is promoted, whereas at the central portions of the resist film, dissolution in an alkali developing solution is suppressed, making thereby rendering all of the exposed portions to be dissolved more uniformly in an alkali developing solution. As such, it is presumed that, the resist composition of the present invention capable of forming a resist pattern having an excellent shape with a high rectangularity, without deterioration in the resolution. It is also presumed that by selecting, as the cation moiety for the component (B1), a cation having a substituent introduced such as the cations represented by formulas (b-c1-13) to (b-c1-21), (b-c1-25) to (b-c1-29) or (b-c12-4) to (b-c12-6), the component (B1) can be distributed more readily in an upper layer of the resist film. As a result, it is presumed that the effect of the component (B1) in appropriately controlling the diffusion of the acid generated from the component (B2) can be enhanced, thereby improving the aforementioned lithography properties.

### <<Method of Forming Resist Pattern>>

The method of forming a resist pattern according to the present invention includes: forming a resist film on a substrate using the resist composition according to the present invention described above, conducting exposure of the resist film, and developing the resist film to form a resist pattern.

The method for forming a resist pattern according to the present invention can be performed, for example, as follows.

First, the resist composition of the present invention is applied onto a substrate using a spinner or the like, and a bake treatment (post applied bake (PAB)) is conducted under temperature conditions of 80 to 150° C. for 40 to 120 seconds, and preferably 60 to 90 seconds to form a resist film.

Subsequently, the resist film is selectively exposed using an exposure apparatus such as an ArF exposure apparatus, electron beam exposure apparatus or EUV exposure apparatus, either by irradiation through a mask having a predetermined pattern formed therein (namely, a mask pattern), or by patterning via direct irradiation with an electron beam without using a mask pattern, and the resist film is then subjected to a bake treatment (post exposure bake (PEB)) under temperature conditions of 80 to 150° C. for 40 to 120 seconds, and preferably 60 to 90 seconds.

Next, the resist film is subjected to a developing treatment.

The developing treatment is performed using an alkali developing solution in the case of an alkali developing process, or using a developing solution containing an organic solvent (an organic developing solution) in the case of a solvent developing process.

A rinse treatment is preferably performed following the developing treatment. In the case of an alkali developing process, the rinse treatment is preferably performed using pure water, whereas in the case of a solvent developing process, the rinse treatment is preferably performed using a rinse liquid containing an organic solvent.

In the case of a solvent developing process, residual developing solution or rinse liquid adhered to the pattern following the developing treatment and/or rinse treatment may be removed using a supercritical fluid.

Drying is performed following the developing treatment or rinse treatment. Further, in some cases, a bake treatment (post bake) may be performed following the developing treatment. In this manner, a resist pattern can be obtained.

There are no particular limitations on the substrate, and a conventionally known substrate may be used. For example, substrates for electronic components, and such substrates having wiring patterns formed thereon can be used. Specific examples of the material of the substrate include metals such as silicon wafer, copper, chromium, iron and aluminum, as well as glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) or an organic film such as the lower organic film in a multilayer resist method can be used.

Here, a “multilayer resist method” is a method in which at least one layer of an organic film (a lower-layer organic film) and at least one layer of a resist film (an upper-layer resist film) are provided on a substrate, and a resist pattern formed within the upper-layer resist film is used as a mask to conduct patterning of the lower-layer organic film. This method is capable of forming a pattern with a high aspect ratio. In other words, in the multilayer resist method, a desired thickness can be ensured by the lower-layer organic film, and as a result, the thickness of the resist film can be reduced, and an extremely fine pattern with a high aspect ratio can be formed.

The multilayer resist method can be broadly classified into a method in which a double-layer structure consisting of an upper-layer resist film and a lower-layer organic film is formed (a double-layer resist method), and a method in which a multilayer structure having at least three layers consisting of an upper-layer resist film, a lower-layer organic film and at least one intermediate layer (a thin metal film or the like) provided between the upper-layer resist film and the lower-layer organic film is formed (a three-layer resist method).

There are no particular limitations on the wavelength used for exposure, and the exposure can be conducted using radiation such as an ArF excimer laser, KrF excimer laser, F₂ excimer laser, extreme ultraviolet radiation (EUV), vacuum ultraviolet radiation (VUV), electron beam (EB), X-rays, and soft X-rays. The resist composition of the present invention is particularly effective for use with a KrF excimer laser, ArF excimer laser, EB or EUV.

The method of exposing the resist film may employ either a general exposure method (dry exposure) conducted in air or an inert gas such as nitrogen, or an immersion exposure method (a liquid immersion lithography method).

Liquid immersion lithography is a method in which the region between the resist film and the lens at the lowermost portion of the exposure apparatus is pre-filled with a solvent (an immersion medium) that has a larger refractive index than the refractive index of air, and the exposure (immersion exposure) is conducted in this state.

The immersion medium preferably exhibits a refractive index larger than the refractive index of air but smaller than the refractive index of the resist film that is to be exposed. The refractive index of the immersion medium is not particularly limited as long at it satisfies the above requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point that is preferably within a range from 70 to 180° C., and more preferably from 80 to 160° C. A fluorine-based inert liquid having a boiling point within the above-mentioned range is advantageous in that the removal of the immersion medium after the exposure can be conducted by a simple method.

As the fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point: 102° C.), and one example of a suitable perfluoroalkylamine compound is perfluorotributylamine (boiling point: 174° C.).

As the immersion medium, water is preferable in terms of cost, safety, environmental issues and versatility.

Examples of the alkali developing solution used in an alkali developing process include 0.1 to 10% by weight aqueous solutions of tetramethylammonium hydroxide (TMAH).

The organic solvent within the organic developing solution that is used in the solvent developing process may be selected appropriately from among any of the conventional solvents capable of dissolving the component (A) (the component (A) prior to exposure). Specific examples of organic solvents that may be used include polar solvents such as ketone-based solvents, ester-based solvents, alcohol-based solvents, amide-based solvents and ether-based solvents, and hydrocarbon solvents.

Conventional additives may be added to the organic developing solution as required. Examples of these additives include surfactants. There are no particular limitations on the surfactants, and ionic and nonionic fluorine-based surfactants and/or silicon-based surfactants can be used.

In those cases where a surfactant is added, the amount of the surfactant is typically within a range from 0.001 to 5% by weight, more preferably from 0.005 to 2% by weight, and still more preferably from 0.01 to 0.5% by weight, relative to the total weight of the organic developing solution.

The developing treatment can be performed using a conventional developing method. Examples of developing methods that may be used include methods in which the substrate is dipped in the developing solution for a predetermined period of time (dipping methods), methods in which the developing solution is placed and held on the surface of the substrate by surface tension for a predetermined period of time (puddle methods), methods in which the developing solution is sprayed onto the substrate surface (spray methods), and methods in which the substrate is spun at a constant rate, and a developing solution discharge nozzle is then scanned across the substrate at a constant rate while the developing solution is discharged from the nozzle (dynamic dispensing methods).

Examples of the organic solvent contained within the rinse liquid used for the rinse treatment performed following a solvent developing process include those organic solvents among the solvents described above for the organic solvent of the organic developing solution which exhibit poor dissolution of the resist pattern. Examples of typical solvents that may be used include one or more solvents selected from among hydrocarbon solvents, ketone-based solvents, ester-based solvents, alcohol-based solvents, amide-based solvents and ether-based solvents. Among these, at least one solvent selected from among hydrocarbon solvents, ketone-based solvents, ester-based solvents, alcohol-based solvents and amide-based solvents is preferred, at least one solvent selected from among alcohol-based solvents and ester-based solvents is more preferred, and an alcohol-based solvent is particularly desirable.

The rinse treatment (washing treatment) using a rinse liquid may be performed using a conventional rinse method. Examples of methods that may be used include methods in which the rinse liquid is discharged continuously onto the substrate while the substrate is spun at a constant rate (spin coating methods), methods in which the substrate is dipped in the rinse liquid for a predetermined period of time (dipping methods) and methods in which the rinse liquid is sprayed onto the substrate surface (spray methods).

### EXAMPLES

A more detailed description of the present invention is presented below based on a series of examples, although the present invention is in no way limited by these examples.

### Examples 1 to 12, Comparative Examples 1 to 4

The components shown in Tables 1 and 2 were mixed together and dissolved to prepare a series of resist compositions.

In the tables, the column labeled “(B2)/(B1+B2) molar ratio” represents the molar ratio of the number of mols of the component (B2) relative to the total number of mols of the component (B1) and the component (B2) within the resist composition.

TABLE 1

| | Component | Component | Component | (B2)/(B1 + B2) | Component | Component | Component | Component | Component | |
|---|---|---|---|---|---|---|---|---|---|---|
| | (A) | (B1) | (B2) | molar ratio | (B3) | (D) | (E) | (F) | (S) | |
| Comparative | (A)-2 | (B1)-1 | — | — | (B3)-1 | (D)-1 | (E)-1 | (F)-1 | (S)-1 | (S)-2 |
| example 1 | [100] | [9.15] | | | [1.00] | [0.45] | [0.75] | [3.0] | [10] | [2700] |
| | | | | | (B3)-2 | | | | | |
| | | | | | [2.3] | | | | | |
| Comparative | (A)-2 | (B1)-1 | — | — | (B3)-1 | (D)-1 | (E)-1 | (F)-1 | (S)-1 | (S)-2 |
| example 2 | [100] | [9.15] | | | [1.00] | [0.45] | [0.75] | [3.0] | [10] | [2700] |
| | | | | | (B3)-3 | | | | | |
| | | | | | [3.15] | | | | | |
| Example 1 | (A)-2 | (B1)-1 | (B2)-2 | 33.1 | (B3)-1 | (D)-1 | (E)-1 | (F)-1 | (S)-1 | (S)-2 |
| | [100] | [9.15] | [2.8] | | [1.00] | [0.45] | [0.75] | [3.0] | [10] | [2700] |
| Example 2 | (A)-2 | (B1)-1 | (B2)-1 | 35.0 | (B3)-1 | (D)-1 | (E)-1 | (F)-1 | (S)-1 | (S)-2 |
| | [100] | [9.15] | [4.05] | | [1.00] | [0.45] | [0.75] | [3.0] | [10] | [2700] |
| Example 3 | (A)-2 | (B1)-1 | (B2)-1 | 25.0 | (B3)-1 | (D)-1 | (E)-1 | (F)-1 | (S)-1 | (S)-2 |
| | [100] | [9.15] | [2.5] | | [1.00] | [0.45] | [0.75] | [3.0] | [10] | [2700] |
| Example 4 | (A)-2 | (B1)-1 | (B2)-1 | 11.7 | (B3)-1 | (D)-1 | (E)-1 | (F)-1 | (S)-1 | (S)-2 |
| | [100] | [9.15] | [1.00] | | [1.00] | [0.45] | [0.75] | [3.0] | [10] | [2700] |
| Example 5 | (A)-2 | (B1)-1 | (B2)-1 | 50.8 | (B3)-1 | (D)-1 | (E)-1 | (F)-1 | (S)-1 | (S)-2 |
| | [100] | [9.15] | [4.05] | | [1.00] | [0.45] | [0.75] | [3.0] | [10] | [2700] |
| | | | (B2)-2 | | | | | | | |
| | | | [2.8] | | | | | | | |
| Example 6 | (A)-2 | (B1)-1 | (B2)-1 | 45.3 | (B3)-1 | (D)-1 | (E)-1 | (F)-1 | (S)-1 | (S)-2 |
| | [100] | [9.15] | [2.5] | | [1.00] | [0.45] | [0.75] | [3.0] | [10] | [2700] |
| | | | (B2)-2 | | | | | | | |
| | | | [2.8] | | | | | | | |
| Example 7 | (A)-2 | (B1)-1 | (B2)-1 | 38.6 | (B3)-1 | (D)-1 | (E)-1 | (F)-1 | (S)-1 | (S)-2 |
| | [100] | [9.15] | [1.0] | | [1.00] | [0.45] | [0.75] | [3.0] | [10] | [2700] |
| | | | (B2)-2 | | | | | | | |
| | | | [2.8] | | | | | | | |
| Comparative | (A)-2 | (B1)-1 | — | — | (B3)-1 | (D)-1 | (E)-1 | (F)-1 | (S)-1 | (S)-2 |
| example 3 | [100] | [9.15] | | | [1.00] | [0.45] | [0.75] | [3.0] | [10] | [2700] |
| | | | | | (B3)-4 | | | | | |
| | | | | | [0.90] | | | | | |

TABLE 2

| | Component | Component | Component | (B2)/(B1 + B2) | Component | Component | Component | Component | |
|---|---|---|---|---|---|---|---|---|---|
| | (A) | (B1) | (B2) | molar ratio | (D) | (E) | (F) | (S) | |
| Comparative | (A)-1 | (B1)-2 | — | — | (D)-2 | (E)-1 | (F)-1 | (S)-1 | (S)-2 |
| example 4 | [100] | [12.5] | | | [3.78] | [0.75] | [3.0] | [10] | [2700] |
| | | (B1)-5 | | | | | | | |
| | | [1.9] | | | | | | | |
| Example 8 | (A)-1 | (B1)-2 | (B2)-1 | 4.1 | (D)-2 | (E)-1 | (F)-1 | (S)-1 | (S)-2 |
| | [100] | [12.5] | [0.5] | | [3.78] | [0.75] | [3.0] | [10] | [2700] |
| | | (B1)-5 | | | | | | | |
| | | [1.9] | | | | | | | |
| Example 9 | (A)-1 | (B1)-2 | (B2)-1 | 11.4 | (D)-2 | (E)-1 | (F)-1 | (S)-1 | (S)-2 |
| | [100] | [12.5] | [1.5] | | [3.78] | [0.75] | [3.0] | [10] | [2700] |
| | | (B1)-5 | | | | | | | |
| | | [1.9] | | | | | | | |
| Example 10 | (A)-1 | (B1)-3 | (B2)-1 | 20.3 | (D)-2 | (E)-1 | (F)-1 | (S)-1 | (S)-2 |
| | [100] | [12.5] | [3.0] | | [3.78] | [0.75] | [3.0] | [10] | [2700] |
| | | (B1)-5 | | | | | | | |
| | | [1.9] | | | | | | | |
| Example 11 | (A)-1 | (B1)-4 | (B2)-1 | 19.8 | (D)-2 | (E)-1 | (F)-1 | (S)-1 | (S)-2 |
| | [100] | [12.5] | [3.0] | | [3.78] | [0.75] | [3.0] | [10] | [2700] |
| | | (B1)-5 | | | | | | | |
| | | [1.9] | | | | | | | |
| Example 12 | (A)-1 | (B1)-2 | (B2)-1 | 20.4 | (D)-2 | (E)-1 | (F)-1 | (S)-1 | (S)-2 |
| | [100] | [12.5] | [3.0] | | [3.78] | [0.75] | [3.0] | [10] | [2700] |
| | | (B1)-5 | | | | | | | |
| | | [1.9] | | | | | | | |

The reference characters in Tables 1 and 2 have the following meanings. Further, the numerical values in brackets [ ] indicate the amount (in terms of parts by weight) of the component added.

(A)-1: a polymeric compound represented by a chemical formula (A1-1) shown below.

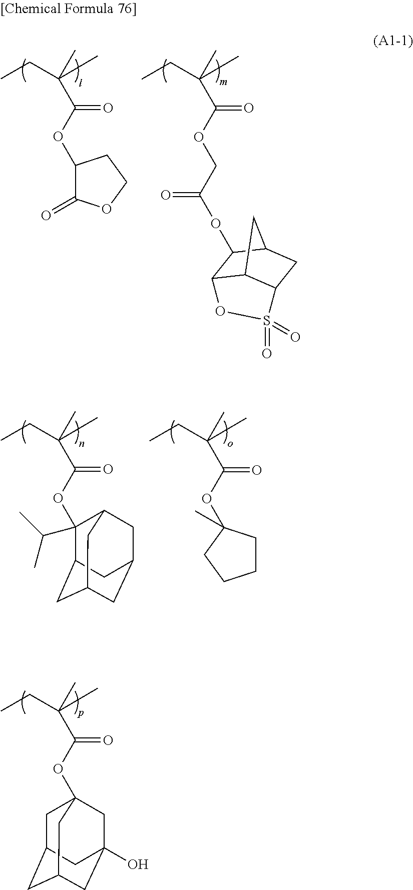

l/m/n/o/p=35/24/16/13/12 (molar ratio), Mw=6,900, Mw/Mn=1.61.

(A)-2: a polymeric compound represented by a chemical formula (A1-2) shown below.

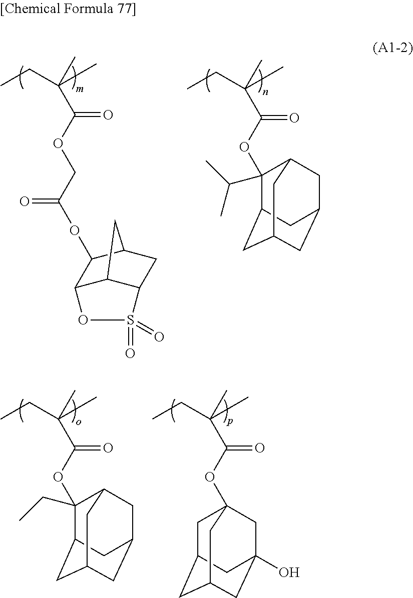

l/m/n/o=35/40/15/10 (molar ratio), Mw=7,000, Mw/Mn=1.5.

(B1)-1 to (B1)-5: compounds represented respectively by chemical formulas (B1-1) to (B1-5) shown below.

(B2)-1: a compound represented by a chemical formula (B2-1) shown below.

(B2)-2: a compound represented by a chemical formula (B2-2) shown below.

(B3)-1: triphenylsulfonium d-camphor-10-sulfonate.

(B3)-2: triphenylsulfonium trifluoromethanesulfonate.

(B3)-3: triphenylsulfonium nonafluoro-n-butanesulfonate.

(B3)-4: a compound represented by a chemical formula (B3-4) shown below.

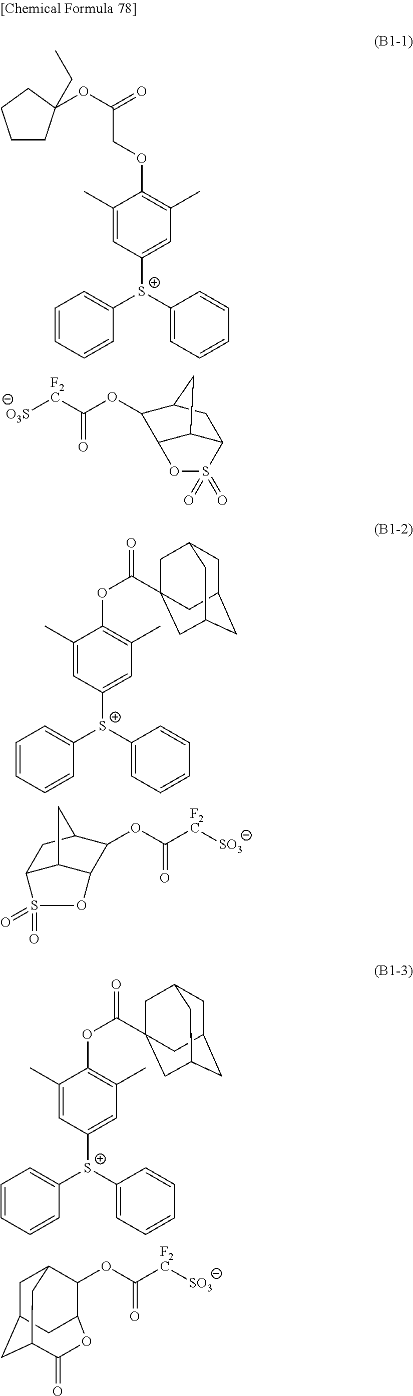

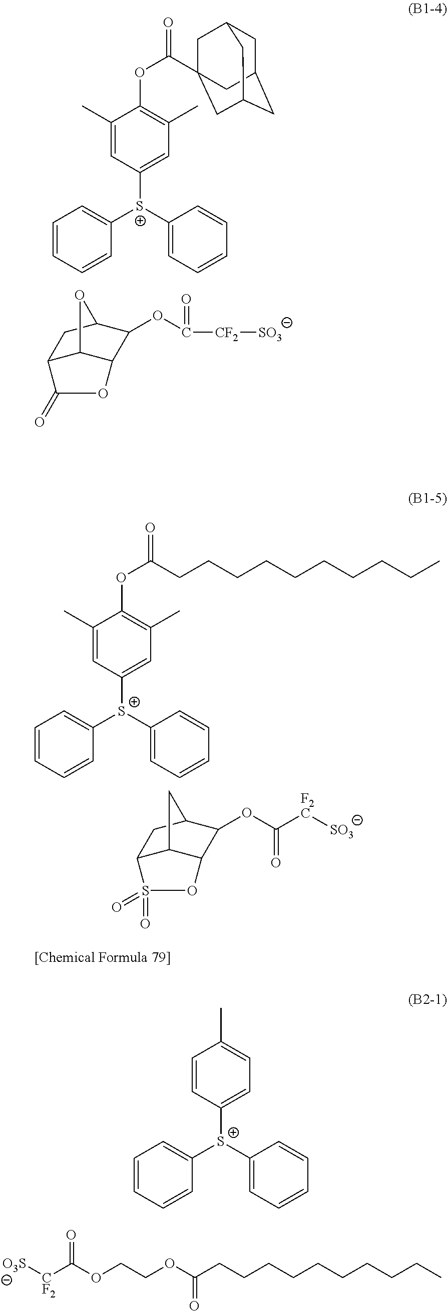

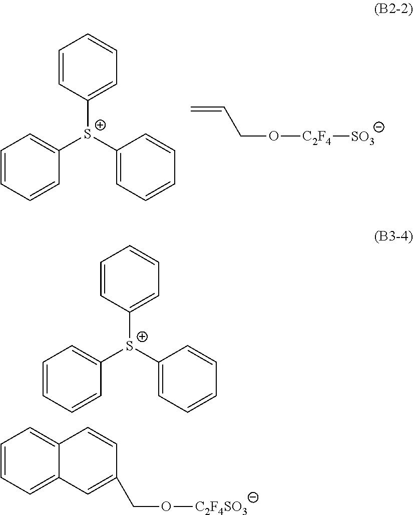

(D)-1: tri-n-pentylamine.

(D)-2: a compound represented by a chemical formula (D-2) shown below.

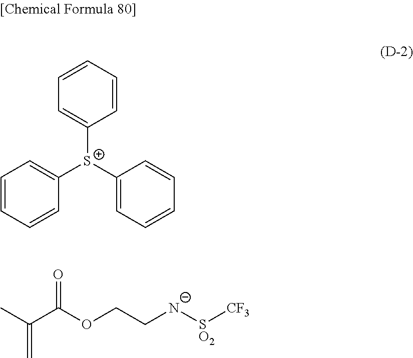

(E)-1: salicylic acid.

(F)-1: a polymeric compound represented by a chemical formula (F-1) shown below.

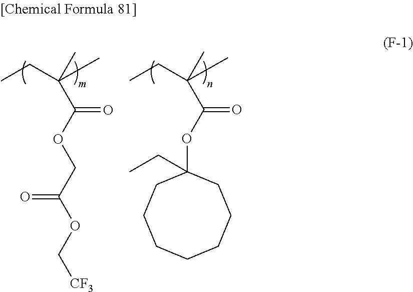

m/n=80/20 (molar ratio), Mw=13,800, Mw/Mn=1.5.

(S)-1: γ-butyrolactone.

(S)-2: a mixed solvent of PGMEA/PGME/cyclohexanone=30/45/25 (weight ratio).

Each of the obtained resist compositions was subjected to the evaluations described below.

### [Resist Pattern Formation (1)]

An organic antireflection film composition ARC29 (a product name, manufactured by Brewer Science Ltd.) was applied onto an 8-inch silicon wafer using a spinner, and the composition was then baked and dried on a hotplate at 205° C. for 60 seconds, thereby forming an organic antireflection film having a film thickness of 77 nm.

Each of the resist compositions prepared above was applied onto a thus formed antireflection film using a spinner, and was then subjected to a bake (PAB) treatment on a hotplate at a PAB temperature indicated in Table 3 for 60 seconds and dried, thereby forming a resist film having a film thickness of 100 nm.

Subsequently, using an ArF exposure apparatus NSR-S302A (manufactured by Nikon Corporation, NA (numerical aperture)=0.60, ⅔ annular illumination), the resist film was selectively irradiated with an ArF excimer laser (193 nm) through a mask pattern (6% halftone mask).

Next, a bake (PEB) treatment was conducted at a PEB temperature indicated in Table 3 for 60 seconds, followed by alkali development for 30 seconds at 23° C. in a 2.38% by weight aqueous solution of TMAH (product name: NMD-3, manufactured by Tokyo Ohka Kogyo Co., Ltd.). The resist film was then rinsed for 30 seconds with pure water, and subjected to an additional bake treatment (postbake) at 100° C. for 60 seconds.

As a result, in each of the examples, a 1:1 line and space (LS) pattern having a line width of 130 nm and a pitch of 260 nm was formed in the resist film. The optimum exposure dose Eop (mJ/cm²) was also determined. The results are shown in Table 3.

### [Evaluation of Line Width Roughness (LWR)]

For each of the LS patterns having a line width of 130 nm and a pitch of 260 nm formed at the above-mentioned Eop value, the line width was measured at 400 locations along the lengthwise direction of the line using a scanning electron microscope (accelerating voltage: 800 V, product name: S-9380, manufactured by Hitachi High-Technologies Corporation), and from these measurement results, a standard deviation (a) was determined, and the value of 3 times the standard deviation (3s) (units: nm) was calculated. The results are shown in Table 3.

The smaller this value of 3s, the lower the level of roughness in the line width, indicating an LS pattern of more uniform width.

### [Resist Pattern Shape Evaluation (1)]

Each of the LS patterns having a line width of 130 nm and a pitch of 260 nm formed at the above-mentioned Eop value was inspected using a scanning electron microscope (product name: SU8000, manufactured by Hitachi High-Technologies Corporation), and the cross-sectional shape of the LS pattern was evaluated. The results are shown in Table 3.

TABLE 3

| | PAB | PEB | Eop | LWR | |
|---|---|---|---|---|---|
| | (° C.) | (° C.) | (mJ/cm²) | (nm) | Resist pattern shape |
| Comparative | 90 | 90 | 24 | 6.5 | Footing (trapezoidal) |
| example 1 | | | | | with poor verticalness |
| Comparative | 90 | 90 | 18 | 6.8 | Footing (trapezoidal) |
| example 2 | | | | | with poor verticalness |
| Example 1 | 90 | 90 | 16 | 5.3 | Rectangular |
| Example 2 | 90 | 90 | 23 | 5.2 | Rectangular |
| Example 3 | 90 | 90 | 26 | 5.1 | Rectangular |
| Example 4 | 90 | 90 | 35 | 5.3 | Rectangular |
| Example 5 | 90 | 90 | 8 | 5.9 | Rectangular (but |
| | | | | | inferior verticalness |
| | | | | | compared with other |
| | | | | | examples) |
| Example 6 | 90 | 90 | 15 | 5.0 | Rectangular |
| Example 7 | 90 | 90 | 16 | 5.7 | Rectangular |
| Comparative | 90 | 90 | 17 | 6.3 | Footing (trapezoidal) |
| example 3 | | | | | with poor verticalness |

As illustrated in Table 3, the cross-sectional shapes of the resist patterns formed using the resist compositions of the examples 1 to 7, which included a combination of the component (B1) and the component (B2), were confirmed as being superior shapes with excellent rectangularity.

Further, it is also evident that the resist compositions of the examples 1 to 4, 6 and 7, in which the amount of the component (B2) was not more than 50 mol % relative to the sum of the component (B1) and the component (B2), formed resist patterns having a higher degree of rectangularity than the resist composition of the example 5 in which the amount of the component (B2) exceeded 50 mol %.

On the other hand, the cross-sectional shapes of the resist patterns formed using the resist compositions of the comparative examples 1 to 3, which included a combination of the component (B1) and another acid generator other than the component (B2), suffered from footing (a trapezoidal shape) and exhibited inferior verticalness.

Moreover, it is also evident that compared with the resist patterns formed using the resist compositions of the comparative examples 1 to 3, the resist patterns formed using the resist compositions of the examples 1 to 7 had a superior shape with a reduced level of roughness.

### [Resist Pattern Formation (2)]

An organic antireflection film composition ARC29A (a product name, manufactured by Brewer Science Ltd.) was applied onto a 12-inch silicon wafer using a spinner, and the composition was then baked and dried on a hotplate at 205° C. for 60 seconds, thereby forming an organic antireflection film having a film thickness of 89 nm.

Each of the resist compositions prepared above was applied onto a thus formed antireflection film using a spinner, and was then subjected to a bake (PAB) treatment on a hotplate at a PAB temperature indicated in Table 4 for 60 seconds and dried, thereby forming a resist film having a film thickness of 100 nm.

Subsequently, using an ArF immersion lithography exposure apparatus NSR-5609B (manufactured by Nikon Corporation, NA (numerical aperture)=1.07, Annular (Out-0.97/In-0.78) w/XY-POLANO, liquid medium: water), the resist film was selectively irradiated with an ArF excimer laser (193 nm) through a mask pattern (binary).

Next, a bake (PEB) treatment was conducted at a PEB temperature indicated in Table 4 for 60 seconds, followed by alkali development for 30 seconds at 23° C. in a 2.38% by weight aqueous solution of tetramethylammonium hydroxide (TMAH). An additional bake treatment (postbake) was then performed at 100° C. for 45 seconds.

As a result, in each of the examples, a contact hole (CH) pattern was obtained in which holes having a hole diameter of 65 nm were arranged with equal spacing therebetween (pitch: 114 nm).

The optimum exposure dose Eop (mJ/cm²) for formation of the target CH pattern was also determined.

The results are shown in Table 4.

### [Evaluation of Circularity]

The CH pattern formed at the aforementioned Eop was observed from above, and using a measuring SEM (product name: S-9380, manufactured by Hitachi High-Technologies Corporation), the distance from the hole center to the hole outer edge was measured in 24 directions for each of 25 holes within the CH pattern. A standard deviation (σ) was calculated from these results, and the value of 3 times the standard deviation (36) was determined. The results are shown in Table 4.

A smaller value for 36 determined in this manner indicates a higher degree of circularity of the holes.

### [Resist Pattern Shape Evaluation (2)]

Each of the CH patterns having a hole diameter of 65 nm and a pitch of 114 nm formed at the above-mentioned Eop value was inspected using a scanning electron microscope SEM (product name: SU8000, manufactured by Hitachi High-Technologies Corporation), and the cross-sectional shape of the CH pattern was evaluated. The results are shown in Table 4.

TABLE 4

| | PAB | PEB | Eop | | |
|---|---|---|---|---|---|
| | (° C.) | (° C.) | (mJ/cm²) | Circularity | Resist pattern shape |
| Comparative | 80 | 80 | 27.4 | 3.1 | Poor verticalness of |
| example 4 | | | | | hole side walls |
| Example 8 | 80 | 80 | 24.2 | 2.9 | Rectangular |
| Example 9 | 80 | 80 | 21.3 | 2.8 | Rectangular |
| Example 10 | 80 | 80 | 25.0 | 2.7 | Rectangular |
| Example 11 | 80 | 80 | 25.0 | 2.8 | Rectangular |
| Example 12 | 80 | 80 | 25.0 | 2.7 | Rectangular |

As illustrated in Table 4, the cross-sectional shapes of the resist patterns formed using the resist compositions of the examples 8 to 12, which included a combination of the component (B1) and the component (B2), were confirmed as being superior shapes with excellent rectangularity. Further, it is also evident that the resist patterns formed using the resist compositions of the examples 8 to 12 exhibited superior hole circularity.

What is claimed is:

1. A resist composition comprising a base component (A) which exhibits changed solubility in a developing solution under action of acid, and an acid generator component (B) which generates acid upon exposure, wherein
the acid generator component (B) comprises a compound (B1) represented by a general formula (b1) shown below, and a compound (B2) represented by a general formula (b2) shown below:
X-Q¹-Y¹—SO₃⁻A⁺ (b 1)
wherein Q¹ represents a divalent linking group containing an oxygen atom, Y¹ represents an alkylene group of 1 to 4 carbon atoms which may have a substituent or a fluorinated alkylene group of 1 to 4 carbon atoms which may have a substituent, X represents an alicyclic hydrocarbon group of 3 to 30 carbon atoms which may have a substituent, and A⁺ represents an organic cation,
R¹—Y⁵—SO₃⁻A⁺ (b 2)
wherein R¹ represents a monovalent chain-like aliphatic hydrocarbon group containing a hetero atom at an arbitrary position, Y⁵ represents an alkylene group of 1 to 4 carbon atoms which may have a substituent or a fluorinated alkylene group of 1 to 4 carbon atoms which may have a substituent, and A⁺ represents an organic cation.

2. The resist composition according to claim 1, wherein the aliphatic hydrocarbon group for R¹ in the general formula (b2) contains 3 to 20 carbon atoms.

3. The resist composition according to claim 1, wherein an amount of the compound (B2) is not more than 50 mol % relative to a sum of the component (B1) and the component (B2).

4. The resist composition according to claim 1, wherein A⁺ in at least one formula selected from the group consisting of the general formula (b1) and the general formula (b2) is an organic cation represented by a general formula (b-c1) shown below: 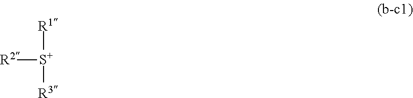
wherein each of R¹″ to R³″ independently represents an aryl group, alkyl group or alkenyl group which may have a substituent, and two of R¹″ to R³″ may be bonded to each other to form a ring together with a sulfur atom in the formula.

5. The resist composition according to claim 1, wherein the base component (A) comprises a polymeric compound (A1) having a structural unit (a1) derived from an acrylate ester in which a hydrogen atom bonded to a carbon atom on an α-position may be substituted with a substituent and containing an acid decomposable group that exhibits increased polarity under action of acid.

6. The resist composition according to claim 5, wherein the polymeric compound (A1) further comprises at least one structural unit selected from the group consisting of structural units (a0) derived from an acrylate ester in which a hydrogen atom bonded to a carbon atom on an α-position may be substituted with a substituent and containing an —SO₂-containing cyclic group, and structural units (a2) derived from an acrylate ester in which a hydrogen atom bonded to a carbon atom on an α-position may be substituted with a substituent and containing a lactone-containing cyclic group.

7. The resist composition according to claim 5, wherein the polymeric compound (A1) further comprises a structural unit (a3) derived from an acrylate ester in which a hydrogen atom bonded to a carbon atom on an α-position may be substituted with a substituent and containing a polar group-containing aliphatic hydrocarbon group.

8. The resist composition according to claim 1, further comprising a nitrogen-containing organic compound (D).

9. A method of forming a resist pattern, the method comprising: using the resist composition according to any one of claims 1 to 8 to form a resist film on a substrate, conducting exposure of the resist film, and developing the resist film to form a resist pattern.
